(19) United States
(12) Patent Application Publication
(10) Pub. No.: US 2025/0185498 A1
(43) Pub. Date: Jun. 5, 2025

(54) LIGHT-EMITTING APPARATUS MATERIAL AND LIGHT-EMITTING DEVICE

(71) Applicant: SEMICONDUCTOR ENERGY LABORATORY CO., LTD., Atsugi-shi, Kanagawa-ken (JP)

(72) Inventors: Hideko YOSHIZUMI, Atsugi (JP); Tomoya YAMAGUCHI, Atsugi (JP); Yui YOSHIYASU, Atsugi (JP); Masatoshi TAKABATAKE, Atsugi (JP); Hiroki HISHINUMA, Isehara (JP); Nobuharu OHSAWA, Zama (JP); Hiromitsu KIDO, Atsugi (JP); Satoshi SEO, Sagamihara (JP)

(21) Appl. No.: 18/962,198

(22) Filed: Nov. 27, 2024

(30) Foreign Application Priority Data
Nov. 30, 2023 (JP) 2023-203379

(51) Int. Cl. H10K 85/30; C07F 15/00; C09K 11/06; H10K 50/11; H10K 101/25

(52) U.S. Cl. CPC H10K 85/346; C07F 15/0086; C09K 11/06; C09K 2211/1007; C09K 2211/1014; C09K 2211/1022; C09K 2211/1033; C09K 2211/1044; C09K 2211/185; H10K 50/11; H10K 2101/25

(57) ABSTRACT

A light-emitting device having excellent characteristics is provided. A light-emitting apparatus material contains an organic compound. In the light-emitting apparatus material, the inner product of a vector A connecting two most distant atoms in the lowest excited state of the organic compound and a vector B that is a transition dipole moment relating to light emission from the organic compound is greater than or equal to 2.5. The length of the vector A is represented in nm, and the magnitude of the vector B is represented in debye. The direction of the vector A is set such that an angle formed by the vector A and the vector B is less than or equal to 90°.

### BACKGROUND OF THE INVENTION

### 1. Field of the Invention

One embodiment of the present invention relates to an organic compound, an organic semiconductor element, a light-emitting device, a photodiode sensor, a display module, a lighting module, a display device, an electronic appliance, a lighting device, and an electronic device. Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Specifically, examples of the technical field of one embodiment of the present invention disclosed in this specification include a semiconductor device, a display device, a liquid crystal display device, a lighting device, a power storage device, a memory device, an image capturing device, a driving method thereof, and a manufacturing method thereof.

### 2. Description of the Related Art

Light-emitting devices (also referred to as organic EL elements) including organic compounds and utilizing electroluminescence (EL) have been put into more practical use. In the basic structure of such light-emitting devices, an organic compound layer containing an emission center substance is located between a pair of electrodes. Carriers are injected by application of voltage to the device, and recombination energy of the carriers is used, whereby light emission can be obtained from the emission center substance.

Since such light-emitting devices are of self-luminous type, display devices in which the light-emitting devices are used for pixels have higher visibility than liquid crystal display devices and do not need a backlight. Display devices that include such light-emitting devices are also highly advantageous in that they can be thin and lightweight. Another feature of such light-emitting devices is that they have an extremely fast response speed.

Since light-emitting layers of such light-emitting devices can be formed as continuous planar layers, planar light emission can be achieved. This feature is difficult to realize with point light sources typified by incandescent lamps and LEDs or linear light sources typified by fluorescent lamps; thus, the light-emitting devices also have great potential as planar light sources, which can be used for lighting devices and the like.

Display devices or lighting devices that include light-emitting devices are suitable for a variety of electronic devices as described above, and research and development of light-emitting devices have progressed for better characteristics.

Patent Document 1 discloses a light-emitting element whose light extraction efficiency is improved by depositing light-emitting substances such that their orientations are aligned with each other to control the direction of light emission.

### REFERENCES

### Patent Document

[Patent Document 1] Japanese Published Patent Application No. 2012-129509

### Non-Patent Documents

[Non-Patent Document 1]D. Yokoyama, Journal of Materials Chemistry, 21, 19187 (2011).
[Non-Patent Document 2] P. Liehm et al., Applied Physics Letters, 101, 253304 (2012).

### SUMMARY OF THE INVENTION

An object of one embodiment of the present invention is to provide a light-emitting device having excellent characteristics. Another object of one embodiment of the present invention is to provide a light-emitting device having high reliability. Another object of one embodiment of the present invention is to provide a light-emitting device having a low driving voltage. Another object of one embodiment of the present invention is to provide a light-emitting device having high reliability and a low driving voltage.

Another object of one embodiment of the present invention is to provide a light-emitting device that enables a display device having excellent characteristics to be provided. Another object of one embodiment of the present invention is to provide a light-emitting device that enables a display device having high reliability to be provided. Another object of one embodiment of the present invention is to provide a display device having a low driving voltage. Another object of one embodiment of the present invention is to provide a light-emitting device that enables a display device having a low driving voltage and high reliability to be provided.

Another object is to provide any of a low-power organic semiconductor device, a low-power light-emitting device, a low-power light-receiving device, a low-power display device, a low-power electronic device, and a low-power lighting device. Another object is to provide a highly reliable electronic device or a highly reliable lighting device.

It is only necessary that at least one of the above-described objects be achieved in the present invention.

One embodiment of the present invention is a light-emitting apparatus material containing an organic compound, in which an inner product of a vector A connecting two most distant atoms in a lowest excited state of the organic compound and a vector B that is a transition dipole moment relating to light emission from the organic compound is greater than or equal to 2.5, a length of the vector A is represented in nm, a magnitude of the vector B is represented in debye, and a direction of the vector A is set such that an angle formed by the vector A and the vector B is less than or equal to 90°.

Another embodiment of the present invention is a light-emitting apparatus material containing an organometallic complex, in which an inner product of a vector A connecting two most distant atoms in a lowest triplet excited state of the organometallic complex and a vector B that is a transition dipole moment relating to light emission from the organometallic complex is greater than or equal to 2.5, a length of the vector A is represented in nm, a magnitude of the vector B is represented in debye, and a direction of the vector A is set such that an angle formed by the vector A and the vector B is less than or equal to 90°.

Another embodiment of the present invention is the light-emitting apparatus material having the above structure, in which the organometallic complex includes a quadridentate ligand.

Another embodiment of the present invention is the light-emitting apparatus material having the above structure, in which the organometallic complex is a cyclometalated complex.

Another embodiment of the present invention is the light-emitting apparatus material having the above structure, in which a metal in the organometallic complex and some atoms in a ligand in the organometallic complex form a six-membered ring.

Another embodiment of the present invention is the light-emitting apparatus material having the above structure, in which a metal in the organometallic complex and some atoms in a ligand in the organometallic complex form a five-membered ring.

Another embodiment of the present invention is the light-emitting apparatus material having the above structure, in which the organometallic complex includes a plurality of the five-membered rings.

Another embodiment of the present invention is the light-emitting apparatus material having the above structure, in which the organometallic complex includes a ligand having carbazole.

Another embodiment of the present invention is the light-emitting apparatus material having the above structure, in which a metal in the organometallic complex is platinum.

Another embodiment of the present invention is the light-emitting apparatus material having the above structure, in which an emission quantum yield of the organometallic complex is higher than or equal to 0.60.

Another embodiment of the present invention is the light-emitting apparatus material having the above structure, in which a molecular orientation parameter a of light emitted from a light-emitting device containing the organometallic complex as an emission center substance in a light-emitting layer is less than or equal to 0.23.

Another embodiment of the present invention is the light-emitting apparatus material having the above structure, in which the light-emitting layer contains a host material and the emission center substance.

Another embodiment of the present invention is a light-emitting device including a first electrode, a second electrode, and a light-emitting layer positioned between the first electrode and the second electrode. The light-emitting layer contains an organic compound in which an inner product of a vector A connecting two most distant atoms in the excited state and a vector B of a transition dipole moment is greater than or equal to 2.5. Note that a length of the vector A is represented in nm, a magnitude of the vector B is represented in debye, and a direction of the vector A is set such that an angle formed by the vector A and the vector B is less than or equal to 90°.

Another embodiment of the present invention is a light-emitting device including a first electrode, a second electrode, and a light-emitting layer positioned between the first electrode and the second electrode. The light-emitting layer contains an organometallic complex in which an inner product of a vector A connecting two most distant atoms in the excited state and a vector B of a transition dipole moment is greater than or equal to 2.5. Note that a length of the vector A is represented in nm, a magnitude of the vector B is represented in debye, and a direction of the vector A is set such that an angle formed by the vector A and the vector B is less than or equal to 90°.

Another embodiment of the present invention is the light-emitting device having the above structure, in which the organometallic complex includes a quadridentate ligand.

Another embodiment of the present invention is the light-emitting device having the above structure, in which the organometallic complex is a cyclometalated complex.

Another embodiment of the present invention is the light-emitting device having the above structure, in which a metal in the organometallic complex and some atoms in a ligand in the organometallic complex form a six-membered ring.

Another embodiment of the present invention is the light-emitting device having the above structure, in which a metal in the organometallic complex and some atoms in a ligand in the organometallic complex form a five-membered ring.

Another embodiment of the present invention is the light-emitting device having the above structure, in which the organometallic complex includes a plurality of the five-membered rings.

Another embodiment of the present invention is the light-emitting device having the above structure, in which the organometallic complex includes a ligand having carbazole.

Another embodiment of the present invention is the light-emitting device having the above structure, in which a metal in the organometallic complex is platinum.

Another embodiment of the present invention is the light-emitting device having the above structure, in which an emission quantum yield of the organometallic complex is higher than or equal to 0.60.

Another embodiment of the present invention is the light-emitting device having the above structure, in which a molecular orientation parameter a of light emitted from the light-emitting device containing the organometallic complex as an emission center substance in a light-emitting layer is less than or equal to 0.23.

Another embodiment of the present invention is the light-emitting device having the above structure, in which the light-emitting layer contains a host material and the emission center substance.

Another embodiment of the present invention is a display device including any of the above light-emitting devices.

Another embodiment of the present invention is an electronic device that includes any of the above light-emitting devices and a sensor, an operation button, a speaker, or a microphone.

Another embodiment of the present invention is a lighting device that includes any of the above light-emitting devices and a housing.

According to one embodiment of the present invention, a light-emitting device having high emission efficiency can be provided. According to another embodiment of the present invention, a light-emitting device having high reliability can be provided. According to another embodiment of the present invention, any of a low-power display device, a low-power electronic device, and a low-power lighting device can be provided. According to another embodiment of the present invention, any of a highly reliable display device, a highly reliable electronic device, and a highly reliable lighting device can be provided.

Note that the description of these effects does not preclude the existence of other effects. One embodiment of the present invention does not necessarily have all these effects. Other effects will be apparent from and can be derived from the description of the specification, the drawings, the claims, and the like.

### BRIEF DESCRIPTION OF THE DRAWINGS

In the accompanying drawings:

FIGS. 1A to 1C are schematic views of light-emitting devices of one embodiment of the present invention;

FIG. 2 shows vectors and an angle formed by the vectors in a platinum complex 2 (a platinum complex B);

FIG. 3 shows a relationship between the observation direction of a measurement device in measuring the spatial distribution of the emission intensity and vector components of a transition dipole moment over a substrate;

FIG. 4 is a graph showing the external quantum efficiency-current density characteristics of a light-emitting device 1, a light-emitting device 2, and a light-emitting device 3;

FIGS. 5A and 5B illustrate a display device of one embodiment of the present invention;

FIGS. 6A and 6B illustrate a display device of one embodiment of the present invention;

FIGS. 7A to 7E are cross-sectional views illustrating an example of a method for fabricating a display device;

FIGS. 8A and 8B are cross-sectional views illustrating an example of a method for fabricating a display device;

FIGS. 9A to 9D are cross-sectional views illustrating an example of a method for fabricating a display device;

FIGS. 10A to 10C are cross-sectional views illustrating an example of a method for fabricating a display device;

FIGS. 11A to 11C are cross-sectional views illustrating an example of a method for fabricating a display device;

FIGS. 12A to 12C are cross-sectional views illustrating an example of a method for fabricating a display device;

FIGS. 13A and 13B are perspective views illustrating a structure example of a display module;

FIGS. 14A and 14B are cross-sectional views illustrating structure examples of a display device;

FIG. 15 is a perspective view illustrating a structure example of a display device;

FIG. 16 is a cross-sectional view illustrating a structure example of a display device;

FIG. 17 is a cross-sectional view illustrating a structure example of a display device;

FIG. 18A is a cross-sectional view illustrating a structure example of a display device, FIG. 18B is a top-view layout illustrating the structure example of the display device, and FIG. 18C is a top view illustrating the structure example of the display device;

FIG. 19 is a cross-sectional view illustrating a structure example of a display device;

FIG. 20A is a cross-sectional view illustrating a structure example of a display device, FIG. 20B is a top-view layout illustrating the structure example of the display device, and FIG. 20C is a top view illustrating the structure example of the display device;

FIGS. 21A to 21D illustrate examples of wearable devices;

FIGS. 22A to 22F illustrate examples of electronic devices;

FIGS. 23A to 23G illustrate examples of electronic devices;

FIG. 24 is a schematic view of a device structure of a light-emitting device for orientation measurement;

FIG. 25 is a graph showing the luminance-current density characteristics of a light-emitting device 1Aa and a light-emitting device 1Ab;

FIG. 26 is a graph showing the current efficiency-current density characteristics of the light-emitting device 1Aa and the light-emitting device 1Ab;

FIG. 27 is a graph showing the luminance-voltage characteristics of the light-emitting device 1Aa and the light-emitting device 1Ab;

FIG. 28 is a graph showing the current density-voltage characteristics of the light-emitting device 1Aa and the light-emitting device 1Ab;

FIG. 29 is a graph showing the external quantum efficiency-current density characteristics of the light-emitting device 1Aa and the light-emitting device 1Ab;

FIG. 30 is a graph showing electroluminescence spectra of the light-emitting device 1Aa and the light-emitting device 1Ab;

FIG. 31 is a graph showing the luminance-current density characteristics of a light-emitting device 1Ba and a light-emitting device 1Bb;

FIG. 32 is a graph showing the current efficiency-current density characteristics of the light-emitting device 1Ba and the light-emitting device 1Bb;

FIG. 33 is a graph showing the luminance-voltage characteristics of the light-emitting device 1Ba and the light-emitting device 1Bb;

FIG. 34 is a graph showing the current density-voltage characteristics of the light-emitting device 1Ba and the light-emitting device 1Bb;

FIG. 35 is a graph showing the external quantum efficiency-current density characteristics of the light-emitting device 1Ba and the light-emitting device 1Bb;

FIG. 36 is a graph showing electroluminescence spectra of the light-emitting device 1Ba and the light-emitting device 1Bb;

FIG. 37 is a graph showing the luminance-current density characteristics of a light-emitting device 1Ca and a light-emitting device 1Cb;

FIG. 38 is a graph showing the current efficiency-current density characteristics of the light-emitting device 1Ca and the light-emitting device 1Cb;

FIG. 39 is a graph showing the luminance-voltage characteristics of the light-emitting device 1Ca and the light-emitting device 1Cb;

FIG. 40 is a graph showing the current density-voltage characteristics of the light-emitting device 1Ca and the light-emitting device 1Cb;

FIG. 41 is a graph showing the external quantum efficiency-current density characteristics of the light-emitting device 1Ca and the light-emitting device 1Cb;

FIG. 42 is a graph showing electroluminescence spectra of the light-emitting device 1Ca and the light-emitting device 1Cb;

FIG. 43 illustrates a method for measuring a molecular orientation parameter a;

FIG. 44 is a graph showing the integrated intensity depending on an angle (θ) of a light-emitting device 1Aa and the angle (θ) of a detector to a substrate;

FIG. 45 is a graph showing the integrated intensity depending on an angle (θ) of a light-emitting device 1Ba and the angle (θ) of a detector to a substrate;

FIG. 46 is a graph showing the integrated intensity depending on an angle (θ) of a light-emitting device 1Ca and the angle (θ) of a detector to a substrate;

FIG. 47 is a graph showing the luminance-current density characteristics of a light-emitting device 2a, a light-emitting device 2b, and a comparative light-emitting device 2;

FIG. 48 is a graph showing the luminance-voltage characteristics of the light-emitting device 2a, the light-emitting device 2b, and the comparative light-emitting device 2;

FIG. 49 is a graph showing the current efficiency-current density characteristics of the light-emitting device 2a, the light-emitting device 2b, and the comparative light-emitting device 2;

FIG. 50 is a graph showing the current density-voltage characteristics of the light-emitting device 2a, the light-emitting device 2b, and the comparative light-emitting device 2;

FIG. 51 is a graph showing the blue index (BI)-current density characteristics of the light-emitting device 2a, the light-emitting device 2b, and the comparative light-emitting device 2;

FIG. 52 is a graph showing electroluminescence spectra of the light-emitting device 2a, the light-emitting device 2b, and the comparative light-emitting device 2; and

FIG. 53 is a graph showing the time dependence of normalized luminance of the light-emitting device 2a, the light-emitting device 2b, and the comparative light-emitting device 2.

### DETAILED DESCRIPTION OF THE INVENTION

Embodiments of the present invention will be described in detail below with reference to the drawings. Note that the embodiments of the present invention are not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

In this specification and the like, a device formed using a metal mask or a fine metal mask (FMM) is sometimes referred to as a device having a metal mask (MM) structure. In this specification and the like, a device formed without using a metal mask or an FMM is sometimes referred to as a device having a metal maskless (MML) structure.

### Embodiment 1

One of factors which greatly influence external quantum efficiency is light extraction efficiency (χ). The light extraction efficiency (χ) is generally 20% to 30% in an organic EL device over a glass substrate, although it depends on the structure, stacked layers, or the like of a light-emitting apparatus. However, the above value is based on the assumption that light emission is isotropic; therefore, this value changes when light emission is anisotropic. Note that light is emitted from an emission center substance in the direction perpendicular to the transition dipole of a molecule; thus, the light extraction efficiency (χ) can be improved by controlling the orientation state of the molecule.

Even when the orientation state is controlled, however, a low emission quantum yield of an emission center substance makes it difficult to obtain a light-emitting device having high emission efficiency.

It is generally known that a highly planar structure of, for example, an organometallic complex represented as a platinum complex 1 by the following structural formula is advantageous in molecular orientation. However, a platinum complex 2 and a platinum complex 3 represented by the following structural formulae, which have not high planarity, can each offer a light-emitting device having higher emission efficiency than that offered by the platinum complex 1. The present inventors have found that a light-emitting device having high emission efficiency can be provided when contribution of a transition dipole moment to an improvement in emission efficiency is estimated from a different point of view from planarity.

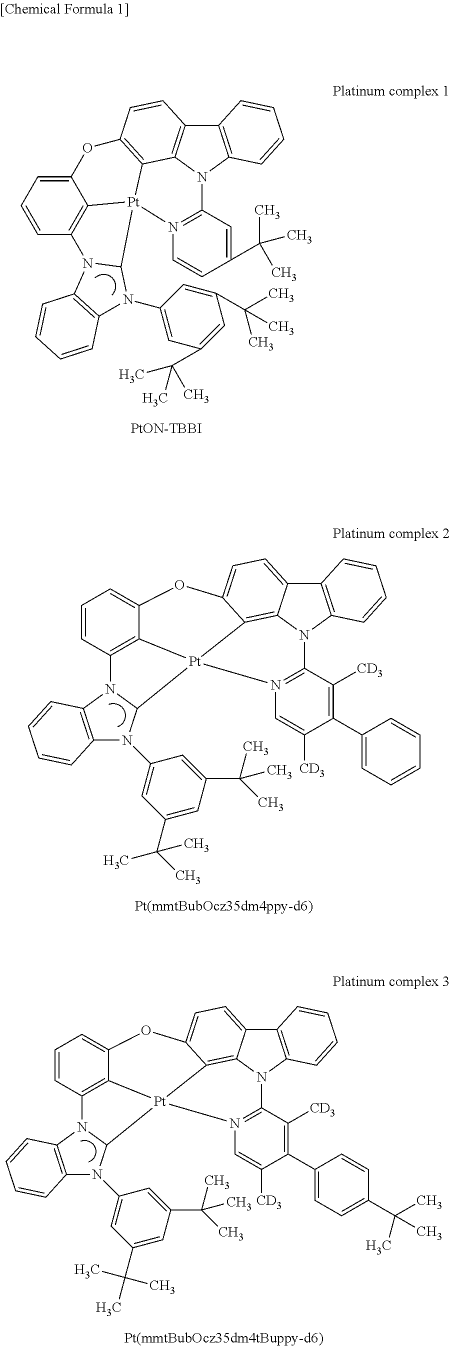

One embodiment of the present invention provides a light-emitting apparatus material or a light-emitting device material that contains an organic compound or an organometallic complex in which the inner product of a vector A connecting two most distant atoms in the lowest excited state and a vector B that is a transition dipole moment relating to light emission is greater than or equal to 2.5, preferably greater than or equal to 4.0. Note that the direction of the vector A is set such that an angle formed by the vector A and the vector B is less than or equal to 90°. The unit of the vector B is debye, and the unit of the vector A is nm in order to match the magnitudes of the vectors. The lowest excited state of a platinum complex is the lowest triplet excited state. A transition dipole moment that is large in the lowest excited state and influences the shape of an emission spectrum is used.

The direction of the vector A connecting two most distant atoms in the lowest excited state is parallel to the direction of the longest side (also referred to as the long-side direction) of a molecule. A small angle formed by the vector A and the vector B of the transition dipole moment is advantageous in molecular orientation. In addition, a large transition dipole moment is advantageous in improving the emission quantum yield.

Accordingly, in the organic compound or the organometallic complex that has such features, the inner product of the vector A connecting two most distant atoms in the lowest excited state and the vector B of the transition dipole moment is large. When the inner product in the organic compound or the organometallic complex is greater than or equal to 2.5, preferably greater than or equal to 4.0, a light-emitting apparatus or a light-emitting device formed using the light-emitting apparatus material or the light-emitting device material that contains the organic compound or the organometallic complex can have high emission efficiency and high reliability.

As described above, light is emitted from the organic compound or the organometallic complex in the direction perpendicular to the transition dipole of a molecule. When a molecule is deposited, the extending direction (long-side direction) of a vector connecting two most distant atoms in the molecule is more probabilistically likely to be a horizontal direction than the other directions with respect to the deposition surface. Thus, the angle formed by the vector A and the vector B that is a vector of the transition dipole moment is preferably small.

Although the vector A connecting two most distant atoms in the lowest excited state is different from a vector connecting two most distant atoms in the ground state, the vector A can be used as an indicator of ease of horizontal orientation with respect to a deposition surface because a significant difference between the directions of the vectors hardly occurs.

The transition dipole moment represents ease of transition between two electron states; a larger transition dipole moment allows the transition to occur more easily, which is advantageous in improving the emission quantum yield. Thus, the transition dipole moment of the vector B is preferably large.

Therefore, the inner product of the vector A and the vector B is preferably large, and the use of the light-emitting apparatus material or the light-emitting device material that contains the organic compound or the organometallic complex in which the inner product is greater than or equal to 2.5, preferably greater than or equal to 4.0 enables light emission to be extracted more efficiently.

In the case where there are a plurality of vectors each connecting two most distant atoms in the lowest excited state in one organic compound or one organometallic complex, a vector that forms the smallest angle with the vector B is regarded as the vector A.

The organic compound or the organometallic complex that is contained in the light-emitting apparatus material or the light-emitting device material has a function of emitting light in a light-emitting apparatus or a light-emitting device. Examples of a material having a function of emitting light include an emission center substance and a color conversion material. Note that the emission quantum yield of the organic compound or the organometallic complex is preferably higher than or equal to 0.60, further preferably higher than or equal to 0.70. The emission quantum yield is preferably measured using a poly(methyl methacrylate) (PMMA) film obtained in the following manner: a solution in which deoxidized dichloromethane is used as a solvent and materials are dispersed at an appropriate concentration (e.g., 4.8 wt %) with respect to PMMA is dripped onto a quartz substrate to form a film by a drop-casting method, and drying is performed under a nitrogen stream in a glove box (e.g., at room temperature for 30 minutes).

The light-emitting apparatus material or the light-emitting device material may contain only the organic compound or the organometallic complex, or may also contain another substance.

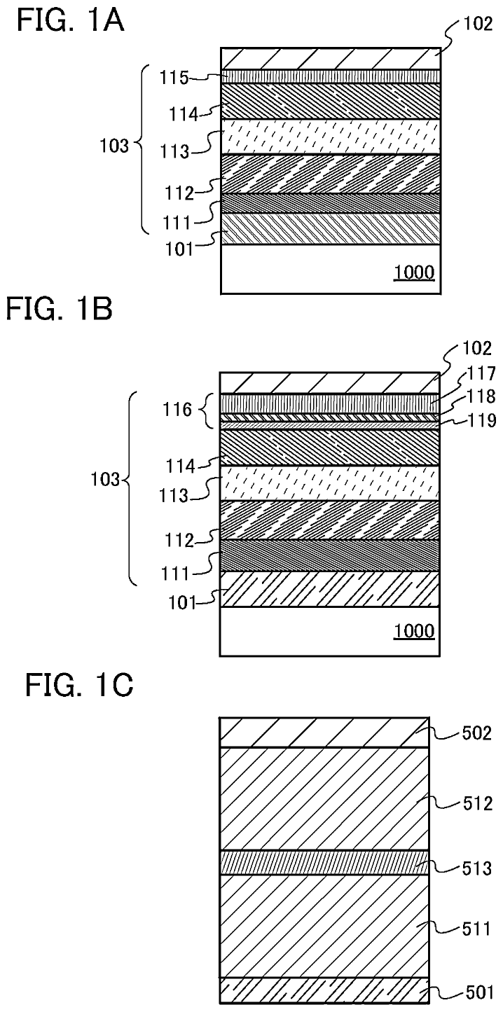

FIG. 1A illustrates a light-emitting device of one embodiment of the present invention. The light-emitting device of one embodiment of the present invention includes a first electrode 101, a second electrode 102, and an organic compound layer 103 over an insulating layer 1000, and the organic compound layer 103 includes a light-emitting layer 113. Note that the organic compound layer 103 may include other functional layers such as a hole-injection layer, a hole-transport layer, an electron-transport layer, and an electron-injection layer.

In the light-emitting device of one embodiment of the present invention, the light-emitting layer 113 contains the light-emitting apparatus material or the light-emitting device material. It is preferable that the light-emitting layer 113 further contain a host material and the light-emitting apparatus material or the light-emitting device material be dispersed in the host material. Note that the host material may be composed of a plurality of organic compounds. An organic compound functioning as the host material may be contained in the light-emitting apparatus material or the light-emitting device material.

The light-emitting device of one embodiment of the present invention having the above structure contains, as an emission center substance, the organic compound or the organometallic complex in which the inner product of the vector A connecting two most distant atoms in the lowest excited state and the vector B of the transition dipole moment relating to light emission is greater than or equal to 2.5, preferably greater than or equal to 4.0; thus, the light-emitting device can have high emission efficiency and high reliability.

In the case where a molecular orientation parameter a of light emitted from the light-emitting device is less than or equal to 0.25, preferably less than or equal to 0.23, light can be extracted easily owing to excellent orientation characteristics and thus the light-emitting device can have higher efficiency. That is, the light-emitting device having the following structure is further preferable: the light-emitting layer contains, as an emission center substance, the organic compound or the organometallic complex in which the inner product of the vector A and the vector B is greater than or equal to 2.5, preferably greater than or equal to 4.0, and the molecular orientation parameter a of light emitted from the light-emitting device is less than or equal to 0.25, preferably less than or equal to 0.23.

The light-emitting apparatus material or the light-emitting device material further preferably contains the organic compound or the organometallic complex in which the inner product of the vector A and the vector B is greater than or equal to 2.5, preferably greater than or equal to 4.0 and which can offer a light-emitting device emitting light with a molecular orientation parameter a of 0.25 or less, preferably 0.23 or less when used in the light-emitting layer.

The molecular orientation parameter a is a value obtained by estimating molecular orientation from an emission state of a device. The radiation angle dependence of the emission intensity (spatial emission pattern) of a light-emitting device reflects the spatial distribution of a transition dipole of an emission center substance. The orientation state of the light-emitting device can be obtained by analysis of this spatial distribution. In this method, light emitted from the light-emitting device is observed and analyzed; thus, as long as the emission center substance emits light, it is possible to obtain the orientation state of the emission center substance in the light-emitting layer in the relationship between a light-emitting surface and a transition dipole moment even when the substance is dispersed in a host material and thus its concentration is low.

Accordingly, the light-emitting device in which the light-emitting apparatus material or the light-emitting device material is used for the light-emitting layer and the molecular orientation parameter a is less than or equal to 0.25, preferably less than or equal to 0.23 can have high efficiency.

### <Method for Calculating Inner Product of Vector A and Vector B>

A method for calculating the inner product of the vector A connecting two most distant atoms in the atomic arrangement in the lowest triplet excited state and the vector B of the transition dipole moment relating to light emission is described using an example in which a platinum complex is used as the organic compound or the organometallic complex contained in the light-emitting apparatus material or the light-emitting device material.

Described here is an example in which the inner product of the vector A and the vector B of each of the platinum complex 1, the platinum complex 2, and the platinum complex 3 is calculated.

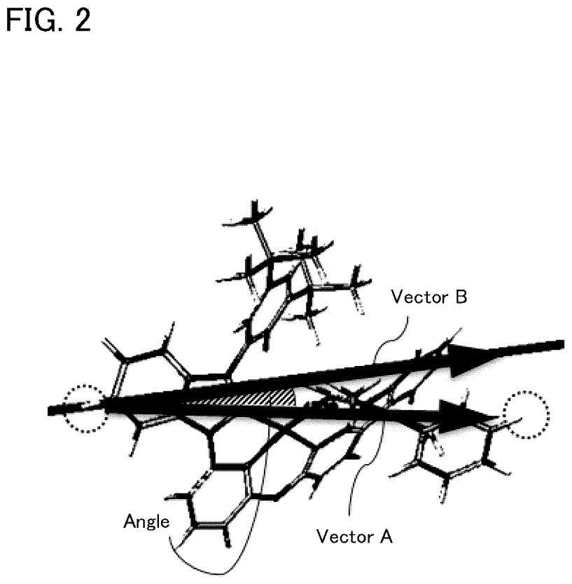

The structure subjected to quantum chemical calculation is sampled by conformational analysis in MacroModel with Maestro GUI produced by Schrödinger, Inc. The quantum chemical calculation software, Jaguar, is used to calculate the most stable structure in the singlet ground state by the density functional theory (DFT), whereby the most stable conformational structure is determined. This structure is subjected to calculation under the following conditions to obtain the most stable structure: as basis functions, DYALL-2ZCVP_ZORA-J-PT-GEN++ is used for a Pt atom and LACVP** is used for the other atoms; ωB97X-D (ω=0.1) is used as a functional; time-dependent density functional theory (TD-DFT) using spin-free ZORA relativistic Hamiltonian is employed; and the excited state is the lowest triplet excited state. The above structure is also subjected to single point energy calculation of the excited state using spin-orbital ZORA relativistic Hamiltonian, whereby the vector B of the transition dipole moment relating to light emission is visualized. In the above structure, the vector A connecting two most distant atoms is set such that an angle formed by the vector A and the vector B is less than or equal to 90°, and the angle is calculated. For example, FIG. 2 illustrates the vectors and the angle formed by the vectors in the platinum complex 2. The results are shown in Table 1.

TABLE 1

| | A | B | Angle | Inner |
|---|---|---|---|---|
| | (nm) | (debye) | (°) | product |
| Platinum complex 1 | 1.56 | 2.17 | 85 | 0.3 |
| Platinum complex 2 | 1.54 | 2.99 | 10 | 4.5 |
| Platinum complex 3 | 1.68 | 2.81 | 25 | 4.3 |

According to the orientation parameters a obtained by experiment described later, the platinum complex 2 and the platinum complex 3 have better orientation characteristics than the platinum complex 1. This result probably correlates to the difference in the inner product of the vector A and the vector B as shown in Table 1. In each of the platinum complex 2 and the platinum complex 3, the transition dipole moment contributes greatly to an improvement in emission efficiency; thus, a light-emitting apparatus or a light-emitting device formed using a light-emitting apparatus material or a light-emitting device material that contains the platinum complex 2 or the platinum complex 3 can have high emission efficiency.

The inner product of the vector A and the vector B is small in the platinum complex 1, which probably leads to small contribution of the transition dipole moment to an improvement in emission efficiency.

As described above, the light-emitting apparatus or the light-emitting device formed using the light-emitting apparatus material or the light-emitting device material that contains the organic compound or the organometallic complex in which the inner product of the vector A and the vector B is large can have high efficiency.

Note that the organometallic complex, rather than the organic compound, is preferably contained in the light-emitting apparatus material or the light-emitting device material, in which case high phosphorescent emission efficiency owing to a fast intersystem crossing process between the singlet state and the triplet state can be achieved. The organometallic complex is preferably a cyclometalated complex, in which case a strong carbon-metal bond can be formed and high phosphorescent emission efficiency owing to metal-to-ligand charge transfer (MLCT) in the excited state can be achieved.

It is preferable that the metal contained in the organometallic complex and some atoms included in the ligand form a ring, in which case the planarity of the organometallic complex is enhanced. Such an organometallic complex is preferable also because a change in the long-side direction between the singlet ground state and the lowest triplet excited state is not so large. Note that the ring is preferably a six-membered ring or a five-membered ring because of its stability. The organometallic complex preferably includes a plurality of the rings, in which case the planarity is further enhanced and a change in the long-side direction between the singlet ground state and the lowest triplet excited state is small. In the case where the plurality of rings are included, both a six-membered ring and a five-membered ring are preferably included, and a plurality of five-membered rings are preferably also included.

The organometallic complex preferably includes the ligand having a carbazole skeleton because of a high energy level of the lowest triplet excited state (T1), an appropriate HOMO-LUMO level, contribution to a hole-transport property or charge confinement in the light-emitting layer, high electron stability, high emission efficiency, low driving voltage, and high durability.

A platinum complex is preferable because it has a quadridentate ligand and the molecular planarity is likely to be kept, which easily makes the inner product of the vector A and the vector B large.

<Method for Calculating Molecular Orientation Parameter a>

Next, a method for calculating the molecular orientation parameter a will be described. The angle dependence of the emission intensity of the measured light-emitting device and the angle dependence of the emission intensity calculated by assuming, with a device simulator, a parameter a (see Formula (1) below) that represents the orientation of a light-emitting molecule are compared; in this manner, the value of the molecular orientation parameter a appropriate for the measured light-emitting device can be estimated to obtain the orientation state of the emission center substance in the light-emitting device (see Non-Patent Document 2).

The present inventors have focused on the shape of the emission spectrum obtained by the device simulator, and compared the measured and calculated values of the shape of the emission spectrum and a change in the shape of the emission spectrum depending on the angle to predict appropriate values. As the emission intensity in the measurement and calculation, not the emission intensity at a particular wavelength but the integrated intensity of the emission spectrum is used. Unlike the method disclosed in Non-Patent Document 2, the methods employed by the present inventors enable highly accurate estimation of the parameter a.

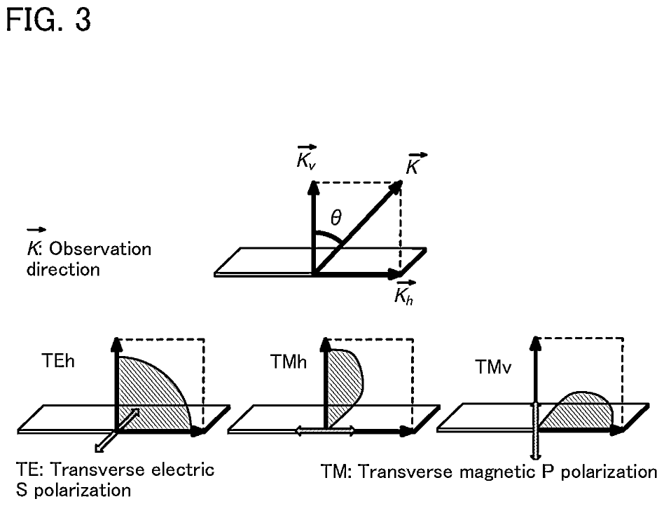

FIG. 3 illustrates a relationship between the observation direction of a measurement device in measuring the spatial distribution of the emission intensity and vector components of a transition dipole moment over a substrate. Since a transition dipole moment is a vector, it can be synthesized and decomposed. An average transition dipole moment in the emission center substance in the light-emitting layer can be decomposed into a component of the x-axis direction (TEh component), a component of the y-axis direction (TMh component), and a component of the z-axis direction (TMv component) which are orthogonal to one another.

Light is emitted from the molecule in the direction perpendicular to the transition dipole moment (a direction in a perpendicular plane) as described above. Among the components decomposed into the three directions, the TEh component and the TMh component (the x-axis direction and the y-axis direction) are transition dipole moments parallel to the substrate surface, and their emission directions are perpendicular to the substrate, so that light emission from the TEh component and the TMh component can be easily extracted. On the other hand, the TMv component (the z-axis direction) is a transition dipole moment perpendicular to the substrate surface and its emission direction is parallel to the substrate, so that light emission from the TMv component is not easily extracted.

In FIG. 3, a figure which extends from the center of an arrow that represents the vector of each component is a schematic figure which represents the emission intensity that is detected by the detector, when the direction of the detector is changed from front of the substrate (θ=0°) to substantially parallel to the substrate (θ=90°). The vertical distance from the center is proportional to the intensity.

Since the detector is located in the direction in which light is emitted, the intensity of detected light of the TEh component (i.e., the vertical distance from the center of the arrow of the figure which extends from the center of the arrow in FIG. 3) is constant, even when the angle of the substrate is changed, and the figure which extends from the center of the arrow has a neat fan shape. On the other hand, the figures which extend from the centers of the arrows of the TMh component and the TMv component have distorted fan shapes, which indicates that the intensity of detected light is greatly changed depending on the angle θ of the detector to the substrate. As shown in FIG. 3, the TMh component has high intensity when θ is small (in a direction closer to the front direction of the substrate), whereas the TMv component has high intensity when θ is large (in a direction closer to the direction parallel to the substrate). In that case, the emission intensity measured by the measurement device (the emission intensity at a wavelength λ and at an angle θ. I_{λ}(θ,λ)) can be represented by Formula (1).

$$[ Formula 1 ]$$

$${I}_{λ} ( θ , λ ) = a \cdot {I}_{TMv} + ( 1 - α ) \cdot ( {I}_{TMh} + {I}_{TEh} ) \qquad Formula ( 1 )$$

In the above formula, I_{TMv}, I_{TMh}, and I_{TEh} represent spatial intensity distribution of light emitted from the transition dipoles arranged as illustrated in FIG. 3, and a represents the proportion of transition dipoles arranged perpendicular to the film surface (the TMv component). In addition, 1-a represents the proportion of transition dipoles arranged parallel to the film surface (the TMh and TEh components). That is, a can also be regarded as a parameter which represents the orientation of transition dipoles of light-emitting molecules.

In the above formula, when the transition dipoles are arranged only in the direction completely parallel to the substrate, the TMv component is eliminated and a is 0. By contrast, when the transition dipoles are arranged only in the direction perpendicular to the substrate, a is 1. When the directions of the transition dipoles are not the same, the directions of the transition dipoles are supposed to be isotropic, i.e., x-axis:y-axis:z-axis=1:1:1, so that the ratio of the component perpendicular to the substrate (the TMv component) to the components parallel to the substrate (the TMh and TEh components) is 1:2 and a is 1/3 (approximately 0.33).

As described above, I_{TEh} is constant independent of the angle; however, I_{TMv}, and I_{TMh} change depending on the angle (θ) of the substrate to the measurement device. Thus, by measuring the emission intensity while changing θ, a can be obtained from the change in I_{TMv} and I_{TMh} depending on θ.

In that case, I_{TEh} which does not change depending on the angle hinders the measurement. The amplitude direction of an electric field of emitted light is the same as the direction of the transition dipole moment, and I_{TEh} is S-polarized light and I_{TMv} and I_{TMh} mare each P-polarized light. Thus, by disposing a linear polarizer in the direction perpendicular to the substrate surface, measurement can be performed under the condition where the TEh component is excluded.

The TMh component and the TMv component are compared. The emission direction of the TMh component is mainly perpendicular to the substrate and the emission direction of the TMv component is mainly parallel to the substrate; in a light-emitting device in which light emission is obtained from a solid, a large part of light emission from the TMv component is totally reflected and cannot be extracted to the outside. On the other hand, light emission from the TMh component is more easily extracted to the outside than light emission from the TMv component. Furthermore, in a light-emitting device in which the thickness is optically optimized, light emission from the TMh component whose emission direction is mainly perpendicular to the substrate is intensified through interference, so that the emission intensity of the TMh component is increased (thus, the emission efficiency is maximized). That is, unless the orientation parameter a is very close to 1, a difference between the emission intensity of the TMv component and that of the TMh component is very large in the light-emitting device in which the thickness is optically optimized. That is, in the light-emitting device in which the emission efficiency is maximized, most light emission which is observed depends on the TMh component. In the case where the difference between the emission intensity of the TMh component and that of the TMv component is large as described above, it is difficult to experimentally extract light emission from the component which has lower intensity (namely the TMv component) from the distribution of the emission intensity depending on the angle.

Thus, in this embodiment, the emission intensity in the front direction of the substrate is suppressed as much as possible by utilizing an interference effect (that is, light emission from the TMh component is reduced as much as possible by utilizing an interference effect), so that the value of a can be easily obtained. For this purpose, a device for orientation measurement in which the thickness is adjusted is prepared for measurement. Specifically, the device is fabricated and used for measurement, in which the luminance in the front direction is lowered by setting the distance between a light-emitting region and a cathode to nλ/2. In general, the thickness is adjusted by increasing the thickness of an electron-transport layer to which an alkali metal is added, for example. However, since there is a limitation on the conductivity of the film, the driving voltage might be increased or the carrier balance might be poor. Accordingly, in order to adjust the thickness, it is preferable to use a composite material of a material having a hole-transport property and a material having an acceptor property with respect to the material having a hole-transport property.

As the composite material, a material similar to a composite material that is preferably used for a hole-injection layer described later in Embodiment 2 can be used. In the device for orientation measurement, molybdenum oxide is preferably used as the acceptor material in order to inhibit an increase in driving voltage.

Examples of device structures of the devices for orientation measurement are shown below.

TABLE 2

| | | | |
|---|---|---|---|
| Thickness | | | |
| (nm) | Device 1 | Device 2 | Device 3 |

| | | |
|---|---|---|
| Second electrode | 200 | Al |
| Thickness | 55 | DBT3P-II:MoOx |
| adjustment layer | | (1:0.5) |
| | 2 | CuPC |
| Electron-injection layer | 0.1 | Li₂O |
| Electron-transport layer | 20 | mPPhen2P |
| | 5 | mSiTrz |
| Light-emitting layer | 35 | SiTrzCz2:PSiCzCz:* |
| | | (0.45:0.45:0.10) |
| Hole-transport layer | 5 | PSiCzCz |
| | 30 | PCBBiF |
| Hole-injection layer | 10 | PCBBiF:OCHD-003 (1:0.03) |
| First electrode | 70 | ITSO |

*Device 1: platinum complex 1
Device 2: platinum complex 2
Device 3: platinum complex 3

Through the measurement using such devices, the molecular orientation parameters a are calculated to be 0.26 for the platinum complex 1, 0.21 for the platinum complex 2, and 0.22 for the platinum complex 3. Since a of 0.33 means random orientation and a of 0 means perfectly horizontal orientation, the above results reveal that the devices formed using any of the platinum complexes have more horizontal orientation components than random orientation components. In particular, the platinum complex 2 and the platinum complex 3 each have more horizontal orientation components than the platinum complex 1 has.

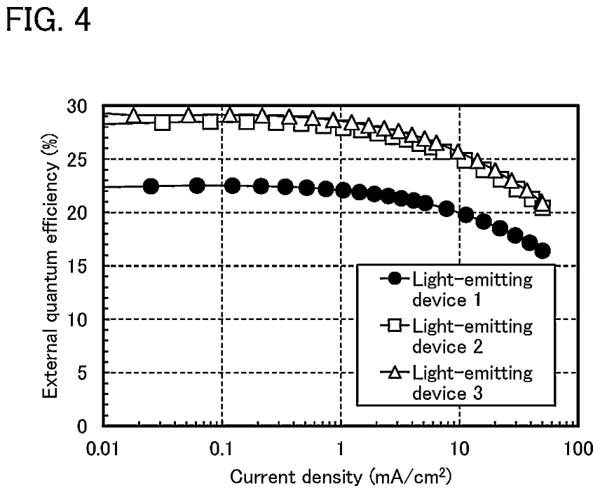

FIG. 4 shows the external quantum efficiency-current density characteristics of light-emitting devices containing the platinum complexes 1 to 3 as emission center substances. A light-emitting device 1, a light-emitting device 2, and a light-emitting device 3 contain the platinum complex 1, the platinum complex 2, and the platinum complex 3, respectively, as the emission center substances. Note that the device structures and the conditions of the light-emitting devices are the same except for the emission center substances.

As shown in FIG. 4, the light-emitting device 2 and the light-emitting device 3 have better external quantum efficiency-current density characteristics than the light-emitting device 1. In this manner, the light-emitting devices containing, as the emission center substances, the platinum complex 2 and the platinum complex 3 in each of which the inner product of the vector A and the vector B is large and the molecular orientation parameter a is less than or equal to 0.23 can have much higher emission efficiency than the light-emitting device containing the platinum complex 1 as the emission center substance.

As described above, the light-emitting device of one embodiment of the present invention can have high emission efficiency when formed using the light-emitting apparatus material or the light-emitting device material that contains the organic compound or the organometallic complex in which the inner product of the vector A and the vector B is greater than or equal to 2.5, preferably greater than or equal to 4.0. When the light-emitting apparatus material or the light-emitting device material is used as the emission center substance, the light-emitting device having a molecular orientation parameter a of 0.23 or less can have higher efficiency.

### Embodiment 2

In this embodiment, a light-emitting device of one embodiment of the present invention that is an organic semiconductor device will be described in detail. FIG. 1A illustrates the light-emitting device of one embodiment of the present invention. The light-emitting device of one embodiment of the present invention includes the organic compound layer 103 between the first electrode 101 formed over the insulating layer 1000 and the second electrode 102 facing the first electrode. The organic compound layer 103 includes at least the light-emitting layer 113, and may further include another functional layer. Although FIGS. 1A and 1B illustrate an example in which the organic compound layer 103 includes a hole-injection layer 111, a hole-transport layer 112, and an electron-transport layer 114, an electron-injection layer 115, an exciton-blocking layer, a charge-generation layer, or the like may be included. In some cases, a layer in the hole-transport layer 112 that is in contact with the light-emitting layer 113 is particularly referred to as an electron-blocking layer, and a layer in the electron-transport layer 114 that is in contact with the light-emitting layer is particularly referred to as a hole-blocking layer.

Although this embodiment describes an example in which the first electrode 101 functions as an anode and the second electrode 102 functions as a cathode, the first electrode 101 may function as a cathode and the second electrode 102 may function as an anode. The first electrode 101 and the second electrode 102 each have a single-layer structure or a stacked-layer structure. In the case of the stacked-layer structure, a layer in contact with the organic compound layer 103 functions as an anode or a cathode. In the case where the electrodes each have the stacked-layer structure, there is no limitation on work functions of materials for layers other than the layer in contact with the organic compound layer 103, and the materials are selected in accordance with required properties such as a resistance value, processing easiness, reflectivity, light-transmitting property, and stability.

Note that the light-emitting layer contains the light-emitting device material described in Embodiment 1. This enables the light-emitting device of one embodiment of the present invention to have high emission efficiency.

The anode is preferably formed using any of metals, alloys, and conductive compounds with a high work function (specifically, higher than or equal to 4.0 eV), mixtures thereof, and the like. Specific examples include indium oxide-tin oxide (ITO: indium tin oxide), indium oxide-tin oxide containing silicon or silicon oxide (ITSO: indium tin silicon oxide), indium oxide-zinc oxide, and indium oxide containing tungsten oxide and zinc oxide (IWZO). Films of such conductive metal oxides are usually formed by a sputtering method, but may be formed by application of a sol-gel method or the like. For example, a film of indium oxide-zinc oxide is formed by a sputtering method using a target in which 1 wt % to 20 wt % zinc oxide is added to indium oxide. Furthermore, a film of indium oxide containing tungsten oxide and zinc oxide (IWZO) can be formed by a sputtering method using a target in which 0.5 wt % to 5 wt % tungsten oxide and 0.1 wt % to 1 wt % zinc oxide are added to indium oxide. Alternatively, gold (Au), platinum (Pt), nickel (Ni), tungsten (W), chromium (Cr), molybdenum (Mo), iron (Fe), cobalt (Co), copper (Cu), palladium (Pd), titanium (Ti), aluminum (Al), nitride of a metal material (e.g., titanium nitride), or the like can be used for the anode. The anode may be a stack of layers formed of any of these materials. For example, a film in which Al, Ti, and ITSO are stacked in this order over Ti is preferable because the film has high efficiency owing to high reflectivity and enables high resolution of several thousand ppi. Graphene can also be used for the anode. When a composite material that can be included in the hole-injection layer 111 described later is used for a layer (typically, the hole-injection layer) in contact with the anode, an electrode material can be selected regardless of its work function.

The hole-injection layer 111 is provided in contact with the anode and has a function of facilitating injection of holes into the organic compound layer 103. The hole-injection layer 111 can be formed using phthalocyanine (abbreviation: H₂Pc), a phthalocyanine-based compound or a phthalocyanine-based complex compound such as copper phthalocyanine (abbreviation: CuPc), an aromatic amine compound such as 4,4′-bis[N-(4-diphenylaminophenyl)-N-phenylamino]biphenyl (abbreviation: DPAB) or 4,4′-bis(N-{4-[N′-(3-methylphenyl)-N′-phenylamino]phenyl}-N-phenylamino)biphenyl (abbreviation: DNTPD), or a high molecular compound such as poly(3,4-ethylenedioxythiophene)/poly(styrenesulfonic acid) (abbreviation: PEDOT/PSS), for example.

The hole-injection layer 111 may be formed using a substance having an electron-accepting property. Examples of the substance having an acceptor property include organic compounds having an electron-withdrawing group (a halogen group or a cyano group), such as 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), and 2-(7-dicyanomethylene-1,3,4,5,6,8,9,10-octafluoro-7H-pyren-2-ylidene)malononitrile. A compound in which electron-withdrawing groups are bonded to a fused aromatic ring having a plurality of heteroatoms, such as HAT-CN, is particularly preferable because it is thermally stable. A [3]radialene derivative having an electron-withdrawing group (in particular, a cyano group, a halogen group such as a fluoro group, or the like) has a significantly high electron-accepting property and thus is preferable. Specific examples include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile]. As the substance having an acceptor property, a transition metal oxide such as molybdenum oxide, vanadium oxide, ruthenium oxide, tungsten oxide, or manganese oxide can be used, other than the above-described organic compounds. The substance having an acceptor property can extract electrons from an adjacent hole-transport layer (or hole-transport material) by application of an electric field.

The hole-injection layer 111 is preferably formed using a composite material containing any of the aforementioned materials having an acceptor property and a substance having a hole-transport property.

As the substance having a hole-transport property used in the composite material, any of a variety of organic compounds such as aromatic amine compounds, heteroaromatic compounds, aromatic hydrocarbons, and high molecular compounds (e.g., oligomers, dendrimers, and polymers) can be used. Note that the substance having a hole-transport property used in the composite material preferably has a hole mobility higher than or equal to 1×10⁻⁶ cm²/Vs. The substance having a hole-transport property used in the composite material is preferably a compound having a fused aromatic hydrocarbon ring or a π-electron rich heteroaromatic ring. As the fused aromatic hydrocarbon ring, an anthracene ring, a naphthalene ring, or the like is preferable. As the π-electron rich heteroaromatic ring, a fused aromatic ring having at least one of a pyrrole skeleton, a furan skeleton, and a thiophene skeleton is preferable; specifically, a carbazole ring, a dibenzothiophene ring, or a ring in which an aromatic ring or a heteroaromatic ring is further fused to a carbazole ring or a dibenzothiophene ring is preferable.

Such a substance having a hole-transport property further preferably has any of a carbazole skeleton, a dibenzofuran skeleton, a dibenzothiophene skeleton, and an anthracene skeleton. In particular, an aromatic amine having a substituent that includes a dibenzofuran ring or a dibenzothiophene ring, an aromatic monoamine that has a naphthalene ring, or an aromatic monoamine in which a 9-fluorenyl group is bonded to nitrogen of an amine through an arylene group may be used. Note that the substance having a hole-transport property preferably has an N,N-bis(4-biphenyl)amino group to enable fabricating a light-emitting device with a long lifetime.

Specific examples of the substance having a hole-transport property include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBipNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, N,N-bis(9,9-dimethyl-9H-fluoren-2-yl)-9,9′-spirobi-9H-fluoren-1-amine, 9-[3-(triphenylsilyl)phenyl]-3,9′-bi-9H-carbazole (abbreviation: PSiCzCz), and 9′-phenyl-9′H-9,3′:6′,9″-tercarbazole (abbreviation: PSiCzGI).

Examples of the aromatic amine compounds that can be used as the substance having a hole-transport property include N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), 4,4′-bis(N-{4-[N′-(3-methylphenyl)-N′-phenylamino]phenyl}-N-phenylamino)biphenyl (abbreviation: DNTPD), and 1,3,5-tris[N-(4-diphenylaminophenyl)-N-phenylamino]benzene (abbreviation: DPA3B).

The formation of the hole-injection layer 111 can improve the hole-injection property, which allows the light-emitting device to be driven at a low voltage.

Among substances having an acceptor property, an organic compound having an acceptor property is easy to use because it is easily deposited by evaporation.

The hole-transport layer 112 is formed using a substance having a hole-transport property. The substance having a hole-transport property preferably has a hole mobility higher than or equal to 1×10⁻⁶ cm²/Vs.

Examples of the substance having a hole-transport property include compounds having an aromatic amine skeleton, such as 4,4′-bis[N-(1-naphthyl)-N-phenylamino]biphenyl (abbreviation: NPB), N,N′-diphenyl-N,N′-bis(3-methylphenyl)-4,4′-diaminobiphenyl (abbreviation: TPD), N,N′-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF); compounds having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), 3,9-bis(9-phenyl-9H-carbazol-3-yl)-9H-carbazole (abbreviation: PCCzPC), 9-(biphenyl-4-yl)-9′-phenyl-3,3′-bi-9H-carbazole (abbreviation: PCCzBP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-9H,9′H-3,3′-bicarbazole (abbreviation: βNCCP), 9-(3-biphenyl)-9′-(2-naphthyl)-3,3′-bi-9H-carbazole (abbreviation: βNCCmBP), 9-(4-biphenyl)-9′-(2-naphthyl)-3,3′-bi-9H-carbazole (abbreviation: βNCCBP), 9,9′-di-2-naphthyl-3,3′-9H,9′H-bicarbazole (abbreviation: BispNCz), 9-(2-naphthyl)-9′-[1,1′:4′,1″-terphenyl]-3-yl-3,3′-9H,9′H-bicarbazole, 9-(2-naphthyl)-9′-[1,1′: 3′, 1″-terphenyl]-3-yl-3,3′-9H,9′H-bicarbazole, 9-(2-naphthyl)-9′-[1,1′: 3′, 1″-terphenyl]-5′-yl-3,3′-9H,9′H-bicarbazole, 9-(2-naphthyl)-9′-[1,1′: 4′, 1″-terphenyl]-4-yl-3,3′-9H,9′H-bicarbazole, 9-(2-naphthyl)-9′-[1,1′: 3′, 1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, 9-(triphenylen-2-yl)-9′-[1,1′: 3′, 1″-terphenyl]-4-yl-3,3′-9H,9′H-bicarbazole, N,N-bis(9,9-dimethyl-9H-fluoren-2-yl)-9,9′-spirobi-9H-fluoren-1-amine, 9-[3-(triphenylsilyl)phenyl]-3,9′-bi-9H-carbazole (abbreviation: PSiCzCz), and 9′-phenyl-9′H-9,3′: 6′, 9″-tercarbazole (abbreviation: PSiCzGI); compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above substances, the compound having an aromatic amine skeleton or the compound having a carbazole skeleton is preferable because the compound is highly reliable and has a high hole-transport property to contribute to a reduction in driving voltage. Any of the organic compounds given as examples of the substance having a hole-transport property used in the composite material for the hole-injection layer 111 can also be suitably used as the material contained in the hole-transport layer 112.

The light-emitting layer 113 has the structure described in Embodiment 1. The emission center substance in the light-emitting layer 113 is preferably the organic compound or the organometallic complex contained in the light-emitting device material described in Embodiment 1. The light-emitting device having high emission efficiency can be obtained when the inner product of the vector A connecting two most distant atoms in the lowest excited state and the vector B of a transition dipole moment is greater than or equal to 2.5, preferably greater than or equal to 4.0 in the organic compound or the organometallic complex.

Any of a fluorescent substance, a phosphorescent substance, a substance exhibiting thermally activated delayed fluorescence (TADF), and other light-emitting substances may be used as the emission center substance as long as the inner product of the vector A and the vector B in the substance is greater than or equal to 2.5, preferably greater than or equal to 4.0.

Note that the emission center substance is preferably the organometallic complex, in which case high phosphorescent emission efficiency owing to a fast intersystem crossing process between the singlet state and the triplet state can be achieved. The organometallic complex is preferably a cyclometalated complex, in which case a strong carbon-metal bond can be formed and high phosphorescent emission efficiency owing to metal-to-ligand charge transfer (MLCT) in the excited state can be achieved.

It is preferable that the metal contained in the organometallic complex and some atoms included in the ligand form a ring, in which case the planarity of the organometallic complex is enhanced. Such an organometallic complex is preferable also because a change in the long-side direction between the singlet ground state and the lowest triplet excited state is not so large. Note that the ring is preferably a six-membered ring or a five-membered ring because of its stability. The organometallic complex preferably includes a plurality of the rings, in which case the planarity is further enhanced and a change in the long-side direction between the singlet ground state and the lowest triplet excited state is small. In the case where the plurality of rings are included, both a six-membered ring and a five-membered ring are preferably included, and a plurality of five-membered rings are preferably also included.

The organometallic complex preferably includes the ligand having a carbazole skeleton because of a high energy level of the lowest triplet excited state (T1), an appropriate HOMO-LUMO level, contribution to a hole-transport property, high electron stability, high emission efficiency, low driving voltage, and high durability.

A platinum complex is preferable because it has a quadridentate ligand and the molecular planarity is likely to be kept, which easily makes the inner product of the vector A and the vector B large.

Examples of the substance that can be used as the organic compound or the organometallic complex include (2-{3-[3-(3,5-di-tert-butylphenyl)benzimidazol-1-yl-2-ylidene-κC²]phenoxy-κC²}-9-[3,5-di(methyl-d3)-4-phenyl-2-pyridinyl-κN]carbazole-2,1-diyl-κC)platinum(II) (abbreviation: Pt(mmtBubOcz35dm4ppy-d6)) and (2-{3-[3-(3,5-di-tert-butylphenyl)benzimidazol-1-yl-2-ylidene-κC²]phenoxy-κC²}-9-[3,5-di(methyl-d3)-4-tert-butylphenyl-2-pyridinyl-κN]carbazole-2,1-diyl-κC)platinum(II) (abbreviation: Pt(mmtBubOcz35dm4tBuppy-d6)).

Note that the light-emitting device can have high emission efficiency also when the light-emitting layer is formed using, among light-emitting materials described below, the light-emitting apparatus material or the light-emitting device material that contains the organic compound or the organometallic complex in which the inner product of the vector A and the vector B calculated as described in Embodiment 1 is greater than or equal to 2.5, preferably greater than or equal to 4.0. That is, the light-emitting device can have high emission efficiency when the organic compound or the organometallic complex in which the inner product of the vector A and the vector B calculated as described in Embodiment 1 is greater than or equal to 2.5, preferably greater than or equal to 4.0, among the light-emitting materials described below, is used as the emission center substance.

As a fluorescent material that can be used as the emission center substance in the light-emitting layer 113 in the light-emitting device of one embodiment of the present invention, any of materials in which the inner product of the vector A and the vector B is greater than or equal to 2.5, preferably greater than or equal to 4.0 among the following materials can be used, for example. A fluorescent material other than the following fluorescent materials can also be used as long as the inner product of the vector A and the vector B is greater than or equal to 2.5, preferably greater than or equal to 4.0.

The examples include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-diphenyl-N,N′-bis[4-(9-phenyl-9H-fluoren-9-yl)phenyl]pyrene-1,6-diamine (abbreviation: 1,6FLPAPrn), N,N-bis(3-methylphenyl)-N,N-bis[3-(9-phenyl-9H-fluoren-9-yl)phenyl]pyrene-1,6-diamine (abbreviation: 1,6mMemFLPAPrn), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N″-(2-tert-butylanthracene-9,10-diyldi-4,1-phenylene)bis(N,N,N′-triphenyl-1,4-phenylenediamine) (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N,N-triphenyl-1,4-phenylenediamine (abbreviation: 2DPAPPA), N,N,N′,N′,N″,N″,N′″,N′″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(biphenyl-2-yl)-2-anthryl]-N,9-diphenyl-9H-carbazol-3-amine (abbreviation: 2PCABPhA), N-(9,10-diphenyl-2-anthryl)-N,N,N′-triphenyl-1,4-phenylenediamine (abbreviation: 2DPAPA), N-[9,10-bis(biphenyl-2-yl)-2-anthryl]-N,N′,N′-triphenyl-1,4-phenylenediamine (abbreviation: 2DPABPhA), 9,10-bis(biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl)-4H-pyran-4-ylidene}propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), N,N-diphenyl-N,N′-(1,6-pyrene-diyl)bis[(6-phenylbenzo[b]naphtho[1,2-d]furan)-8-amine](abbreviation: 1,6BnfAPrn-03), N,N′-diphenyl-N,N′-bis(9-phenyl-9H-carbazol-2-yl)naphtho[2,3-b;6,7-b′]bisbenzofuran-3,10-diamine (abbreviation: 3,10PCA2Nbf(IV)-02), and 3,10-bis[N-(dibenzofuran-3-yl)-N-phenylamino]naphtho[2,3-b;6,7-b′]bisbenzofuran (abbreviation: 3,10FrA2Nbf(IV)-02). Fused aromatic diamine compounds typified by pyrenediamine compounds such as 1,6FLPAPrn, 1,6mMemFLPAPrn, and 1,6BnfAPrn-03 are particularly preferable because of their high hole-trapping properties, high emission efficiency, or high reliability.

A fused heteroaromatic compound containing nitrogen and boron, especially a compound having a diaza-boranaphtho-anthracene skeleton, exhibits a narrow emission spectrum, emits blue light with high color purity, and can thus be suitably used. Examples of the compound include 5,9-diphenyl-5,9-diaza-13b-boranaphtho[3,2,1-de]anthracene (abbreviation: DABNA1), 9-(biphenyl-3-yl)-N,N,5,11-tetraphenyl-5H,9H-[1,4]benzazaborino[2,3,4-kl]phenazaborin-3-amine (abbreviation: DABNA2), 2,12-di(tert-butyl)-5,9-di(4-tert-butylphenyl)-N,N-diphenyl-5H,9H-[1,4]benzazaborino[2,3,4-kl]phenazaborin-7-amine (abbreviation: DPhA-tBu4DABNA), 2,12-di(tert-butyl)-N,N,5,9-tetra(4-tert-butylphenyl)-5H,9H-[1,4]benzazaborino[2,3,4-kl]phenazaborin-7-amine (abbreviation: tBuDPhA-tBu4DABNA), 2,12-di(tert-butyl)-5,9-di(4-tert-butylphenyl)-7-methyl-5H,9H-[1,4]benzazaborino[2,3,4-kl]phenazaborine (abbreviation: Me-tBu4DABNA), N⁷,N⁷,N¹³,N¹³,5,9,11,15-octaphenyl-5H,9H,11H,15H-[1,4]benzazaborino[2,3,4-kl][1,4]benzazaborino[4′,3′,2′:4,5][1,4]benzazaborino[3,2-b]phenazaborine-7,13-diamine (abbreviation: v-DABNA), and 2-(4-tert-butylphenyl)benz[5,6]indolo[3,2,1-jk]benzo[b]carbazole (abbreviation: tBuPBibc).

Besides the above compounds, 9,10,11-tris[3,6-bis(1,1-dimethylethyl)-9H-carbazolyl-9-yl]-2,5,15,18-tetrakis(1,1-dimethylethyl)indolo[3,2,1-de]indolo[3′,2′,1′:8,1][1,4]benzazaborino[2,3,4-kl]phenazaborine (abbreviation: BBCz-G), 9,11-bis[3,6-bis(1,1-dimethylethyl)-9H-carbazolyl-9-yl]-2,5,15,18-tetrakis(1,1-dimethylethyl)indolo[3,2,1-de]indolo[3′,2′,1′:8,1][1,4]benzazaborino[2,3,4-kl]phenazaborine (abbreviation: BBCz-Y), or the like can be suitably used.

As a phosphorescent material that can be used as the emission center substance in the light-emitting layer 113 in the light-emitting device of one embodiment of the present invention, any of materials in which the inner product of the vector A and the vector B is greater than or equal to 2.5, preferably greater than or equal to 4.0 among the following materials can be used, for example. A phosphorescent material other than the following phosphorescent materials can also be used as long as the inner product of the vector A and the vector B is greater than or equal to 2.5, preferably greater than or equal to 4.0.

The examples include an organometallic iridium complex having a 4H-triazole skeleton, such as tris(2-[5-(2-methylphenyl)-4-(2,6-dimethylphenyl)-4H-1,2,4-triazol-3-yl-κN²]phenyl-κC)iridium(III) (abbreviation: [Ir(mpptz-dmp)₃]) and tris(5-methyl-3,4-diphenyl-4H-1,2,4-triazolato)iridium(I) (abbreviation: [Ir(Mptz)₃]); an organometallic iridium complex having a 1H-triazole skeleton, such as tris[3-methyl-1-(2-methylphenyl)-5-phenyl-1H-1,2,4-triazolato]iridium(lIm) (abbreviation: [Ir(Mptz1-mp)₃]) and tris(1-methyl-5-phenyl-3-propyl-1H-1,2,4-triazolato)iridium(Ill) (abbreviation: [Ir(Prptz1-Me)₃]); an organometallic iridium complex having an imidazole skeleton, such as fac-tris[1-(2,6-diisopropylphenyl)-2-phenyl-1H-imidazole]iridium(III) (abbreviation: [Ir(iPrpim)₃]), tris[3-(2,6-dimethylphenyl)-7-methylimidazo[1,2-f]phenanthridinato]iridium(III) (abbreviation: [Ir(dmpimpt-Me)₃]), and tris(2-{1-[2,6-bis(1-methylethyl)phenyl]-1H-imidazol-2-yl-κN³}-4-cyanophenyl-κC)iridium(III) (abbreviation: CNImIr); an organometallic complex having a benzimidazolidene skeleton, such as tris[(6-tert-butyl-3-phenyl-2H-imidazo[4,5-b]pyrazin-1-yl-κC²)phenyl-κC]iridium(II) (abbreviation: [Ir(cb)₃]); and an organometallic iridium complex in which a phenylpyridine derivative having an electron-withdrawing group is a ligand, such as bis[2-(4′,6′-difluorophenyl)pyridinato-N,C²-]iridium(III) tetrakis(1-pyrazolyl)borate (abbreviation: FIr6), bis[2-(4′,6′-difluorophenyl)pyridinato-N,C²]iridium(III) picolinate (abbreviation: FIrpic), bis{2-[3′,5′-bis(trifluoromethyl)phenyl]pyridinato-N,C²}iridium(Ill) picolinate (abbreviation: [Ir(CF₃ppy)₂(pic)]), and bis[2-(4′,6′-difluorophenyl)pyridinato-N,C²-]iridium(III) acetylacetonate (abbreviation: FIracac). These compounds emit blue phosphorescent light and have an emission peak in the wavelength range from 450 nm to 520 nm.

Other examples include an organometallic iridium complex having a pyrimidine skeleton, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(IB) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), and (acetylacetonato)bis(4,6-diphenylpyrimidinato)iridium(III) (abbreviation: [Ir(dppm)₂(acac)]); an organometallic iridium complex having a pyrazine skeleton, such as (acetylacetonato)bis(3,5-dimethyl-2-phenylpyrazinato)iridium(III) (abbreviation: [Ir(mppr-Me)₂(acac)]) and (acetylacetonato)bis(5-isopropyl-3-methyl-2-phenylpyrazinato)iridium(III) (abbreviation: [Ir(mppr-iPr)₂(acac)]); an organometallic iridium complex having a pyridine skeleton, such as tris(2-phenylpyridinato-N,C²)iridium(III) (abbreviation: [Ir(ppy)₃]), bis(2-phenylpyridinato-N,C²)iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C²)iridium(III) (abbreviation: [Ir(pq)₃]), bis(2-phenylquinolinato-N,C²)iridium(III) acetylacetonate (abbreviation: [Ir(pq)₂(acac)]), [2-d₃-methyl-8-(2-pyridinyl-κN)benzofuro[2,3-b]pyridine-κC]bis[2-(5-d₃-methyl-2-pyridinyl-κN)phenyl-κC]iridium(III) (abbreviation: [Ir(5mppy-d₃)₂(mbfpypy-d₃)]), {2-(methyl-d₃)-8-[4-(1-methylethyl-1-d)-2-pyridinyl-κN]benzofuro[2,3-b]pyridin-7-yl-κC}bis{5-(methyl-d₃)-2-[5-(methyl-d₃)-2-pyridinyl-κN]phenyl-κC}iridium(III) (abbreviation: [Ir(5mtpy-d₆)₂(mbfpypy-iPr-d₄)]), [2-d₃-methyl-(2-pyridinyl-κN)benzofuro[2,3-b]pyridine-κC]bis[2-(2-pyridinyl-κN)phenyl-κC]iridium(III) (abbreviation: [Ir(ppy)₂(mbfpypy-d₃)]), [2-(4-methyl-5-phenyl-2-pyridinyl-κN)phenyl-κC]bis[2-(2-pyridinyl-κN)phenyl-κC]iridium(III) (abbreviation: [Ir(ppy)₂(mdppy)]), [2-(4-d₃-methyl-5-phenyl-2-pyridinyl-κN²)phenyl-κC]bis[2-(5-d₃-methyl-2-pyridinyl-κN)phenyl-κC]iridium(III) (abbreviation: [Ir(5mppy-d₃)₂(mdppy-d₃)]), and [2-methyl-(2-pyridinyl-κN)benzofuro[2,3-b]pyridine-κC]bis[2-(2-pyridinyl-κN)phenyl-κC]iridium(III) (abbreviation: [Ir(ppy)₂(mbfpypy)]); and a rare earth metal complex such as tris(acetylacetonato) (monophenanthroline)terbium(III) (abbreviation: [Tb(acac)₃(Phen)]). These are mainly compounds that emit green phosphorescent light and have an emission peak in the wavelength range from 500 nm to 600 nm. Note that an organometallic iridium complex having a pyrimidine skeleton has distinctively high reliability or emission efficiency and thus is particularly preferable.

Other examples include an organometallic iridium complex having a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), and bis[4,6-di(naphthalen-1-yl)pyrimidinato](dipivaloylmethanato)iridium(III) (abbreviation: [Ir(d1npm)₂(dpm)]); an organometallic iridium complex having a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), and (acetylacetonato)bis[2,3-bis(4-fluorophenyl)quinoxalinato]iridium(III) (abbreviation: [Ir(Fdpq)₂(acac)]); an organometallic iridium complex having a pyridine skeleton, such as tris(1-phenylisoquinolinato-N,C^{2′})iridium(III) (abbreviation: [Ir(piq)₃]), bis(1-phenylisoquinolinato-N,C²)iridium(III) acetylacetonate (abbreviation: [Ir(piq)₂(acac)]), (3,7-diethyl-4,6-nonanedionato-κO⁴,κO⁶)bis[2,4-dimethyl-6-[7-(1-methylethyl)-1-isoquinolinyl-κN]phenyl-κC]iridium(III), and (3,7-diethyl-4,6-nonanedionato-κO⁴,κO⁶)bis[2,4-dimethyl-6-[5-(1-methylethyl)-2-quinolinyl-κN]phenyl-κC]iridium(III); a platinum complex such as 2,3,7,8,12,13,17,18-octaethyl-21H,23H-porphyrinplatinum(II) (abbreviation: PtOEP); and a rare earth metal complex such as tris(1,3-diphenyl-1,3-propanedionato)(monophenanthroline)europium(III) (abbreviation: [Eu(DBM)₃(Phen)]) and tris[1-(2-thenoyl)-3,3,3-trifluoroacetonato](monophenanthroline)europium(III) (abbreviation: [Eu(TTA)₃(Phen)]). These compounds emit red phosphorescent light and have an emission peak in the wavelength range from 600 nm to 700 nm. Furthermore, an organometallic iridium complex having a pyrazine skeleton can provide red light emission with favorable chromaticity.

A phosphorescent material other than the above phosphorescent materials can also be used as long as the inner product of the vector A and the vector B is greater than or equal to 2.5, preferably greater than or equal to 4.0.

As a TADF material that can be used as the emission center substance in the light-emitting layer 113 in the light-emitting device of one embodiment of the present invention, any of materials in which the inner product of the vector A and the vector B is greater than or equal to 2.5, preferably greater than or equal to 4.0 among the following materials can be used, for example. A TADF material other than the following TADF materials can also be used as long as the inner product of the vector A and the vector B is greater than or equal to 2.5, preferably greater than or equal to 4.0.

Examples of the TADF material include a fullerene, a derivative thereof, an acridine, a derivative thereof, and an eosin derivative. Furthermore, a metal-containing porphyrin, such as a porphyrin containing magnesium (Mg), zinc (Zn), cadmium (Cd), tin (Sn), platinum (Pt), indium (In), or palladium (Pd), can be given. Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP), which are represented by the following structural formulae.

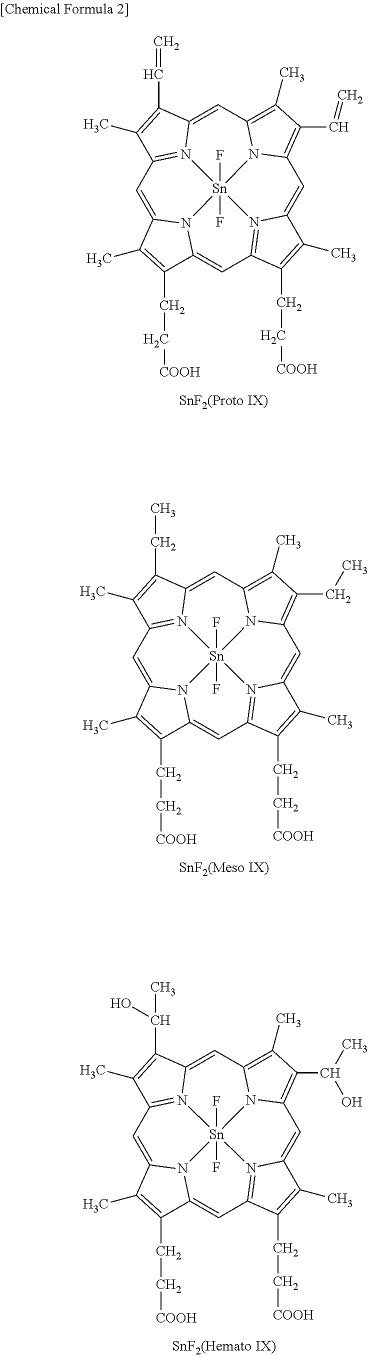

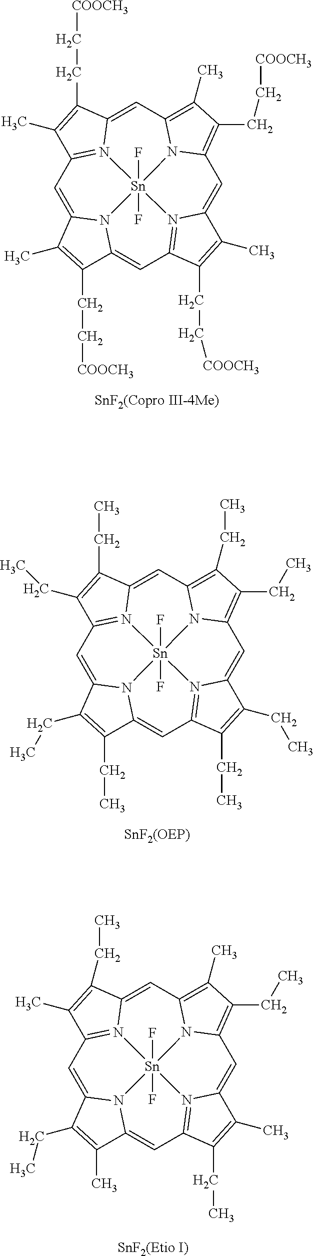

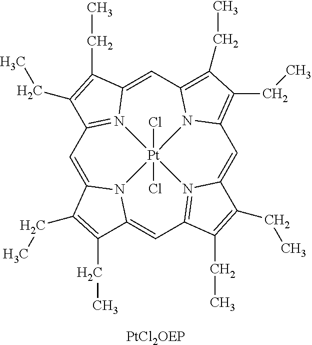

Alternatively, it is possible to use a heterocyclic compound having one or both of a n-electron rich heteroaromatic ring and a π-electron deficient heteroaromatic ring that is represented by the following structural formulae, such as 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA). Such a heterocyclic compound is preferable because of having high electron-transport and hole-transport properties owing to a π-electron rich heteroaromatic ring and a π-electron deficient heteroaromatic ring. Among skeletons having the π-electron deficient heteroaromatic ring, a pyridine skeleton, a diazine skeleton (a pyrimidine skeleton, a pyrazine skeleton, and a pyridazine skeleton), and a triazine skeleton are preferable because of their high stability and reliability. In particular, a benzofuropyrimidine skeleton, a benzothienopyrimidine skeleton, a benzofuropyrazine skeleton, and a benzothienopyrazine skeleton are preferable because of their high acceptor properties and high reliability. Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; thus, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable. Note that a substance in which the π-electron rich heteroaromatic ring is directly bonded to the π-electron deficient heteroaromatic ring is particularly preferable because the electron-donating property of the π-electron rich heteroaromatic ring and the electron-accepting property of the π-electron deficient heteroaromatic ring are both improved, the energy difference between the S₁ level and the T₁ level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used. As a π-electron deficient skeleton, a xanthene skeleton, a thioxanthene dioxide skeleton, an oxadiazole skeleton, a triazole skeleton, an imidazole skeleton, an anthraquinone skeleton, a skeleton containing boron such as phenylborane or boranthrene, an aromatic ring or a heteroaromatic ring having a cyano group or a nitrile group such as benzonitrile or cyanobenzene, a carbonyl skeleton such as benzophenone, a phosphine oxide skeleton, a sulfone skeleton, or the like can be used. As described above, a π-electron deficient skeleton and a π-electron rich skeleton can be used instead of at least one of the π-electron deficient heteroaromatic ring and the π-electon rich heteroaromatic ring.

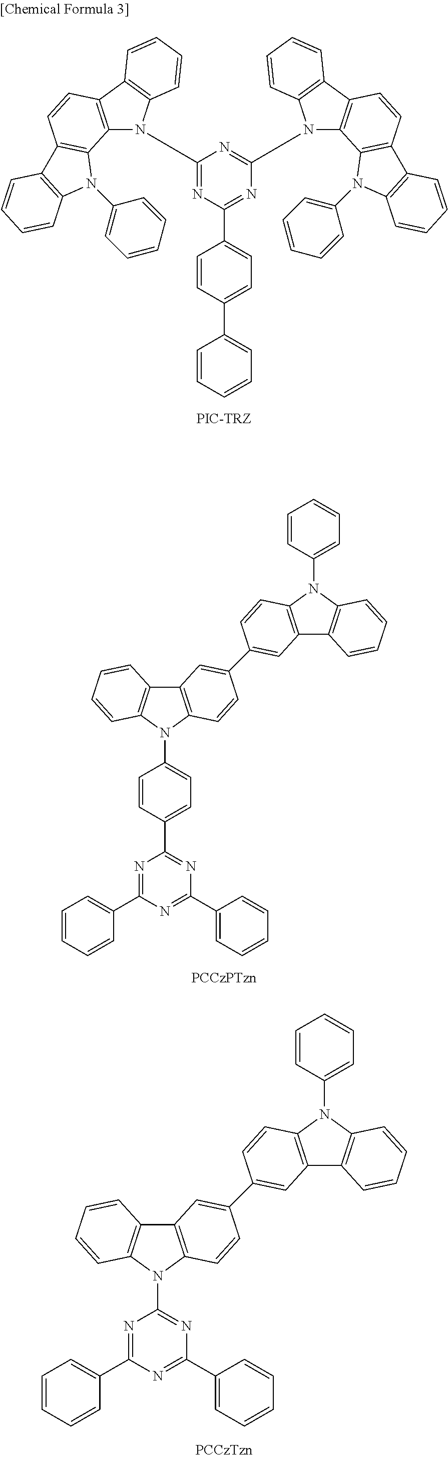 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2nc(-c3ccccc3)nc(-n3c4ccccc4c4cc(-c5ccc6c(c5)c5ccccc5n6-c5ccccc5)ccc43)n2)cc1]

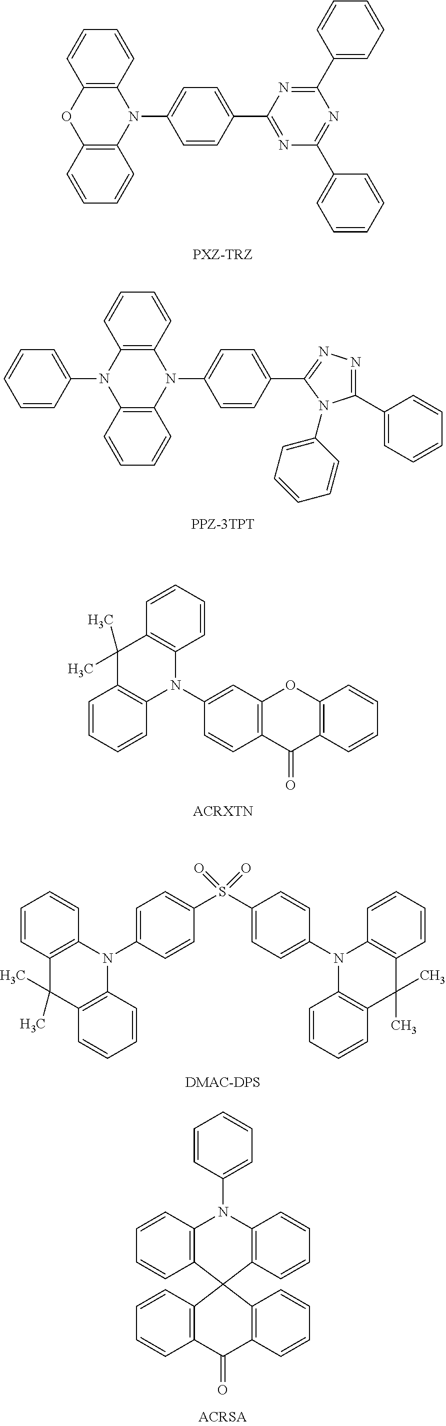 [SMILES: c1ccc(-c2nc(-c3ccccc3)nc(-c3ccc(N4c5ccccc5Oc5ccccc54)cc3)n2)cc1 ; c1ccc(-c2nnc(-c3ccc(N4c5ccccc5N(c5ccccc5)c5ccccc54)cc3)n2-c2ccccc2)cc1 ; CC1(C)c2ccccc2N(c2ccc3c(=O)c4ccccc4oc3c2)c2ccccc21 ; CC1(C)c2ccccc2N(c2ccc(S(=O)(=O)c3ccc(N4c5ccccc5C(C)(C)c5ccccc54)cc3)cc2)c2ccccc21 ; O=C1c2ccccc2C2(c3ccccc31)c1ccccc1N(c1ccccc1)c1ccccc12]

Note that a TADF material is a material having a small difference between the S₁ level and the T₁ level and a function of converting triplet excitation energy into singlet excitation energy by reverse intersystem crossing. Thus, a TADF material can upconvert triplet excitation energy into singlet excitation energy (i.e., reverse intersystem crossing) using a small amount of thermal energy and efficiently generate a singlet excited state. In addition, the triplet excitation energy can be converted into light emission.

An exciplex whose excited state is formed of two kinds of substances has an extremely small difference between the S₁ level and the T₁ level and functions as a TADF material capable of converting triplet excitation energy into singlet excitation energy.

A phosphorescent spectrum observed at low temperatures (e.g., 77 K to 10 K) is used for an index of the T₁ level. When the level of energy with a wavelength of the line obtained by extrapolating a tangent to the fluorescent spectrum at a tail on the short wavelength side is the S₁ level and the level of energy with a wavelength of the line obtained by extrapolating a tangent to the phosphorescent spectrum at a tail on the short wavelength side is the T₁ level, the difference between the S₁ level and the T₁ level of the TADF material is preferably smaller than or equal to 0.3 eV, further preferably smaller than or equal to 0.2 eV.

When a TADF material is used as the light-emitting substance, the S₁ level of the host material is preferably higher than that of the TADF material. In addition, the T₁ level of the host material is preferably higher than that of the TADF material.

As the host material in the light-emitting layer, various carrier-transport materials such as materials having an electron-transport property and/or materials having a hole-transport property, and the TADF materials can be used.

As the material having a hole-transport property, any of a variety of organic compounds such as aromatic amine compounds, heteroaromatic compounds, aromatic hydrocarbons, and high molecular compounds (e.g., oligomers, dendrimers, and polymers) can be used. Note that the substance having a hole-transport property used in the composite material preferably has a hole mobility higher than or equal to 1×10⁻⁶ cm²/Vs. The material having a hole-transport property is preferably an organic compound having an amine skeleton or a π-electron rich heteroaromatic ring skeleton, for example. As the π-electron rich heteroaromatic ring, a fused aromatic ring having at least one of an acridine skeleton, a phenoxazine skeleton, a phenothiazine skeleton, a furan skeleton, a thiophene skeleton, and a pyrrole skeleton is preferable; specifically, a carbazole ring, a dibenzothiophene ring, or a ring in which an aromatic ring or a heteroaromatic ring is further fused to a carbazole ring or a dibenzothiophene ring is preferable.

Such an organic compound having a hole-transport property further preferably has any of a carbazole skeleton, a dibenzofuran skeleton, a dibenzothiophene skeleton, and an anthracene skeleton. In particular, an aromatic amine having a substituent that includes a dibenzofuran ring or a dibenzothiophene ring, an aromatic monoamine that has a naphthalene ring, or an aromatic monoamine in which a 9-fluorenyl group is bonded to nitrogen of an amine through an arylene group may be used. Note that the organic compound having a hole-transport property preferably has an N,N-bis(4-biphenyl)amino group to enable fabricating a light-emitting device having a long lifetime.

Examples of such an organic compound include compounds having an aromatic amine skeleton, such as 4,4′-bis[N-(1-naphthyl)-N-phenylamino]biphenyl (abbreviation: NPB), N,N′-diphenyl-N,N′-bis(3-methylphenyl)-4,4′-diaminobiphenyl (abbreviation: TPD), N,N′-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF); compounds having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), 3,9-bis(9-phenyl-9H-carbazol-3-yl)-9H-carbazole (abbreviation: PCCzPC), 9-(biphenyl-4-yl)-9′-phenyl-3,3′-bi-9H-carbazole (abbreviation: PCCzBP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-9H,9′H-3,3′-bicarbazole (abbreviation: βNCCP), 9-(3-biphenyl)-9′-(2-naphthyl)-3,3′-bi-9H-carbazole (abbreviation: βNCCmBP), 9-(4-biphenyl)-9′-(2-naphthyl)-3,3′-bi-9H-carbazole (abbreviation: βNCCBP), 9,9′-di-2-naphthyl-3,3′-9H,9′H-bicarbazole (abbreviation: BisβNCz), 9-(2-naphthyl)-9′-[1,1′:4′,1″-terphenyl]-3-yl-3,3′-9H,9′H-bicarbazole, 9-(2-naphthyl)-9′-[1,1′:3′,1″-terphenyl]-3-yl-3,3′-9H,9′H-bicarbazole, 9-(2-naphthyl)-9′-[1,1′:3′,1″-terphenyl]-5′-yl-3,3′-9H,9′H-bicarbazole, 9-(2-naphthyl)-9′-[1,1′:4′,1″-terphenyl]-4-yl-3,3′-9H,9′H-bicarbazole, 9-(2-naphthyl)-9′-[1,1′:3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, 9-(triphenylen-2-yl)-9′-[1,1′:3′,1″-terphenyl]-4-yl-3,3′-9H,9′H-bicarbazole, N,N-bis(9,9-dimethyl-9H-fluoren-2-yl)-9,9′-spirobi-9H-fluoren-1-amine, 9-[3-(triphenylsilyl)phenyl]-3,9′-bi-9H-carbazole (abbreviation: PSiCzCz), and 9′-phenyl-9′H-9,3′:6′,9″-tercarbazole (abbreviation: PSiCzGI); compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above substances, the compound having an aromatic amine skeleton or the compound having a carbazole skeleton is preferable because the compound is highly reliable and has a high hole-transport property to contribute to a reduction in driving voltage. In addition, the organic compounds given as examples of the material having a hole-transport property that can be used for the hole-transport layer can also be used.

The material having an electron-transport property preferably has an electron mobility higher than or equal to 1×10⁻⁶ cm²/Vs, further preferably higher than or equal to 1×10⁻⁶ cm²/Vs in the case where the square root of the electric field strength [V/cm] is 600. Note that any other substance can also be used as long as the substance has an electron-transport property higher than a hole-transport property.

As the material having an electron-transport property, for example, a metal complex such as bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ); or an organic compound having a π-electron deficient heteroaromatic ring is preferably used. Examples of the organic compound having a π-electron deficient heteroaromatic ring skeleton include an organic compound that includes a heteroaromatic ring having a polyazole skeleton, an organic compound that includes a heteroaromatic ring having a pyridine skeleton, an organic compound that includes a heteroaromatic ring having a diazine skeleton, and an organic compound that includes a heteroaromatic ring having a triazine skeleton.

Among the above materials, the organic compound that includes a heteroaromatic ring having a diazine skeleton (a pyrimidine skeleton, a pyrazine skeleton, or a pyridazine skeleton), the organic compound that includes a heteroaromatic ring having a pyridine skeleton, and the organic compound that includes a heteroaromatic ring having a triazine skeleton have high reliability and thus are preferable. In particular, the organic compound that includes a heteroaromatic ring having a diazine (pyrimidine or pyrazine) skeleton and the organic compound that includes a heteroaromatic ring having a triazine skeleton have a high electron-transport property to contribute to a reduction in driving voltage. A benzofuropyrimidine skeleton, a benzothienopyrimidine skeleton, a benzofuropyrazine skeleton, and a benzothienopyrazine skeleton are preferable because of their high acceptor properties and high reliability.

Examples of the organic compound having a π-electron deficient heteroaromatic ring skeleton include an organic compound having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), or 4,4′-bis(5-methylbenzoxazol-2-yl)stilbene (abbreviation: BzOS); an organic compound having a heteroaromatic ring having a pyridine skeleton, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), bathophenanthroline (abbreviation: BPhen), bathocuproine (abbreviation: BCP), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), 2-[3-(2-triphenylenyl)phenyl]-1,10-phenanthroline (abbreviation: mTpPPhen), 2-phenyl-9-(2-triphenylenyl)-1,10-phenanthroline (abbreviation: Ph-TpPhen), 2-[4-(9-phenanthrenyl)-1-naphthalenyl]-1,10-phenanthroline (abbreviation: PnNPhen), or 2-[4-(2-triphenylenyl)phenyl]-1,10-phenanthroline (abbreviation: pTpPPhen); an organic compound having a diazine skeleton, such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[fh]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl)biphenyl-3-yl]naphtho[1′,2′:4,5]furo[2,3-b]pyrazine (abbreviation: 9mDBtBPNfpr), 9-[3′-(dibenzothiophen-4-yl)biphenyl-4-yl]naphtho[1′,2′:4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(dibenzothiophen-4-yl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(biphenyl-4-yl)-4-[3-(dibenzothiophen-4-yl)phenyl]-[1]benzofuro[3,2-d]pyrimidine (abbreviation: 8BP-4mDBtPBfpm), 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)(biphenyl-3-yl)]naphtho[1′,2′:4,5]furo[3,2-d]pyrimidine (abbreviation: 8mDBtBPNfpm), 8-[(2,2′-binaphthalen)-6-yl]-4-[3-(dibenzothiophen-4-yl)phenyl]-[1]benzofuro[3,2-d]pyrimidine (abbreviation: 8(ON2)-4mDBtPBfpm), 2,2′-(pyridine-2,6-diyl)bis(4-phenylbenzo[h]quinazoline) (abbreviation: 2,6(P-Bqn)2Py), 2,2′-(pyridine-2,6-diyl)bis(4-[4-(2-naphthyl)phenyl]-6-phenylpyrimidine) (abbreviation: 2,6(NP—PPm)2Py), 6-(biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(biphenyl-4-yl)pyrimidine (abbreviation: 6BP-4Cz2PPm), 7-[4-(9-phenyl-9H-carbazol-2-yl)quinazolin-2-yl]-7H-dibenzo[c,g]carbazole (abbreviation: PC-cgDBCzQz), or 8-(1,1′:4′,1″-terphenyl-3-yl)-4-[3-(dibenzothiophen-4-yl)phenyl]-[1]benzofuro[3,2-d]pyrimidine (abbreviation: 8mpTP-4mDBtPBfpm); and an organic compound having a heteroaromatic ring having a triazine skeleton, such as 2-(biphenyl-4-yl)-4-phenyl-6-(9,9′-spirobi[9H-fluoren]-2-yl)-1,3,5-triazine (abbreviation: BP-SFTzn), 2-(3-[3-(benzo[b]naphtho[1,2-d]furan-8-yl)phenyl]phenyl)-4,6-diphenyl-1,3,5-triazine (abbreviation: mBnfBPTzn), 2-(3-[3-(benzo[b]naphtho[1,2-d]furan-6-yl)phenyl]phenyl)-4,6-diphenyl-1,3,5-triazine (abbreviation: mBnfBPTzn-02), 2-(4-[3-(N-phenyl-9H-carbazol-3-yl)-9H-carbazol-9-yl]phenyl)-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris[3′-(pyridin-3-yl)biphenyl-3-yl]-1,3,5-triazine (abbreviation: TmPPPyTz), 2-[3-(2,6-dimethyl-3-pyridinyl)-5-(9-phenanthrenyl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenyl-indolo[2,3-a]carbazole (abbreviation: BP-Icz(II)Tzn), 2-[3′-(triphenylen-2-yl)biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), 2-(biphenyl-3-yl)-4-phenyl-6-{8-[(1,1′:4′,1″-terphenyl)-4-yl]-1-dibenzofuranyl}-1,3,5-triazine (abbreviation: mBP-TPDBfTzn), 2-[4-(2-naphthalenyl)phenyl]-4-phenyl-6-spiro[9H-fluorene-9,9′-[9H]xanthen]-4-yl-1,3,5-triazine (abbreviation: ONP-SFx(4)Tzn), 9,9′-{6-[3-(triphenylsilyl)phenyl]-1,3,5-triazine-2,4-diyl}bis(9H-carbazole) (abbreviation: SiTrzCz2), 2-phenyl-4,6-bis[3-(triphenylsilyl)phenyl]-1,3,5-triazine (abbreviation: mSiTrz), 11-[4-(biphenyl-4-yl)-6-phenyl-1,3,5-triazin-2-yl]-11,12-dihydro-12-(biphenyl-3-yl)indolo[2,3-a]carbazole (abbreviation: BP-mBPIcz(II)Tzn), 3-{3-[9-(4,6-diphenyl-1,3,5-triazin-2-yl)-2-dibenzofuranyl]phenyl}-9-phenyl-9H-carbazole (abbreviation: mPCPDBfTzn), 9,9′-[6-(biphenyl-4-yl)-2-phenyl-1,3,5-triazin-4,3″-diyl]bis(9H-carbazole) (abbreviation: Cz-pmCzBPTzn), 3-pheny-9-[4-phenyl-6-(9-phenyl-3-dibenzofuranyl)-1,3,5-triazin-2-yl]-9H-carbazole (abbreviation: PDBf-PCzTzn), or 9-[4-(4,6-diphenyl-1,3,5-triazin-2-yl)-2-dibenzothienyl]-2-phenyl-9H-carbazole (abbreviation: PCzDBtTzn). The organic compound that includes a heteroaromatic ring having a diazine skeleton, the organic compound that includes a heteroaromatic ring having a pyridine skeleton, and the organic compound that includes a heteroaromatic ring having a triazine skeleton are preferable because of having high reliability. In particular, the organic compound that includes a heteroaromatic ring having a diazine (pyrimidine or pyrazine) skeleton and the organic compound that includes a heteroaromatic ring having a triazine skeleton have a high electron-transport property to contribute to a reduction in driving voltage.

An organic compound having a bipolar property, such as 3,6-bis(diphenylamino)-9-[4-(4,6-diphenyl-1,3,5-triazin-2-yl)phenyl]-9H-carbazole (abbreviation: DACT-II) or 2-{3-[3-(N-phenyl-9H-carbazol-3-yl)-9H-carbazol-9-yl]phenyl}dibenzo[f,h]quinoxaline (abbreviation: 2mPCCzPDBq) can also be used.

As the TADF material that can be used as the host material, the above materials mentioned as the TADF material can also be used. When the TADF material is used as the host material, triplet excitation energy generated in the TADF material is converted into singlet excitation energy by reverse intersystem crossing and transferred to the light-emitting substance, whereby the emission efficiency of the light-emitting device can be increased. Here, the TADF material functions as an energy donor, and the light-emitting substance functions as an energy acceptor.

This is very effective in the case where the light-emitting substance is a fluorescent substance. In that case, the S₁ level of the TADF material is preferably higher than that of the fluorescent substance in order that high emission efficiency can be achieved. Furthermore, the T₁ level of the TADF material is preferably higher than the S₁ level of the fluorescent substance. Therefore, the T₁ level of the TADF material is preferably higher than that of the fluorescent substance.

It is also preferable to use a TADF material that emits light whose wavelength overlaps with the wavelength on a lowest-energy-side absorption band of the fluorescent substance, in which case excitation energy is transferred smoothly from the TADF material to the fluorescent substance and light emission can be obtained efficiently.

In addition, in order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protective group around a luminophore (a skeleton which causes light emission) of the fluorescent substance. As the protective group, a substituent having no π bond and a saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protective groups. The substituents having no π bond are poor in carrier transport performance; thus, the TADF material and the luminophore of the fluorescent substance can be made away from each other with little influence on carrier transportation or carrier recombination. Here, the luminophore refers to an atomic group (skeleton) that causes light emission in a fluorescent substance. The luminophore is preferably a skeleton having a π bond, further preferably includes an aromatic ring, and still further preferably includes a fused aromatic ring or a fused heteroaromatic ring. Examples of such a luminophore include a phenanthrene skeleton, a stilbene skeleton, an acridone skeleton, a phenoxazine skeleton, a phenothiazine skeleton, a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferable because of its high fluorescence quantum yield.

In the case where a fluorescent substance is used as the emission center substance, a material having an acene skeleton, especially an anthracene skeleton, is suitably used as the host material. The use of a substance having an anthracene skeleton as the host material for the fluorescent substance makes it possible to obtain a light-emitting layer with high emission efficiency and high durability. Among the substances having an anthracene skeleton, a substance having a diphenylanthracene skeleton, especially a substance having a 9,10-diphenylanthracene skeleton, is chemically stable and thus is preferably used as the host material. The host material preferably has a carbazole skeleton to have higher hole-injection and hole-transport properties; further preferably, the host material has a benzocarbazole skeleton in which a benzene ring is further fused to carbazole because the HOMO level of the host material having a benzocarbazole skeleton is higher than that of the host material having a carbazole skeleton by approximately 0.1 eV and thus holes enter the host material easily. In particular, the host material preferably has a dibenzocarbazole skeleton because the HOMO level of the host material having a dibenzocarbazole skeleton is higher than that of the host material having a carbazole skeleton by approximately 0.1 eV so that holes enter the host material easily, the hole-transport property is improved, and the heat resistance is increased. Accordingly, a substance that has both a 9,10-diphenylanthracene skeleton and a carbazole skeleton (or a benzocarbazole or dibenzocarbazole skeleton) is further preferable as the host material. Note that in terms of the hole-injection and hole-transport properties described above, instead of a carbazole skeleton, a benzofluorene skeleton or a dibenzofluorene skeleton may be used.

Examples of such a substance include 9-phenyl-3-[4-(10-phenyl-9-anthryl)phenyl]-9H-carbazole (abbreviation: PCzPA), 3-[4-(1-naphthyl)phenyl]-9-phenyl-9H-carbazole (abbreviation: PCPN), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]benzo[b]naphtho[1,2-d]furan (abbreviation: 2mBnfPPA), 9-phenyl-10-[4-(9-phenyl-9H-fluoren-9-yl)biphenyl-4′-yl]anthracene (abbreviation: FLPPA), 9-(1-naphthyl)-10-[4-(2-naphthyl)phenyl]anthracene (abbreviation: aN-ONPAnth), 9-(1-naphthyl)-10-(2-naphthyl)anthracene (abbreviation: α,βADN), 2-(10-phenylanthracen-9-yl)dibenzofuran, 2-(10-phenyl-9-anthracenyl)benzo[b]naphtho[2,3-d]furan (abbreviation: Bnf(II)PhA), 9-(2-naphthyl)-10-[3-(2-naphthyl)phenyl]anthracene (abbreviation: ON-mpNPAnth), and 1-{4-[10-(biphenyl-4-yl)-9-anthracenyl]phenyl}-2-ethyl-1H-benzimidazole (abbreviation: EtBImPBPhA). In particular, CzPA, cgDBCzPA, 2mBnfPPA, and PCzPA exhibit excellent properties and thus are preferably selected.

Note that the host material may be a mixture of a plurality of kinds of substances; in the case of using a mixed host material, it is preferable to mix a material having an electron-transport property with a material having a hole-transport property. By mixing the material having an electron-transport property with the material having a hole-transport property, the transport property of the light-emitting layer 113 can be easily adjusted and a recombination region can be easily controlled. The weight ratio of the content of the material having a hole-transport property to the content of the material having an electron-transport property is 1:19 to 19:1.

Note that a phosphorescent substance can be used as part of the mixed material. When a fluorescent substance is used as the light-emitting substance, a phosphorescent substance can be used as an energy donor for supplying excitation energy to the fluorescent substance.

An exciplex may be formed of these mixed materials. These mixed materials are preferably selected so as to form an exciplex that exhibits light emission whose wavelength overlaps with the wavelength on a lowest-energy-side absorption band of the light-emitting substance, in which case energy can be transferred smoothly and light emission can be obtained efficiently. The use of such a structure is preferable because the driving voltage can also be reduced.

Note that at least one of the materials forming an exciplex may be a phosphorescent substance. In that case, triplet excitation energy can be efficiently converted into singlet excitation energy by reverse intersystem crossing.

In order to form an exciplex efficiently, a material having an electron-transport property is preferably combined with a material having a hole-transport property and a HOMO level higher than or equal to that of the material having an electron-transport property. In addition, the LUMO level of the material having a hole-transport property is preferably higher than or equal to that of the material having an electron-transport property. Note that the LUMO levels and the HOMO levels of the materials can be derived from the electrochemical characteristics (the reduction potentials and the oxidation potentials) of the materials that are measured by cyclic voltammetry (CV).

The formation of an exciplex can be confirmed by a phenomenon in which the emission spectrum of the mixed film in which the material having a hole-transport property and the material having an electron-transport property are mixed is shifted to the longer wavelength side than the emission spectrum of each of the materials (or has another peak on the longer wavelength side) observed by comparison of the emission spectra of the material having a hole-transport property, the material having an electron-transport property, and the mixed film of these materials, for example. Alternatively, the formation of an exciplex can be confirmed by a difference in transient response, such as a phenomenon in which the transient photoluminescence (PL) lifetime of the mixed film has a longer lifetime component or has a larger proportion of delayed component than that of each of the materials, observed by comparison of transient PL of the material having a hole-transport property, the material having an electron-transport property, and the mixed film of these materials. The transient PL may be rephrased as transient electroluminescence (EL). That is, the formation of an exciplex can also be confirmed by a difference in transient response observed by comparison of the transient EL of the material having a hole-transport property, the material having an electron-transport property, and the mixed film of these materials.

The electron-transport layer 114 contains a substance having an electron-transport property. The substance having an electron-transport property preferably has an electron mobility higher than or equal to 1×10⁻⁷ cm²/Vs, further preferably higher than or equal to 1×10⁻⁶ cm²/Vs in the case where the square root of the electric field strength [V/cm] is 600. Note that any other substance can also be used as long as the substance has an electron-transport property higher than a hole-transport property. An organic compound including a π-electron deficient heteroaromatic ring is preferable as the above organic compound. The organic compound including a π-electron deficient heteroaromatic ring is preferably one or more of an organic compound including a heteroaromatic ring having a polyazole skeleton, an organic compound including a heteroaromatic ring having a pyridine skeleton, an organic compound including a heteroaromatic ring having a diazine skeleton, and an organic compound including a heteroaromatic ring having a triazine skeleton.

As the organic compound that can be used for the electron-transport layer 114, any of the materials given as examples of the material that has an electron-transport property and can be used as the host material in the light-emitting layer 113 can be used. Among the above materials, the organic compound that includes a heteroaromatic ring having a diazine skeleton, the organic compound that includes a heteroaromatic ring having a pyridine skeleton, and the organic compound that includes a heteroaromatic ring having a triazine skeleton are preferable because of having high reliability. In particular, the organic compound that includes a heteroaromatic ring having a diazine (pyrimidine or pyrazine) skeleton and the organic compound that includes a heteroaromatic ring having a triazine skeleton have a high electron-transport property to contribute to a reduction in driving voltage. In particular, an organic compound having a phenanthroline skeleton such as mTpPPhen, PnNPhen, or mPPhen2P is preferable, and an organic compound having a phenanthroline dimer structure such as mPPhen2P is further preferable because of high stability.

Note that the electron-transport layer 114 may have a stacked-layer structure. A layer in the stacked-layer structure of the electron-transport layer 114, which is in contact with the light-emitting layer 113, may function as a hole-blocking layer. In the case where the electron-transport layer in contact with the light-emitting layer functions as a hole-blocking layer, the electron-transport layer is preferably formed using a material having a lower HOMO level than a material contained in the light-emitting layer 113 by greater than or equal to 0.5 eV.

A layer that contains an alkali metal, an alkaline earth metal, a compound or a complex of an alkali metal or an alkaline earth metal, 1,1′-pyridine-2,6-diyl-bis(1,3,4,6,7,8-hexahydro-2H-pyrimido[1,2-a]pyrimidine) (abbreviation: hpp2Py), or the like may be provided as the electron-injection layer 115. The electron-injection layer 115 may be a layer containing a material having an electron-transport property and any of the above substances.

Instead of the electron-injection layer 115, a charge-generation layer 116 may be provided (FIG. 1B). The charge-generation layer 116 refers to a layer capable of injecting holes into a layer in contact with the cathode side of the charge-generation layer 116 and electrons into a layer in contact with the anode side thereof when a potential is applied. The charge-generation layer 116 includes at least a p-type layer 117. The p-type layer 117 is preferably formed using any of the composite materials given above as examples of materials that can be used for the hole-injection layer 111. The p-type layer 117 may be formed by stacking a film containing the above-described acceptor material as a material included in the composite material and a film containing a hole-transport material. When a potential is applied to the p-type layer 117, electrons are injected into the electron-transport layer 114 and holes are injected into the cathode; thus, the light-emitting device operates. Since the organic compound of one embodiment of the present invention has a low refractive index, using the organic compound for the p-type layer 117 enables the light-emitting device to have high external quantum efficiency.

Note that the charge-generation layer 116 preferably includes one or both of an electron-relay layer 118 and an electron-injection buffer layer 119 in addition to the p-type layer 117.

The electron-relay layer 118 includes at least the substance having an electron-transport property and has a function of preventing an interaction between the electron-injection buffer layer 119 and the p-type layer 117 and smoothly transferring electrons. The LUMO level of the substance having an electron-transport property included in the electron-relay layer 118 is preferably positioned between the LUMO level of the acceptor substance in the p-type layer 117 and the LUMO level of a substance included in a layer of the electron-transport layer 114 that is in contact with the charge-generation layer 116. As a specific value of the energy level, the LUMO level of the substance having an electron-transport property in the electron-relay layer 118 is preferably higher than or equal to −5.0 eV, further preferably higher than or equal to −5.0 eV and lower than or equal to −3.0 eV, still further preferably higher than or equal to −4.30 eV and lower than or equal to −3.00 eV, yet still further preferably higher than or equal to −4.30 eV and lower than or equal to −3.30 eV, in which case an increase in driving voltage can be suppressed. Note that as the substance having an electron-transport property in the electron-relay layer 118, a phthalocyanine-based material or a metal complex having a metal-oxygen bond and an aromatic ligand is preferably used.

Specific examples of the substance having an electron-transport property in the electron-relay layer 118 include a perylenetetracarboxylic acid derivative such as diquinoxalino[2,3-a:2′,3′-c]phenazine (abbreviation: HATNA), 2,3,8,9,14,15-hexafluorodiquinoxalino[2,3-a:2′,3′-c]phenazine (abbreviation: HATNA-F6), 3,4,9,10-perylenetetracarboxylic diimide (abbreviation: PTCDI), or 3,4,9,10-perylenetetracarboxyl-bis-benzimidazole (abbreviation: PTCBI), (C₆₀—Iₕ)[5,6]fullerene (abbreviation: C₆₀), and (C₇₀-D₅ₕ)[5,6]fullerene (abbreviation: C₇₀). It is also possible to use a compound including a heterophane skeleton, which is a cyclophane skeleton having a hetero ring; for example, a phthalocyanine compound such as phthalocyanine (abbreviation: H₂Pc) can be used as the compound. Alternatively, it is possible to use a metal phthalocyanine containing copper, zinc, cobalt, iron, chromium, nickel, or the like or a derivative thereof, such as copper phthalocyanine (abbreviation: CuPc), zinc phthalocyanine (abbreviation: ZnPc), cobalt phthalocyanine (abbreviation: CoPc), iron phthalocyanine (abbreviation: FePc), tin phthalocyanine (abbreviation: SnPc), tin oxide phthalocyanine (abbreviation: SnOPc), titanium oxide phthalocyanine (abbreviation: TiOPc), or vanadium oxide phthalocyanine (abbreviation: VOPc). It is particularly preferable to use a phthalocyanine-based metal complex such as copper phthalocyanine or zinc phthalocyanine or 2,3,8,9,14,15-hexafluorodiquinoxalino[2,3-a:2′,3′-c]phenazine.

The electron-injection buffer layer 119 can be formed using a substance having a high electron-injection property, e.g., an alkali metal, an alkaline earth metal, a rare earth metal, or a compound thereof (an alkali metal compound (including an oxide such as lithium oxide, a halide, and a carbonate such as lithium carbonate or cesium carbonate), an alkaline earth metal compound (including an oxide, a halide, and a carbonate), or a rare earth metal compound (including an oxide, a halide, and a carbonate)).

In the case where the electron-injection buffer layer 119 contains a material having an electron-transport property and a donor substance, the donor substance can be an organic compound such as tetrathianaphthacene (abbreviation: TTN), nickelocene, or decamethylnickelocene, as well as an alkali metal, an alkaline earth metal, a rare earth metal, or a compound thereof (e.g., an alkali metal compound (including an oxide such as lithium oxide, a halide, and a carbonate such as lithium carbonate or cesium carbonate), an alkaline earth metal compound (including an oxide, a halide, and a carbonate), or a rare earth metal compound (including an oxide, a halide, and a carbonate)). As the material having an electron-transport property, a material similar to the above-described material for the electron-transport layer 114 can be used. Alternatively, a layer containing the material having an electron-transport property and a strongly basic substance having an acid dissociation constant pKₐ of 8 or more (e.g., 1,1′-pyridine-2,6-diyl-bis(1,3,4,6,7,8-hexahydro-2H-pyrimido[1,2-a]pyrimidine) (abbreviation: hpp2Py)) may be used.

The second electrode 102 is an electrode including a cathode. The second electrode 102 may have a stacked-layer structure, in which case a layer in contact with the organic compound layer 103 functions as a cathode. For the cathode, a metal, an alloy, an electrically conductive compound, or a mixture thereof each having a low work function (specifically, lower than or equal to 3.8 eV) can be used, for example. Specific examples of such a cathode material include elements belonging to Groups 1 and 2 of the periodic table, such as alkali metals (e.g., lithium (Li) and cesium (Cs)), magnesium (Mg), calcium (Ca), and strontium (Sr), alloys containing these elements (e.g., MgAg and AlLi), compounds containing these elements (e.g., lithium fluoride (LiF), cesium fluoride (CsF), and calcium fluoride (CaF₂)), rare earth metals such as europium (Eu) and ytterbium (Yb), and alloys containing these rare earth metals. However, when the electron-injection layer 115 or a thin film formed using any of the above materials having a low work function is provided between the second electrode 102 and the electron-transport layer, a variety of conductive materials such as Al, Ag, ITO, and indium oxide-tin oxide containing silicon or silicon oxide can be used for the cathode regardless of the work function.

When the second electrode 102 is formed using a material that transmits visible light, the light-emitting device can emit light from the second electrode 102 side.

Films of these conductive materials can be formed by a dry process such as a vacuum evaporation method or a sputtering method, an ink-jet method, a spin coating method, or the like. Alternatively, a wet process using a sol-gel method or a wet process using a paste of a metal material may be employed.

The organic compound layer 103 can be formed by any of a variety of methods, including a dry process and a wet process. For example, a vacuum evaporation method, a gravure printing method, an offset printing method, a screen printing method, an ink-jet method, a spin coating method, or the like may be used.

Different film formation methods may be used to form the electrodes or the layers described above.

Next, an embodiment of a light-emitting device with a structure in which a plurality of light-emitting units are stacked (this type of light-emitting device is also referred to as a stacked or tandem device) is described with reference to FIG. 1C. This light-emitting device includes a plurality of light-emitting units between an anode and a cathode. One light-emitting unit has substantially the same structure as the organic compound layer 103 illustrated in FIG. 1A. In other words, the light-emitting device illustrated in FIG. 1C includes a plurality of light-emitting units, and the light-emitting device illustrated in FIG. 1A or 1B includes a single light-emitting unit.

In FIG. 1C, a first light-emitting unit 511 and a second light-emitting unit 512 are stacked between a first electrode 501 and a second electrode 502, and a charge-generation layer 513 is provided between the first light-emitting unit 511 and the second light-emitting unit 512. The first electrode 501 and the second electrode 502 respectively correspond to the first electrode 101 and the second electrode 102 illustrated in FIG. 1A, and the materials given in the description for FIG. 1A can be used. Furthermore, the first light-emitting unit 511 and the second light-emitting unit 512 may have the same structure or different structures.

The charge-generation layer 513 has a function of injecting electrons into one of the light-emitting units and injecting holes into the other of the light-emitting units when voltage is applied between the first electrode 501 and the second electrode 502. That is, in FIG. 1C, the charge-generation layer 513 injects electrons into the first light-emitting unit 511 and holes into the second light-emitting unit 512 when voltage is applied such that the potential of the anode becomes higher than the potential of the cathode.

The charge-generation layer 513 preferably has a structure similar to that of the charge-generation layer 116 described with reference to FIG. 1B. A composite material of an organic compound and a metal oxide enables low-voltage driving and low-current driving because of having an excellent carrier-injection property and an excellent carrier-transport property. In the case where the anode-side surface of a light-emitting unit is in contact with the charge-generation layer 513, the charge-generation layer 513 can also function as a hole-injection layer of the light-emitting unit; therefore, a hole-injection layer is not necessarily provided in the light-emitting unit.

In the case where the electron-injection buffer layer 119 is provided in the charge-generation layer 513, the electron-injection buffer layer 119 functions as the electron-injection layer in the light-emitting unit on the anode side; thus, an electron-injection layer is not necessarily formed in the light-emitting unit on the anode side.

The light-emitting device having two light-emitting units is described with reference to FIG. 1C; however, one embodiment of the present invention can also be applied to a light-emitting device in which three or more light-emitting units are stacked. With a plurality of light-emitting units partitioned by the charge-generation layer 513 between a pair of electrodes as in the light-emitting device of this embodiment, it is possible to provide a long-life device that can emit light with high luminance at a low current density. A light-emitting apparatus that can be driven at a low voltage and has low power consumption can also be provided.

When the emission colors of the light-emitting units are different, light emission of a desired color can be obtained from the light-emitting device as a whole. For example, in a light-emitting device having two light-emitting units, the emission colors of the first light-emitting unit may be red and green and the emission color of the second light-emitting unit may be blue, so that the light-emitting device can emit white light as the whole.

The organic compound layer 103, the first light-emitting unit 511, the second light-emitting unit 512, the layers such as the charge-generation layer, and the electrodes that are described above can be formed by a method such as an evaporation method (including a vacuum evaporation method), a droplet discharge method (also referred to as an ink-jet method), a coating method, or a gravure printing method. A low molecular material, a middle molecular material (including an oligomer and a dendrimer), or a high molecular material may be included in the above components.

### Embodiment 3

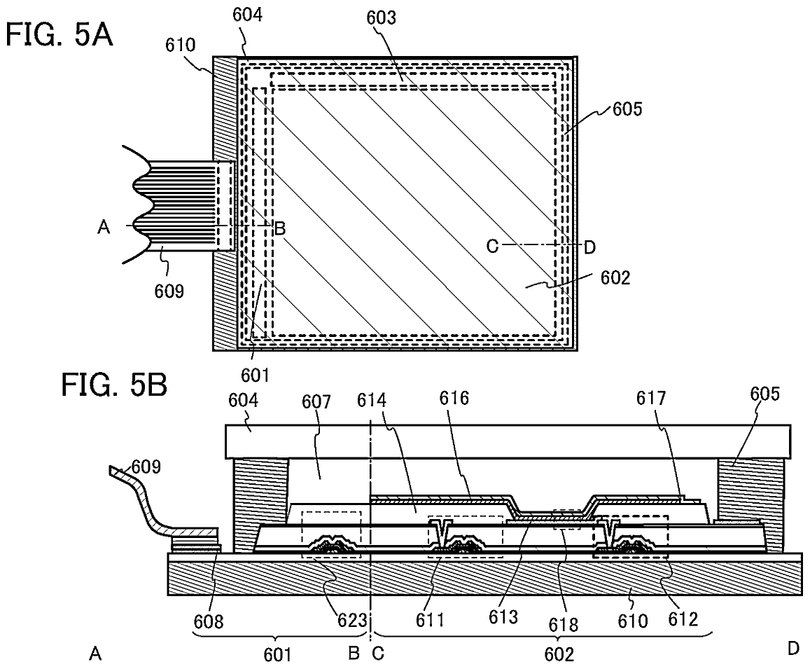

In this embodiment, a display device fabricated using the light-emitting device described in Embodiments 1 and 2 will be described with reference to FIGS. 5A and 5B. FIG. 5A is a top view of the display device and FIG. 5B is a cross-sectional view taken along the lines A-B and C-D in FIG. 5A. This display device includes a driver circuit portion (source line driver circuit) 601, a pixel portion 602, and a driver circuit portion (gate line driver circuit) 603, which are to control light emission of a light-emitting device and illustrated with dotted lines. Reference numeral 604 denotes a sealing substrate; 605, a sealing material; and 607, a space surrounded by the sealing material 605.

Reference numeral 608 denotes a wiring for transmitting signals to be input to the source line driver circuit 601 and the gate line driver circuit 603 and receiving signals such as a video signal, a clock signal, a start signal, and a reset signal from a flexible printed circuit (FPC) 609 serving as an external input terminal. Although only the FPC is illustrated here, a printed wiring board (PWB) may be attached to the FPC. The display device in the present specification includes, in its category, not only the display device itself but also the display device provided with the FPC or the PWB.

Next, a cross-sectional structure is described with reference to FIG. 5B. The driver circuit portions and the pixel portion are formed over an element substrate 610; FIG. 5B illustrates the source line driver circuit 601, which is a driver circuit portion, and one pixel in the pixel portion 602.

The element substrate 610 may be a substrate containing glass, quartz, an organic resin, a metal, an alloy, or a semiconductor or a plastic substrate formed of fiber reinforced plastic (FRP), polyvinyl fluoride (PVF), polyester, or an acrylic resin, for example.

The structure of transistors used in pixels and driver circuits is not particularly limited. For example, inverted staggered transistors may be used, or staggered transistors may be used. Furthermore, top-gate transistors or bottom-gate transistors may be used. A semiconductor material used for the transistors is not particularly limited, and for example, silicon, germanium, silicon carbide, gallium nitride, or the like can be used. Alternatively, an oxide semiconductor containing at least one of indium, gallium, and zinc, such as an In—Ga—Zn-based metal oxide, may be used.

There is no particular limitation on the crystallinity of a semiconductor material used for the transistors, and either an amorphous semiconductor or a semiconductor having crystallinity (a microcrystalline semiconductor, a polycrystalline semiconductor, a single crystal semiconductor, or a semiconductor partly including crystal regions) can be used. It is preferable to use a semiconductor having crystallinity, in which case degradation of transistor characteristics can be inhibited.

Here, an oxide semiconductor is preferably used for semiconductor devices such as the transistors provided in the pixels and driver circuits and transistors used for touch sensors described later, and the like. In particular, an oxide semiconductor having a wider band gap than silicon is preferably used. When an oxide semiconductor having a wider band gap than silicon is used, off-state current of the transistors can be reduced.

The oxide semiconductor preferably contains at least indium (In) or zinc (Zn). Further preferably, the oxide semiconductor contains an oxide represented by an In-M-Zn-based oxide (M represents a metal such as Al, Ti, Ga, Ge, Y, Zr, Sn, La, Ce, or Hf).

As a semiconductor layer, it is particularly preferable to use an oxide semiconductor film including a plurality of crystal parts whose c-axes are aligned perpendicular to a surface on which the semiconductor layer is formed or the top surface of the semiconductor layer and in which the adjacent crystal parts have no grain boundary.

The use of such materials for the semiconductor layer makes it possible to provide a highly reliable transistor in which a change in the electrical characteristics is suppressed.

Charge accumulated in a capacitor through a transistor including the above-described semiconductor layer can be held for a long time because of the low off-state current of the transistor. When such a transistor is used in a pixel, operation of a driver circuit can be stopped while a gray scale of each pixel is maintained. As a result, an electronic device with extremely low power consumption can be obtained.

For stable characteristics of the transistor and the like, a base film is preferably provided. The base film can be formed with a single-layer structure or a stacked-layer structure using an inorganic insulating film such as a silicon oxide film, a silicon nitride film, a silicon oxynitride film, or a silicon nitride oxide film. The base film can be formed by a sputtering method, a chemical vapor deposition (CVD) method (e.g., a plasma CVD method, a thermal CVD method, or a metal organic CVD (MOCVD) method), an atomic layer deposition (ALD) method, a coating method, a printing method, or the like. Note that the base film is not necessarily provided.

Note that an FET 623 is described as a transistor formed in the driver circuit portion 601. In addition, the driver circuit may be formed with any of a variety of circuits such as a CMOS circuit, a PMOS circuit, or an NMOS circuit. Although a driver integrated type in which the driver circuit is formed over the substrate is described in this embodiment, the driver circuit is not necessarily formed over the substrate, and the driver circuit can be formed outside, not over the substrate.

The pixel portion 602 includes a plurality of pixels each including a switching FET 611, a current controlling FET 612, and a first electrode 613 electrically connected to a drain of the current controlling FET 612. One embodiment of the present invention is not limited to the structure. The pixel portion 602 may include three or more FETs and a capacitor in combination.

Note that an insulator 614 is formed to cover an end portion of the first electrode 613. Here, the insulator 614 can be formed using a positive photosensitive acrylic resin film.

In order to improve coverage with an organic compound layer or the like formed later, the insulator 614 is formed to have a curved surface with curvature at its upper or lower end portion. For example, in the case where a positive photosensitive acrylic resin is used as a material of the insulator 614, only the upper end portion of the insulator 614 preferably has a curved surface with a curvature radius (0.2 μm to 3 μm). As the insulator 614, either a negative photosensitive resin or a positive photosensitive resin can be used.

An organic compound layer 616 and a second electrode 617 are formed over the first electrode 613. Here, as a material used for the first electrode 613 functioning as an anode, a material having a high work function is preferably used. For example, a single-layer film of an ITO film, an indium tin oxide film containing silicon, an indium oxide film containing zinc oxide at 2 wt % to 20 wt %, a titanium nitride film, a chromium film, a tungsten film, a Zn film, a Pt film, or the like, a stack of a titanium nitride film and a film containing aluminum as its main component, a stack of three layers of a titanium nitride film, a film containing aluminum as its main component, and a titanium nitride film, or the like can be used. The stacked-layer structure enables low wiring resistance, favorable ohmic contact, and a function as an anode.

The organic compound layer 616 is formed by any of a variety of methods such as an evaporation method using an evaporation mask, an ink-jet method, and a spin coating method. The organic compound layer 616 has the structure described in Embodiments 1 and 2. As another material included in the organic compound layer 616, a low molecular compound or a high molecular compound (including an oligomer or a dendrimer) may be used.

As a material used for the second electrode 617, which is formed over the organic compound layer 616 and functions as a cathode, a material having a low work function (e.g., Al, Mg, Li, and Ca, or an alloy or a compound thereof, such as MgAg, MgIn, and AlLi) is preferably used. In the case where light generated in the organic compound layer 616 is transmitted through the second electrode 617, a stack of a thin metal film and a transparent conductive film (e.g., ITO, indium oxide containing zinc oxide at 2 wt % to 20 wt %, indium tin oxide containing silicon, or zinc oxide (ZnO)) is preferably used for the second electrode 617.

Note that the light-emitting device is formed with the first electrode 613, the organic compound layer 616, and the second electrode 617. The light-emitting device is the light-emitting device described in Embodiments 1 and 2. In the display device of this embodiment, the pixel portion, which includes a plurality of light-emitting devices, may include both the light-emitting device described in Embodiments 1 and 2 and a light-emitting device having another structure.

The sealing substrate 604 is attached to the element substrate 610 with the sealing material 605, so that a light-emitting device 618 is provided in the space 607 surrounded by the element substrate 610, the sealing substrate 604, and the sealing material 605. The space 607 is filled with a filler, and may be filled with an inert gas (such as nitrogen or argon) or the sealing material. The structure of the sealing substrate in which a depressed portion is formed and a desiccant is provided is preferable because deterioration due to the influence of moisture can be inhibited.

An epoxy resin or glass frit is preferably used for the sealing material 605. It is preferable that such a material not be permeable to moisture or oxygen as much as possible. As the sealing substrate 604, a glass substrate, a quartz substrate, or a plastic substrate formed of fiber reinforced plastic (FRP), polyvinyl fluoride (PVF), polyester, or an acrylic resin can be used.

Although not illustrated in FIGS. 5A and 5B, a protective film may be provided over the second electrode. As the protective film, an organic resin film or an inorganic insulating film may be formed. The protective film may be formed to cover an exposed portion of the sealing material 605. The protective film may be provided to cover surfaces and side surfaces of the pair of substrates and exposed side surfaces of a sealing layer, an insulating layer, and the like.

The protective film can be formed using a material that does not easily transmit an impurity such as water. Thus, diffusion of an impurity such as water from the outside into the inside can be effectively suppressed.

As a material of the protective film, an oxide, a nitride, a fluoride, a sulfide, a ternary compound, a metal, a polymer, or the like can be used. For example, the material may contain aluminum oxide, hafnium oxide, hafnium silicate, lanthanum oxide, silicon oxide, strontium titanate, tantalum oxide, titanium oxide, zinc oxide, niobium oxide, zirconium oxide, tin oxide, yttrium oxide, cerium oxide, scandium oxide, erbium oxide, vanadium oxide, indium oxide, aluminum nitride, hafnium nitride, silicon nitride, tantalum nitride, titanium nitride, niobium nitride, molybdenum nitride, zirconium nitride, gallium nitride, a nitride containing titanium and aluminum, an oxide containing titanium and aluminum, an oxide containing aluminum and zinc, a sulfide containing manganese and zinc, a sulfide containing cerium and strontium, an oxide containing erbium and aluminum, an oxide containing yttrium and zirconium, or the like.

The protective film is preferably formed by a film formation method that offers good step coverage. One such method is an atomic layer deposition (ALD) method. A material that can be deposited by an ALD method is preferably used for the protective film. A dense protective film having reduced defects such as cracks or pinholes or a uniform thickness can be formed by an ALD method. Furthermore, damage caused to a process member in forming the protective film can be reduced.

By an ALD method, a uniform protective film with few defects can be formed even on, for example, a surface with a complex uneven shape or upper, side, and lower surfaces of a touch panel.

As described above, the display device fabricated using the light-emitting device described in Embodiments 1 and 2 can be obtained.

The display device in this embodiment is fabricated using the light-emitting device described in Embodiments 1 and 2 and thus can have excellent characteristics. Specifically, since the light-emitting device described in Embodiments 1 and 2 has high emission efficiency, the display device can achieve low power consumption. Since the light-emitting device described in Embodiments 1 and 2 has high reliability, the display device can be highly reliable. In addition, since the light-emitting device described in Embodiments 1 and 2 can have favorable chromaticity and high color purity, the display device can achieve high display quality.

This embodiment can be freely combined with any of the other embodiments.

### Embodiment 4

As illustrated in FIGS. 6A and 6B, a plurality of light-emitting devices 130 are formed over an insulating layer 175 to constitute a display device. In this embodiment, the display device of another embodiment of the present invention will be described in detail.

A display device 100 includes a pixel portion 177 in which a plurality of pixels 178 are arranged in a matrix. The pixels 178 each include a subpixel 110R, a subpixel 110G, and a subpixel 110B.

In this specification and the like, for example, description common to the subpixels 110R, 110G, and 110B is sometimes made using the collective term “subpixel 110”. As for other components that are distinguished from each other using letters of the alphabet, matters common to the components are sometimes described using reference numerals excluding the letters of the alphabet.

The subpixel 110R emits red light, the subpixel 110G emits green light, and the subpixel 110B emits blue light. Thus, an image can be displayed on the pixel portion 177. Note that in this embodiment, three colors of red (R), green (G), and blue (B) are given as examples of colors of light emitted from the subpixels; however, subpixels of a different combination of colors may be employed. The number of subpixels is not limited to three, and may be four or more. Examples of four subpixels include subpixels emitting light of four colors of R, G, B, and white (W), subpixels emitting light of four colors of R, G, B, and Y, and four subpixels emitting light of R, G, and B and infrared light (IR).

In this specification and the like, the row direction and the column direction are sometimes referred to as the X direction and the Y direction, respectively. The X direction and the Y direction intersect with each other and are perpendicular to each other, for example.

FIG. 6A illustrates an example in which subpixels of different colors are arranged in the X direction and subpixels of the same color are arranged in the Y direction. Note that subpixels of different colors may be arranged in the Y direction, and subpixels of the same color may be arranged in the X direction.

Outside the pixel portion 177, a connection portion 140 is provided and a region 141 may also be provided. In the case where the region 141 is provided, the region 141 is provided between the pixel portion 177 and the connection portion 140. In the case where the region 141 is provided, the organic compound layer 103 is provided in the region 141. A conductive layer 151C is provided in the connection portion 140.

Although FIG. 6A illustrates an example in which the region 141 and the connection portion 140 are positioned on the right side of the pixel portion 177, the positions of the region 141 and the connection portion 140 are not particularly limited. The number of regions 141 and the number of connection portions 140 can each be one or more.

FIG. 6B is an example of a cross-sectional view along the dashed-dotted line A1-A2 in FIG. 6A. As illustrated in FIG. 6B, the display device 100 includes an insulating layer 171, a conductive layer 172 over the insulating layer 171, an insulating layer 173 over the insulating layer 171 and the conductive layer 172, an insulating layer 174 over the insulating layer 173, and the insulating layer 175 over the insulating layer 174. The insulating layer 171 is provided over a substrate (not illustrated). An opening reaching the conductive layer 172 is provided in the insulating layers 175, 174, and 173, and a plug 176 is provided to fill the opening.

In the pixel portion 177, the light-emitting device 130 is provided over the insulating layer 175 and the plug 176. A protective layer 131 is provided to cover the light-emitting device 130. A substrate 120 is bonded to the protective layer 131 with a resin layer 122. An inorganic insulating layer 125 and an insulating layer 127 over the inorganic insulating layer 125 are preferably provided between the adjacent light-emitting devices 130.

Although each of the inorganic insulating layer 125 and the insulating layer 127 looks like a plurality of layers in the cross-sectional view in FIG. 6B, each of the inorganic insulating layer 125 and the insulating layer 127 is preferably one continuous layer when the display device 100 is seen from above.

In FIG. 6B, a light-emitting device 130R, a light-emitting device 130G, and a light-emitting device 130B are illustrated as the light-emitting devices 130. The light-emitting devices 130R, 130G, and 130B emit light of different colors. For example, the light-emitting device 130R can emit red light, the light-emitting device 130G can emit green light, and the light-emitting device 130B can emit blue light. Alternatively, the light-emitting device 130R, the light-emitting device 130G, or the light-emitting device 130B may emit visible light of another color or infrared light.

The display device of one embodiment of the present invention can be, for example, a top-emission display device where light is emitted in the direction opposite to a substrate over which light-emitting devices are formed. Note that the display device of one embodiment of the present invention may be of a bottom emission type.

The light-emitting device 130R includes a first electrode (pixel electrode) 101R including a conductive layer 151R and a conductive layer 152R, an organic compound layer 103R over the first electrode, a common layer 104 over the organic compound layer 103R, and the second electrode (common electrode) 102 over the common layer. Although the common layer 104 is not necessarily provided, it is preferable to provide the common layer 104 to reduce damage to the organic compound layer 103R during processing.

The light-emitting device 130G includes a first electrode (pixel electrode) 101G including a conductive layer 151G and a conductive layer 152G, an organic compound layer 103G over the first electrode, the common layer 104 over the organic compound layer 103G, and the second electrode (common electrode) 102 over the common layer. Although the common layer 104 is not necessarily provided, it is preferable to provide the common layer 104 to reduce damage to the organic compound layer 103G during processing.

The light-emitting device 130B has a structure as described in Embodiments 1 and 2. The light-emitting device 130B includes a first electrode (pixel electrode) 101B including a conductive layer 151B and a conductive layer 152B, an organic compound layer 103B over the first electrode, the common layer 104 over the organic compound layer 103B, and the second electrode (common electrode) 102 over the common layer. Although the common layer 104 is not necessarily provided, it is preferable to provide the common layer 104 to reduce damage to the organic compound layer 103B during processing. In the case where the common layer 104 is provided, a stack of the organic compound layer 103B and the common layer 104 corresponds to the organic compound layer 103 described in Embodiments 1 and 2.

Note that the common layer 104 is preferably an electron-injection layer or an electron-transport layer, further preferably an electron-injection layer. In the case of an electron-transport layer, the electron-transport layer preferably has a stacked-layer structure. It is further preferable that a layer on the second electrode side among the stacked layers be the common layer 104 and a layer on the light-emitting layer side among the stacked layers be the organic compound layer 103.

Since the light-emitting device 130R and the light-emitting device 130G are fabricated through a photolithography process, the above structure can inhibit an increase in driving voltage due to the photolithography process so that the light-emitting devices can have low driving voltage.

In the light-emitting device 130, one of the pixel electrode and the common electrode functions as an anode and the other functions as a cathode. Hereinafter, description is made on the assumption that the pixel electrode functions as the anode and the common electrode functions as the cathode unless otherwise specified.

The organic compound layers 103R, 103G, and 103B are island-shaped layers that are independent of each other on a light-emitting device basis or on an emission color basis. Providing the island-shaped organic compound layer 103 in each of the light-emitting devices 130 can suppress leakage current between the adjacent light-emitting devices 130 even in a high-resolution display device. This can prevent crosstalk, so that a display device with extremely high contrast can be obtained. Specifically, a display device having high current efficiency at low luminance can be obtained.

The island-shaped organic compound layer 103 is formed by forming an organic compound film and processing the organic compound film by a photolithography method.

The organic compound layer 103 is preferably provided to cover the top surface and the side surface of the first electrode (pixel electrode) of the light-emitting device 130. In that case, the aperture ratio of the display device 100 can be easily increased as compared to the structure in which an end portion of the organic compound layer 103 is positioned inward from an end portion of the pixel electrode. Covering the side surface of the pixel electrode of the light-emitting device 130 with the organic compound layer 103 can inhibit the pixel electrode from being in contact with the second electrode 102; hence, a short circuit of the light-emitting device 130 can be inhibited.

In the display device of one embodiment of the present invention, the first electrode (pixel electrode) of the light-emitting device preferably has a stacked-layer structure. For example, in the example illustrated in FIG. 6B, the first electrode of the light-emitting device 130 is a stack of the conductive layer 151 and the conductive layer 152.

A metal material can be used for the conductive layer 151, for example. Specifically, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals, for example.

For the conductive layer 152, an oxide containing one or more selected from indium, tin, zinc, gallium, titanium, aluminum, and silicon can be used. For example, it is preferable to use a conductive oxide containing one or more of indium oxide, indium tin oxide, indium zinc oxide, zinc oxide, zinc oxide containing gallium, titanium oxide, indium zinc oxide containing gallium, indium zinc oxide containing aluminum, indium tin oxide containing silicon, indium zinc oxide containing silicon, and the like. In particular, indium tin oxide containing silicon can be suitably used for the conductive layer 152 because of having a work function higher than or equal to 4.0 eV, for example.

The conductive layer 151 and the conductive layer 152 may each be a stack of a plurality of layers containing different materials. In that case, the conductive layer 151 may include a layer formed using a material that can be used for the conductive layer 152, such as a conductive oxide. Furthermore, the conductive layer 152 may include a layer formed using a material that can be used for the conductive layer 151, such as a metal material. In the case where the conductive layer 151 is a stack of two or more layers, for example, a layer in contact with the conductive layer 152 can be formed using a material that can be used for the conductive layer 152.

The conductive layer 151 preferably has a tapered side surface. Specifically, the side surface of the conductive layer 151 preferably has a tapered shape with a taper angle less than 90°. In that case, the conductive layer 152 provided along the side surface of the conductive layer 151 also has a tapered shape. When the side surface of the conductive layer 152 has a tapered shape, coverage with the organic compound layer 103 provided along the side surface of the conductive layer 152 can be improved.

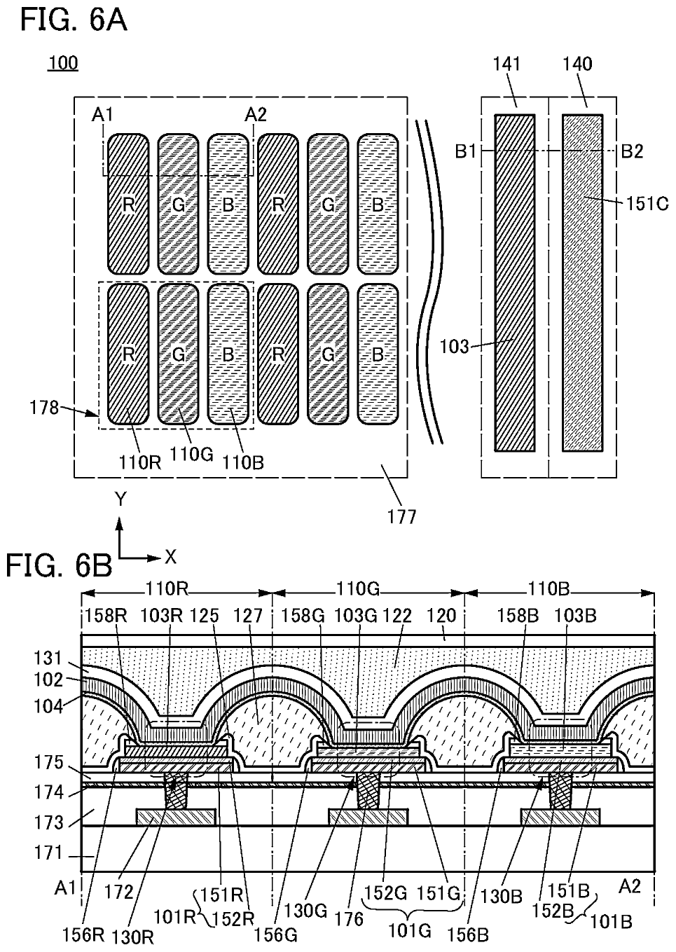

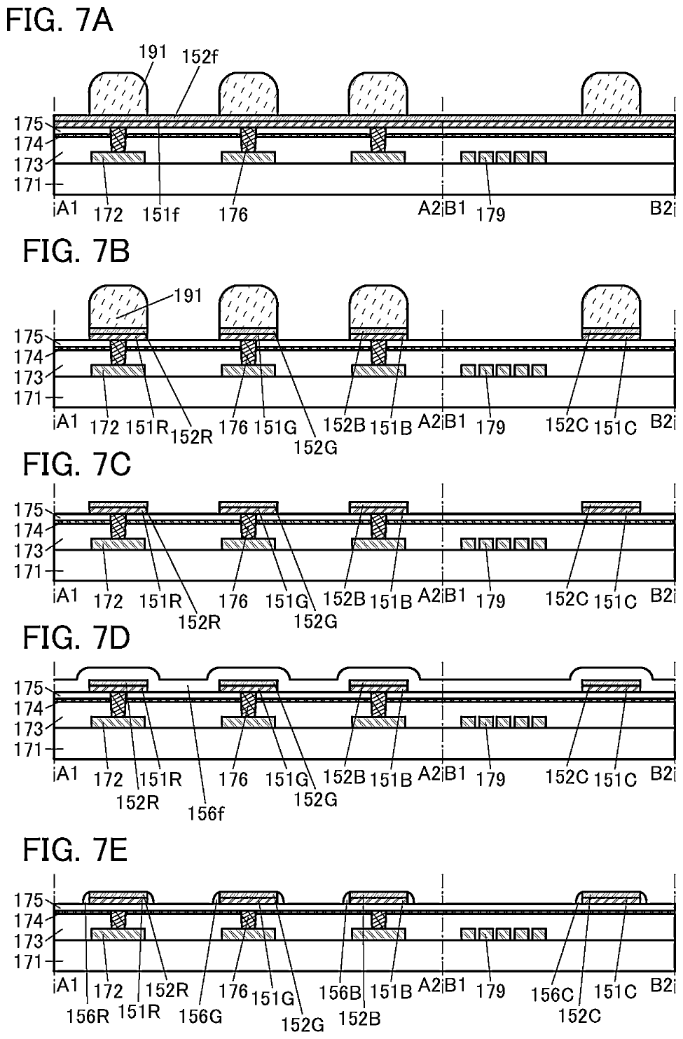

Next, an exemplary method for fabricating the display device 100 having the structure illustrated in FIG. 6A is described with reference to FIGS. 7A to 7E, FIGS. 8A and 8B, FIGS. 9A to 9D, FIGS. 10A to 10C, FIGS. 11A to 11C, and FIGS. 12A to 12C.

### [Fabrication Method Example]

Thin films included in the display device (e.g., insulating films, semiconductor films, and conductive films) can be formed by a sputtering method, a chemical vapor deposition (CVD) method, a vacuum evaporation method, a pulsed laser deposition (PLD) method, an ALD method, or the like.

Thin films included in the display device (e.g., insulating films, semiconductor films, and conductive films) can also be formed by a wet process such as spin coating, dipping, spray coating, ink-jetting, dispensing, screen printing, offset printing, doctor blade coating, slit coating, roll coating, curtain coating, or knife coating.

Thin films included in the display device can be processed by a photolithography method, for example.

As light used for exposure in the photolithography method, for example, light with an i-line (wavelength: 365 nm), light with a g-line (wavelength: 436 nm), light with an h-line (wavelength: 405 nm), or light in which the i-line, the g-line, and the h-line are mixed can be used. Alternatively, ultraviolet rays, KrF laser light, ArF laser light, or the like can be used. Exposure may be performed by liquid immersion exposure technique. As the light for exposure, extreme ultraviolet (EUV) light or X-rays may also be used. Furthermore, instead of the light used for the exposure, an electron beam can also be used.

For etching of thin films, a dry etching method, a wet etching method, a sandblast method, or the like can be used.

First, as illustrated in FIG. 7A, the insulating layer 171 is formed over a substrate (not illustrated). Next, the conductive layer 172 and a conductive layer 179 are formed over the insulating layer 171, and the insulating layer 173 is formed over the insulating layer 171 to cover the conductive layer 172 and the conductive layer 179. Then, the insulating layer 174 is formed over the insulating layer 173, and the insulating layer 175 is formed over the insulating layer 174.

As the substrate, a substrate that has heat resistance high enough to withstand at least heat treatment performed later can be used. For example, it is possible to use a glass substrate; a quartz substrate; a sapphire substrate; a ceramic substrate; an organic resin substrate; or a semiconductor substrate such as a single crystal semiconductor substrate or a polycrystalline semiconductor substrate of silicon, silicon carbide, or the like, a compound semiconductor substrate of silicon germanium or the like, or an SOI substrate.

Next, as illustrated in FIG. 7A, openings reaching the conductive layer 172 are formed in the insulating layers 175, 174, and 173. Then, the plugs 176 are formed to fill the openings.

Next, as illustrated in FIG. 7A, a conductive film 151f to be the conductive layers 151R, 151G, 151B, and 151C and a conductive film 152f to be the conductive layers 152R, 152G, 152B, and 152C are formed over the plugs 176 and the insulating layer 175. A metal material can be used for the conductive film 151f, for example. For the conductive film 152f, an oxide containing one or more selected from indium, tin, zinc, gallium, titanium, aluminum, and silicon can be used, for example.

Then, a resist mask 191 is formed over the conductive film 152f as illustrated in FIG. 7A. The resist mask 191 can be formed by application of a photosensitive material (photoresist), light exposure, and development.

Subsequently, as illustrated in FIG. 7B, the conductive films 151f and 152f in a region not overlapping with the resist mask 191 are removed, for example. In this manner, the conductive layers 151 and 152 are formed.

Next, the resist mask 191 is removed as illustrated in FIG. 7C. The resist mask 191 can be removed by ashing using oxygen plasma, for example.

Then, as illustrated in FIG. 7D, an insulating film 156f to be an insulating layer 156R, an insulating layer 156G, an insulating layer 156B, and an insulating layer 156C is formed over the conductive layers 152R, 152G, 152B, and 152C and the insulating layer 175.

As the insulating film 156f, an inorganic insulating film such as an oxide insulating film, a nitride insulating film, an oxynitride insulating film, or a nitride oxide insulating film, e.g., silicon oxynitride, can be used.

Subsequently, as illustrated in FIG. 7E, the insulating film 156f is processed to form the insulating layers 156R, 156G, 156B, and 156C.

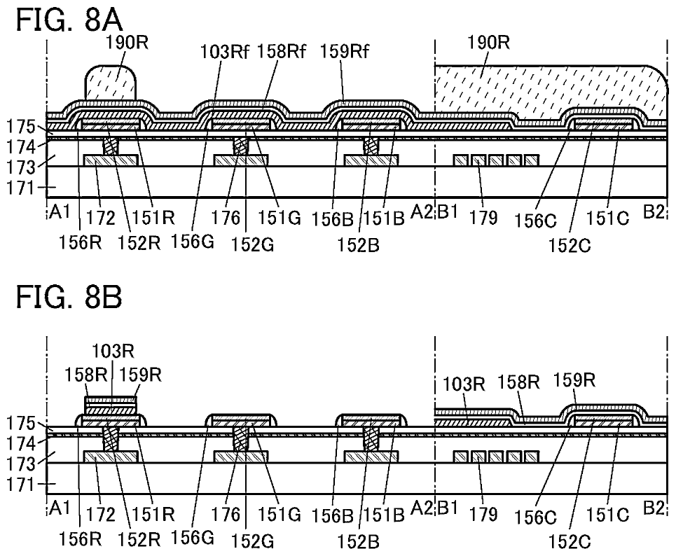

Next, as illustrated in FIG. 8A, an organic compound film 103Rf is formed over the conductive layers 152R, 152G, and 152B and the insulating layer 175. As illustrated in FIG. 8A, the organic compound film 103Rf is not formed over the conductive layer 152C.

Then, as illustrated in FIG. 8A, a sacrificial film 158Rf and a mask film 159Rf are formed.

Providing the sacrificial film 158Rf over the organic compound film 103Rf can reduce damage to the organic compound film 103Rf in the fabrication process of the display device, resulting in an increase in the reliability of the light-emitting device.

As the sacrificial film 158Rf, a film that is highly resistant to the process conditions for the organic compound film 103Rf, specifically, a film having high etching selectivity with respect to the organic compound film 103Rf is used. As the mask film 159Rf, a film having high etching selectivity with respect to the sacrificial film 158Rf is used.

The sacrificial film 158Rf and the mask film 159Rf are formed at a temperature lower than the upper temperature limit of the organic compound film 103Rf. The typical substrate temperatures in formation of the sacrificial film 158Rf and the mask film 159Rf are each higher than or equal to 100° C. and lower than or equal to 200° C., preferably higher than or equal to 100° C. and lower than or equal to 150° C., further preferably higher than or equal to 100° C. and lower than or equal to 120° C.

The sacrificial film 158Rf and the mask film 159Rf are preferably films that can be removed by a wet etching method or a dry etching method.

Note that the sacrificial film 158Rf that is formed over and in contact with the organic compound film 103Rf is preferably formed by a formation method that is less likely to damage the organic compound film 103Rf than a formation method of the mask film 159Rf. For example, the sacrificial film 158Rf is preferably formed by an ALD method or a vacuum evaporation method rather than a sputtering method.

As each of the sacrificial film 158Rf and the mask film 159Rf, one or more of a metal film, an alloy film, a metal oxide film, a semiconductor film, an organic insulating film, and an inorganic insulating film, for example, can be used.

For each of the sacrificial film 158Rf and the mask film 159Rf, a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials can be used, for example. It is particularly preferable to use a low-melting-point material such as aluminum or silver. It is preferable to use a metal material that can block ultraviolet rays for one or both of the sacrificial film 158Rf and the mask film 159Rf, in which case the organic compound film 103Rf can be inhibited from being irradiated with ultraviolet rays in patterning light exposure and thus deterioration of the organic compound film 103Rf can be inhibited.

The sacrificial film 158Rf and the mask film 159Rf can each be formed using a metal oxide such as an In—Ga—Zn oxide, an indium oxide, an In—Zn oxide, an In—Sn oxide, an indium titanium oxide (In—Ti oxide), an indium tin zinc oxide (In—Sn—Zn oxide), an indium titanium zinc oxide (In—Ti—Zn oxide), an indium gallium tin zinc oxide (In—Ga—Sn—Zn oxide), or an indium tin oxide containing silicon.

In the above metal oxide, in place of gallium, an element M (M is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used.

The sacrificial film 158Rf and the mask film 159Rf are preferably formed using a semiconductor material such as silicon or germanium for excellent compatibility with a semiconductor manufacturing process, for example. Alternatively, a compound containing the above semiconductor material can be used.

As each of the sacrificial film 158Rf and the mask film 159Rf, any of a variety of inorganic insulating films can be used. In particular, an oxide insulating film is preferable because its adhesion to the organic compound film 103Rf is higher than that of a nitride insulating film.

Subsequently, a resist mask 190R is formed as illustrated in FIG. 8A. The resist mask 190R can be formed by application of a photosensitive material (photoresist), light exposure, and development.

The resist mask 190R is provided at a position overlapping with the conductive layer 152R. The resist mask 190R is preferably provided also at a position overlapping with the conductive layer 152C. This can inhibit the conductive layer 152C from being damaged during the process of fabricating the display device.

Next, as illustrated in FIG. 8B, part of the mask film 159Rf is removed using the resist mask 190R, whereby a mask layer 159R is formed. The mask layer 159R remains over the conductive layers 152R and 152C. After that, the resist mask 190R is removed. Then, part of the sacrificial film 158Rf is removed using the mask layer 159R as a mask (also referred to as a hard mask), whereby a sacrificial layer 158R is formed.

The use of a wet etching method can reduce damage to the organic compound film 103Rf in processing of the sacrificial film 158Rf and the mask film 159Rf, as compared to the case of using a dry etching method. In the case of using a wet etching method, it is preferable to use a developer, an alkaline aqueous solution such as a tetramethylammonium hydroxide (TMAH) aqueous solution, or an acid aqueous solution such as dilute hydrofluoric acid, oxalic acid, phosphoric acid, acetic acid, nitric acid, or a chemical solution containing a mixed solution of any of these acids, for example.

In the case of using a dry etching method to process the sacrificial film 158Rf, deterioration of the organic compound film 103Rf can be inhibited by not using a gas containing oxygen as the etching gas.

The resist mask 190R can be removed by a method similar to that for the resist mask 191.

Next, as illustrated in FIG. 8B, the organic compound film 103Rf is processed to form the organic compound layer 103R. For example, part of the organic compound film 103Rf is removed using the mask layer 159R and the sacrificial layer 158R as a hard mask, whereby the organic compound layer 103R is formed.

Accordingly, as illustrated in FIG. 8B, the stacked-layer structure of the organic compound layer 103R, the sacrificial layer 158R, and the mask layer 159R remains over the conductive layer 152R. The conductive layers 152G and 152B are exposed.

The organic compound film 103Rf is preferably processed by anisotropic etching. Anisotropic dry etching is particularly preferable. Alternatively, wet etching may be used.

In the case of using a dry etching method, deterioration of the organic compound film 103Rf can be inhibited by not using a gas containing oxygen as the etching gas.

A gas containing oxygen may be used as the etching gas. When the etching gas contains oxygen, the etching rate can be increased. Thus, the etching can be performed under a low-power condition while an adequately high etching rate is maintained. Accordingly, damage to the organic compound film 103Rf can be reduced. Furthermore, a defect such as attachment of a reaction product generated during the etching can be inhibited.

In the case of using a dry etching method, it is preferable to use a gas containing at least one of H₂, CF₄, C₄F₈, SF₆, CHF₃, Cl₂, H₂O, BCl₃, and a Group 18 element such as He or Ar as the etching gas, for example. Alternatively, a gas containing oxygen and at least one of the above is preferably used as the etching gas. Alternatively, an oxygen gas may be used as the etching gas.

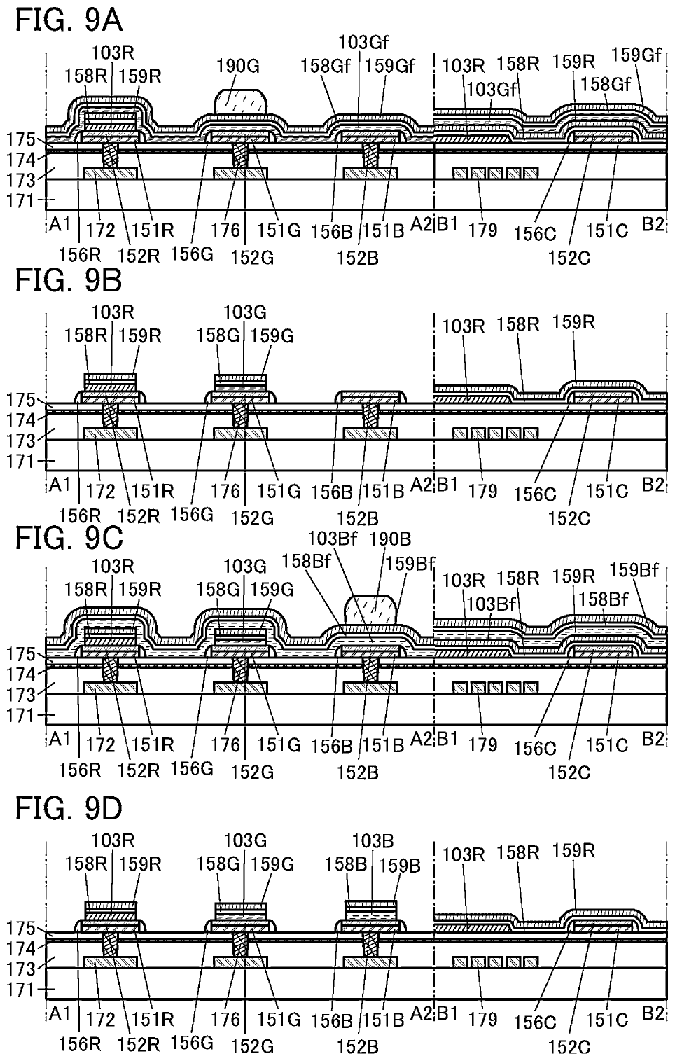

Then, as illustrated in FIG. 9A, an organic compound film 103Gf to be the organic compound layer 103G is formed.

The organic compound film 103Gf can be formed by a method similar to that for forming the organic compound film 103Rf. The organic compound film 103Gf can have a structure similar to that of the organic compound film 103Rf.

Subsequently, as illustrated in FIG. 9A, a sacrificial film 158Gf and a mask film 159Gf are formed in this order. After that, a resist mask 190G is formed. The materials and the formation methods of the sacrificial film 158Gf and the mask film 159Gf are similar to those for the sacrificial film 158Rf and the mask film 159Rf. The material and the formation method of the resist mask 190G are similar to those for the resist mask 190R.

The resist mask 190G is provided at a position overlapping with the conductive layer 152G.

Subsequently, as illustrated in FIG. 9B, part of the mask film 159Gf is removed using the resist mask 190G, whereby a mask layer 159G is formed. The mask layer 159G remains over the conductive layer 152G. After that, the resist mask 19OG is removed. Then, part of the sacrificial film 158Gf is removed using the mask layer 159G as a mask, whereby a sacrificial layer 158G is formed. Next, the organic compound film 103Gf is processed to form the organic compound layer 103G.

Then, an organic compound film 103Bf is formed as illustrated in FIG. 9C.

The organic compound film 103Bf can be formed by a method similar to that for forming the organic compound film 103Rf. The organic compound film 103Bf can have a structure similar to that of the organic compound film 103Rf.

Subsequently, a sacrificial film 158Bf and a mask film 159Bf are formed in this order as illustrated in FIG. 9C. After that, a resist mask 190B is formed. The materials and the formation methods of the sacrificial film 158Bf and the mask film 159Bf are similar to those for the sacrificial film 158Rf and the mask film 159Rf. The material and the formation method of the resist mask 190B are similar to those for the resist mask 190R.

The resist mask 190B is provided at a position overlapping with the conductive layer 152B.

Subsequently, as illustrated in FIG. 9D, part of the mask film 159Bf is removed using the resist mask 190B, whereby a mask layer 159B is formed. The mask layer 159B remains over the conductive layer 152B. After that, the resist mask 190B is removed. Then, part of the sacrificial film 158Bf is removed using the mask layer 159B as a mask, whereby a sacrificial layer 158B is formed. Next, the organic compound film 103Bf is processed to form the organic compound layer 103B. For example, part of the organic compound film 103Bf is removed using the mask layer 159B and the sacrificial layer 158B as a hard mask, whereby the organic compound layer 103B is formed.

Accordingly, as illustrated in FIG. 9D, the stacked-layer structure of the organic compound layer 103B, the sacrificial layer 158B, and the mask layer 159B remains over the conductive layer 152B. The mask layers 159R and 159G are exposed.

Note that the side surfaces of the organic compound layers 103R, 103G, and 103B are preferably perpendicular or substantially perpendicular to their formation surfaces. For example, the angle between the formation surfaces and these side surfaces is preferably greater than or equal to 60° and less than or equal to 90°.

The distance between two adjacent layers among the organic compound layers 103R, 103G, and 103B, which are formed by a photolithography method as described above, can be reduced to less than or equal to 8 μm, less than or equal to 5 μm, less than or equal to 3 μm, less than or equal to 2 μm, or less than or equal to 1 μm. Here, the distance can be specified, for example, by a distance between opposite end portions of two adjacent layers among the organic compound layers 103R, 103G, and 103B. Reducing the distance between the island-shaped organic compound layers makes it possible to provide a display device having high resolution and a high aperture ratio. In addition, the distance between the first electrodes of adjacent light-emitting devices can also be shortened to for example, less than or equal to 10 μm, less than or equal to 8 μm, less than or equal to 5 μm, less than or equal to 3 μm, or less than or equal to 2 μm. Note that the distance between the first electrodes of adjacent light-emitting devices is preferably greater than or equal to 2 μm and less than or equal to 5 μm.

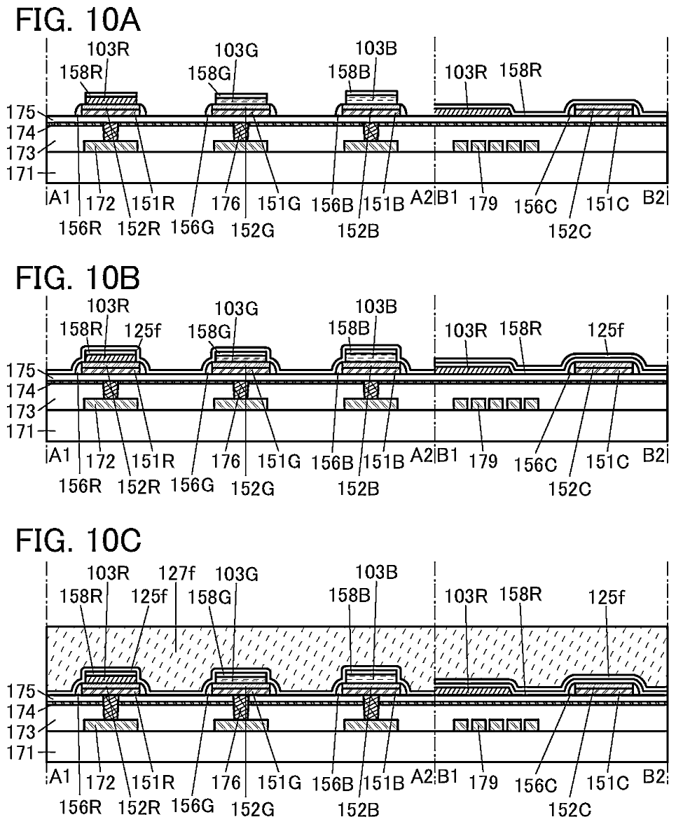

Next, as illustrated in FIG. 10A, the mask layers 159R, 159G, and 159B are preferably removed.

The step of removing the mask layers can be performed by a method similar to that for the step of processing the mask films. Specifically, by using a wet etching method, damage to the organic compound layer 103 at the time of removing the mask layers can be reduced as compared to the case of using a dry etching method.

The mask layers may be removed by being dissolved in a polar solvent such as water or an alcohol. Examples of an alcohol include ethyl alcohol, methyl alcohol, isopropyl alcohol (IPA), and glycerin.

After the mask layers are removed, drying treatment may be performed in order to remove water adsorbed on surfaces. For example, heat treatment in an inert gas atmosphere or a reduced-pressure atmosphere can be performed. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. The heat treatment is preferably performed in a reduced-pressure atmosphere, in which case drying at a lower temperature is possible.

Next, an inorganic insulating film 125f is formed as illustrated in FIG. 10B.

Then, as illustrated in FIG. 10C, an insulating film 127f to be the insulating layer 127 is formed over the inorganic insulating film 125f.

The substrate temperature at the time of forming the inorganic insulating film 125f and the insulating film 127f is preferably higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C.

As the inorganic insulating film 125f, an insulating film having a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm is preferably formed.

The inorganic insulating film 125f is preferably formed by an ALD method, for example. An ALD method is preferably used, in which case damage due to film formation is reduced and a film with good coverage can be formed. As the inorganic insulating film 125f, an aluminum oxide film is preferably formed by an ALD method, for example.

The insulating film 127f is preferably formed by the aforementioned wet process. The insulating film 127f is preferably formed by spin coating using a photosensitive material, for example, and specifically preferably formed using a photosensitive resin composition containing an acrylic resin.

Then, part of the insulating film 127f is exposed to visible light or ultraviolet rays. The insulating layer 127 is formed in regions that are interposed between any two of the conductive layers 152R, 152G, and 152B and around the conductive layer 152C.

The width of the insulating layer 127 formed later can be controlled in accordance with the exposed region of the insulating film 127f. In this embodiment, processing is performed such that the insulating layer 127 includes a portion overlapping with the top surface of the conductive layer 151.

Light used for the exposure preferably includes the i-line (wavelength: 365 nm). Furthermore, light used for the exposure may include at least one of the g-line (wavelength: 436 nm) and the h-line (wavelength: 405 nm).

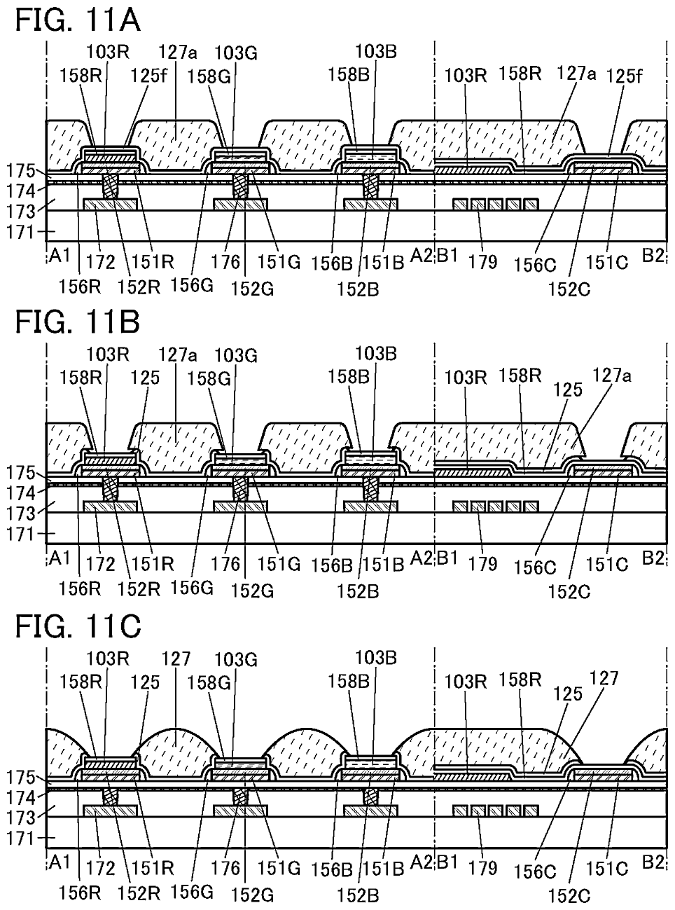

Next, as illustrated in FIG. 11A, development is performed to remove the exposed region of the insulating film 127f, whereby an insulating layer 127a is formed.

Next, as illustrated in FIG. 11B, etching treatment is performed using the insulating layer 127a as a mask to remove part of the inorganic insulating film 125f and reduce the thickness of part of the sacrificial layers 158R, 158G, and 158B. Thus, the inorganic insulating layer 125 is formed under the insulating layer 127a. Moreover, the surfaces of the thin portions in the sacrificial layers 158R, 158G, and 158B are exposed. Note that the etching treatment using the insulating layer 127a as a mask may be hereinafter referred to as first etching treatment.

The first etching treatment can be performed by dry etching or wet etching. Note that the inorganic insulating film 125f is preferably formed using a material similar to that of the sacrificial layers 158R, 158G, and 158B, in which case the first etching treatment can be performed concurrently.

In the case of performing dry etching, a chlorine-based gas is preferably used. As the chlorine-based gas, one of Cl₂, BCl₃, SiCl₄, CCl₄, and the like or a mixture of two or more of them can be used. Moreover, one of an oxygen gas, a hydrogen gas, a helium gas, an argon gas, and the like or a mixture of two or more of them can be added as appropriate to the chlorine-based gas. By the dry etching, the thin regions of the sacrificial layers 158R, 158G, and 158B can be formed with favorable in-plane uniformity.

As a dry etching apparatus, a dry etching apparatus including a high-density plasma source can be used. As the dry etching apparatus including a high-density plasma source, an inductively coupled plasma (ICP) etching apparatus can be used, for example. Alternatively, a capacitively coupled plasma (CCP) etching apparatus including parallel plate electrodes can be used.

The first etching treatment is preferably performed by wet etching. The use of a wet etching method can reduce damage to the organic compound layers 103R, 103G, and 103B, as compared to the case of using a dry etching method. Wet etching can be performed using, for example, an alkaline solution. For instance, a TMAH aqueous solution, which is an alkaline solution, can be used for the wet etching of an aluminum oxide film. Alternatively, an acid solution containing fluoride can be used. In that case, puddle wet etching can be performed. Note that the inorganic insulating film 125f is preferably formed using a material similar to that of the sacrificial layers 158R, 158G, and 158B, in which case the above etching treatment can be performed concurrently.

The sacrificial layers 158R, 158G, and 158B are not completely removed by the first etching treatment, and the etching treatment is stopped when the thicknesses of the sacrificial layers 158R, 158G, and 158B are reduced. The sacrificial layers 158R, 158G, and 158B remain over the corresponding organic compound layers 103R, 103G, and 103B in this manner, whereby the organic compound layers 103R, 103G, and 103B can be prevented from being damaged by treatment in a later step.

Next, light exposure is preferably performed on the entire substrate so that the insulating layer 127a is irradiated with visible light or ultraviolet rays. The energy density for the light exposure is preferably greater than 0 mJ/cm² and less than or equal to 800 mJ/cm², further preferably greater than 0 mJ/cm² and less than or equal to 500 mJ/cm². Performing such light exposure after the development can sometimes increase the degree of transparency of the insulating layer 127a. In addition, it is sometimes possible to lower the substrate temperature required for subsequent heat treatment for changing the shape of the insulating layer 127a into a tapered shape.

Here, when a barrier insulating layer against oxygen (e.g., an aluminum oxide film) exists as each of the sacrificial layers 158R, 158G, and 158B, diffusion of oxygen to the organic compound layers 103R, 103G, and 103B can be inhibited.

Then, heat treatment (also referred to as post-baking) is performed. The heat treatment can change the insulating layer 127a into the insulating layer 127 having a tapered side surface (FIG. 11C). The heat treatment is performed at a temperature lower than the upper temperature limit of the organic compound layer. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 130° C. The heating atmosphere may be an air atmosphere or an inert gas atmosphere. Moreover, the heating atmosphere may be an atmospheric-pressure atmosphere or a reduced-pressure atmosphere. Accordingly, adhesion between the insulating layer 127 and the inorganic insulating layer 125 can be improved, and corrosion resistance of the insulating layer 127 can be increased.

When the sacrificial layers 158R, 158G, and 158B are not completely removed by the first etching treatment and the thinned sacrificial layers 158R, 158G, and 158B are left, the organic compound layers 103R, 103G, and 103B can be prevented from being damaged and deteriorating in the heat treatment. This increases the reliability of the light-emitting devices.

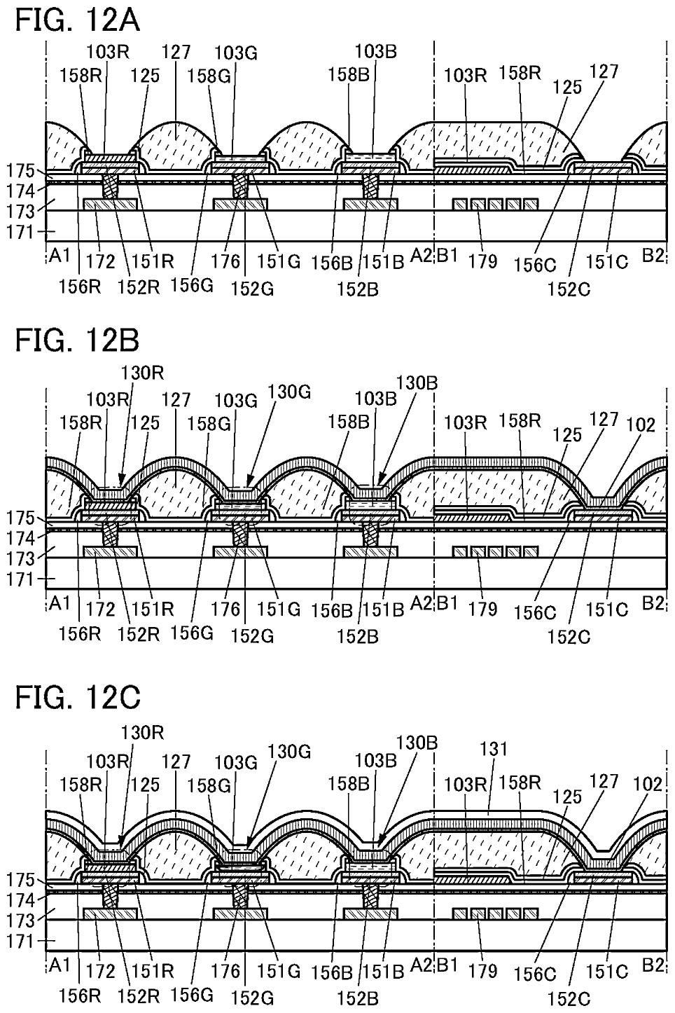

Next, as illustrated in FIG. 12A, etching treatment is performed using the insulating layer 127 as a mask to partly remove the sacrificial layers 158R, 158G, and 158B. Thus, openings are formed in the sacrificial layers 158R, 158G, and 158B, and the top surfaces of the organic compound layers 103R, 103G, and 103B and the conductive layer 152C are exposed. Note that this etching treatment may be hereinafter referred to as second etching treatment.

An end portion of the inorganic insulating layer 125 is covered with the insulating layer 127. FIG. 12A illustrates an example in which part of the end portion of the sacrificial layer 158 (specifically a tapered portion formed by the first etching treatment) is covered with the insulating layer 127 and a tapered portion formed by the second etching treatment is exposed.

The second etching treatment is performed by wet etching. The use of a wet etching method can reduce damage to the organic compound layers 103R, 103G, and 103B, as compared to the case of using a dry etching method. Wet etching can be performed using an alkaline solution or an acid solution, for example. An aqueous solution is preferably used in order that the organic compound layer 103 is not dissolved.

Next, as illustrated in FIG. 12B, the cathode 102 is formed over the organic compound layers 103R, 103G, and 103B, the conductive layer 152C, and the insulating layer 127. The cathode 102 can be formed by a sputtering method, a vacuum evaporation method, or the like.

Next, as illustrated in FIG. 12C, the protective layer 131 is formed over the cathode 102. The protective layer 131 can be formed by a vacuum evaporation method, a sputtering method, a CVD method, an ALD method, or the like.

Then, the substrate 120 is bonded to the protective layer 131 using the resin layer 122, so that the display device can be fabricated. In the method for fabricating the display device of one embodiment of the present invention, the insulating layer 156 is formed to include a region overlapping with the side surface of the conductive layer 151 and the conductive layer 152 is formed to cover the conductive layer 151 and the insulating layer 156 as described above. This can increase the yield of the display device and inhibit generation of defects.

As described above, in the method for fabricating the display device of one embodiment of the present invention, the island-shaped organic compound layers 103R, 103G, and 103B are formed not by using a fine metal mask but by processing a film formed on the entire surface; thus, the island-shaped layers can be formed to have a uniform thickness. Consequently, a high-resolution display device or a display device with a high aperture ratio can be obtained. Furthermore, even when the resolution or the aperture ratio is high and the distance between the subpixels is extremely short, the organic compound layers 103R, 103G, and 103B can be inhibited from being in contact with each other in the adjacent subpixels. As a result, generation of leakage current between the subpixels can be inhibited. This can prevent crosstalk, so that a display device with extremely high contrast can be obtained. Moreover, even a display device that includes tandem light-emitting devices formed by a photolithography method can have excellent characteristics.

### Embodiment 5

In this embodiment, a display device of one embodiment of the present invention will be described.

The display device in this embodiment can be a high-resolution display device. Thus, the display device in this embodiment can be used for display portions of information terminals (wearable devices) such as watch-type and bracelet-type information terminals and display portions of wearable devices capable of being worn on a head, such as a VR device like a head-mounted display (HMD) and a glasses-type AR device.

The display device in this embodiment can be a high-definition display device or a large-sized display device. Accordingly, the display device in this embodiment can be used for display portions of a digital camera, a digital video camera, a digital photo frame, a mobile phone, a portable game machine, a portable information terminal, and an audio reproducing device, in addition to display portions of electronic devices with a relatively large screen, such as a television device, desktop and laptop personal computers, a monitor of a computer and the like, digital signage, and a large game machine such as a pachinko machine.

### [Display Module]

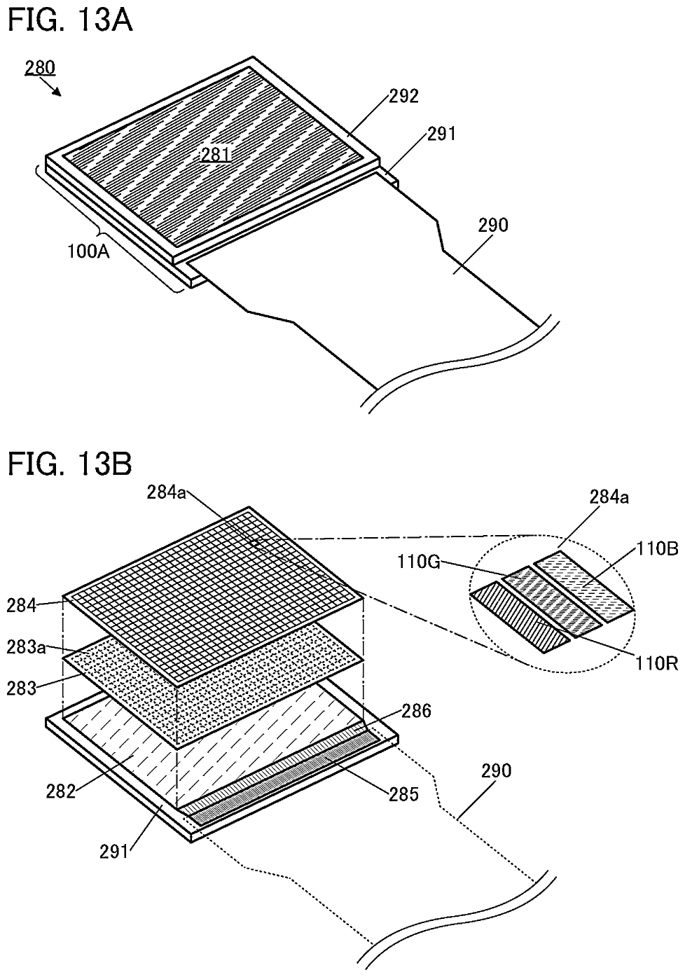

FIG. 13A is a perspective view of a display module 280. The display module 280 includes a display device 100A and an FPC 290. Note that the display device included in the display module 280 is not limited to the display device 100A and may be any of display devices 100B to 100E2 described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 13B is a perspective view schematically illustrating the structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is included in a portion not overlapping with the pixel portion 284 over the substrate 291. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 13B. The pixels 284a can employ any of the structures described in the above embodiments.

The pixel circuit portion 283 includes a plurality of pixel circuits 283a arranged periodically.

One pixel circuit 283a is a circuit that controls driving of a plurality of elements included in one pixel 284a.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high.

Such a display module 280 has extremely high resolution, and thus can be suitably used for a VR device such as an HMD or a glasses-type AR device. For example, even in the case of a structure in which the display portion of the display module 280 is seen through a lens, pixels of the extremely-high-resolution display portion 281 included in the display module 280 are prevented from being recognized when the display portion is enlarged by the lens, so that display providing a high sense of immersion can be performed. Without being limited thereto, the display module 280 can be suitably used for electronic devices including a relatively small display portion.

### [Display Device 100A]

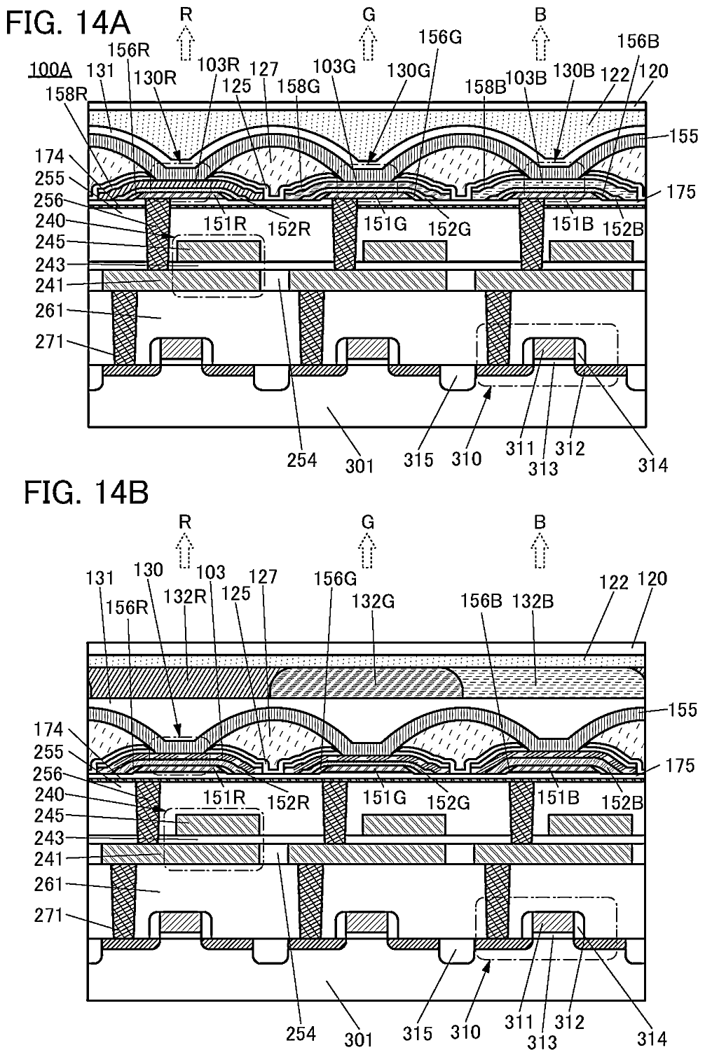

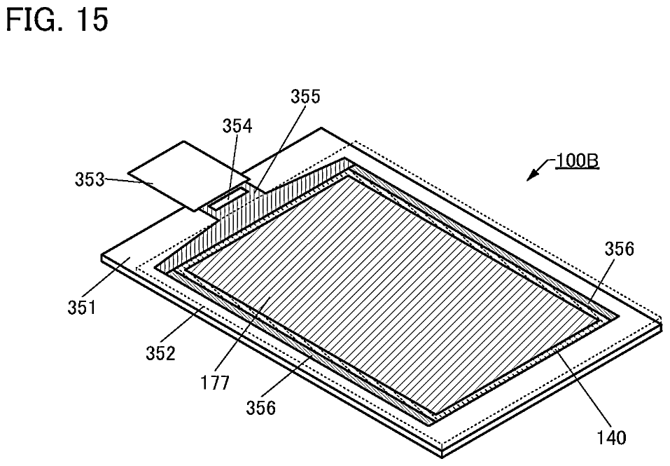

The display device 100A illustrated in FIG. 14A includes a substrate 301, the light-emitting devices 130R, 130G, and 130B, a capacitor 240, and a transistor 310.

The substrate 301 corresponds to the substrate 291 in FIGS. 13A and 13B. The transistor 310 includes a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as a source or a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240. The insulating layer 174 is provided over the insulating layer 255. The insulating layer 175 is provided over the insulating layer 174. The light-emitting devices 130R, 130G, and 130B are provided over the insulating layer 175. An insulator is provided in regions between adjacent light-emitting devices.

The insulating layer 156R is provided to include a region overlapping with the side surface of the conductive layer 151R. The insulating layer 156G is provided to include a region overlapping with the side surface of the conductive layer 151G. The insulating layer 156B is provided to include a region overlapping with the side surface of the conductive layer 151B. The conductive layer 152R is provided to cover the conductive layer 151R and the insulating layer 156R. The conductive layer 152G is provided to cover the conductive layer 151G and the insulating layer 156G. The conductive layer 152B is provided to cover the conductive layer 151B and the insulating layer 156B. The sacrificial layer 158R is positioned over the organic compound layer 103R. The sacrificial layer 158G is positioned over the organic compound layer 103G. The sacrificial layer 158B is positioned over the organic compound layer 103B.

Each of the conductive layers 151R, 151G, and 151B is electrically connected to one of the source and the drain of the corresponding transistor 310 through a plug 256 embedded in the insulating layers 243, 255, 174, and 175, the conductive layer 241 embedded in the insulating layer 254, and the plug 271 embedded in the insulating layer 261. Any of a variety of conductive materials can be used for the plugs.

The protective layer 131 is provided over the light-emitting devices 130R, 130G, and 130B. The substrate 120 is bonded to the protective layer 131 with the resin layer 122. Embodiment 4 can be referred to for the details of the light-emitting device 130 and the components thereover up to the substrate 120. The substrate 120 corresponds to the substrate 292 in FIG. 13A.

FIG. 14B illustrates a variation example of the display device 100A illustrated in FIG. 14A. The display device illustrated in FIG. 14B includes coloring layers 132R, 132G, and 132B, and each of the light-emitting devices 130 includes a region overlapping with one of the coloring layers 132R, 132G, and 132B. In the display device illustrated in FIG. 14B, the light-emitting device 130 can emit white light, for example. The coloring layer 132R, the coloring layer 132G, and the coloring layer 132B can transmit red light, green light, and blue light, respectively, for example.

### [Display Device 100B]

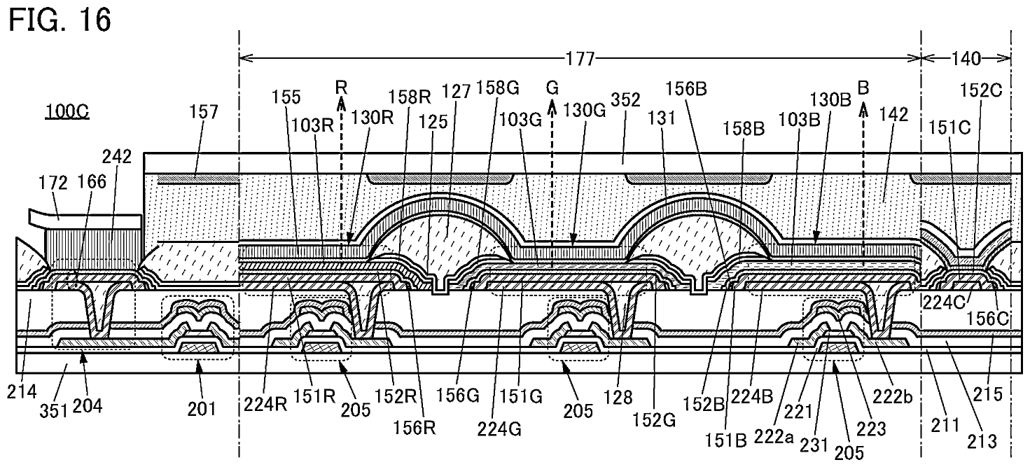

FIG. 15 is a perspective view of the display device 100B, and FIG. 16 is a cross-sectional view of the display device 100C.

In the display device 100B, a substrate 352 and a substrate 351 are bonded to each other. In FIG. 15, the substrate 352 is denoted by a dashed line.

The display device 100B includes the pixel portion 177, the connection portion 140, a circuit 356, a wiring 355, and the like. FIG. 15 illustrates an example in which an IC 354 and an FPC 353 are mounted on the display device 100B. Thus, the structure illustrated in FIG. 15 can be regarded as a display module including the display device 100B, the integrated circuit (IC), and the FPC. Here, a display device in which a substrate is equipped with a connector such as an FPC or mounted with an IC is referred to as a display module.

The connection portion 140 is provided outside the pixel portion 177. The number of connection portions 140 may be one or more. In the connection portion 140, a common electrode of a light-emitting device is electrically connected to a conductive layer, so that a potential can be supplied to the common electrode.

As the circuit 356, a scan line driver circuit can be used, for example.

The wiring 355 has a function of supplying a signal and power to the pixel portion 177 and the circuit 356. The signal and power are input to the wiring 355 from the outside through the FPC 353 or from the IC 354.

FIG. 15 illustrates an example in which the IC 354 is provided over the substrate 351 by a chip on glass (COG) method, a chip on film (COF) method, or the like. An IC including a scan line driver circuit, a signal line driver circuit, or the like can be used as the IC 354, for example. Note that the display device 100B and the display module are not necessarily provided with an IC. Alternatively, the IC may be mounted on the FPC by a COF method, for example.

FIG. 16 illustrates, as the display device 100C, an example of cross sections of part of a region including the FPC 353, part of the circuit 356, part of the pixel portion 177, part of the connection portion 140, and part of a region including an end portion of the display device 100B in FIG. 15.

### [Display Device 100C]

The display device 100C illustrated in FIG. 16 includes a transistor 201, a transistor 205, the light-emitting device 130R that emits red light, the light-emitting device 130G that emits green light, the light-emitting device 130B that emits blue light, and the like between the substrate 351 and the substrate 352.

Embodiment 4 can be referred to for the details of the light-emitting devices 130R, 130G, and 130B.

The light-emitting device 130R includes a conductive layer 224R, the conductive layer 151R over the conductive layer 224R, and the conductive layer 152R over the conductive layer 151R. The light-emitting device 130G includes a conductive layer 224G, the conductive layer 151G over the conductive layer 224G, and the conductive layer 152G over the conductive layer 151G. The light-emitting device 130B includes a conductive layer 224B, the conductive layer 151B over the conductive layer 224B, and the conductive layer 152B over the conductive layer 151B.

The conductive layer 224R is connected to a conductive layer 222b included in the transistor 205 through the opening provided in an insulating layer 214. An end portion of the conductive layer 151R is positioned outward from an end portion of the conductive layer 224R. The insulating layer 156R is provided to include a region that is in contact with the side surface of the conductive layer 151R, and the conductive layer 152R is provided to cover the conductive layer 151R and the insulating layer 156R.

The conductive layers 224G, 151G, and 152G and the insulating layer 156G in the light-emitting device 130G are not described in detail because they are respectively similar to the conductive layers 224R, 151R, and 152R and the insulating layer 156R in the light-emitting device 130R; the same applies to the conductive layers 224B, 151B, and 152B and the insulating layer 156B in the light-emitting device 130B.

The conductive layers 224R, 224G, and 224B each have a depressed portion covering an opening provided in the insulating layer 214. A layer 128 is embedded in the depressed portion.

The layer 128 has a function of filling the depressed portions of the conductive layers 224R, 224G, and 224B to obtain planarity. Over the conductive layers 224R, 224G, and 224B and the layer 128, the conductive layers 151R, 151G, and 151B that are respectively electrically connected to the conductive layers 224R, 224G, and 224B are provided. Thus, the regions overlapping with the depressed portions of the conductive layers 224R, 224G, and 224B can also be used as light-emitting regions, whereby the aperture ratio of the pixel can be increased.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. The layer 128 can be formed using an organic insulating material usable for the insulating layer 127, for example.

The protective layer 131 is provided over the light-emitting devices 130R, 130G, and 130B. The protective layer 131 and the substrate 352 are bonded to each other with an adhesive layer 142. The substrate 352 is provided with a light-blocking layer 157. A solid sealing structure, a hollow sealing structure, or the like can be employed to seal the light-emitting device 130. In FIG. 16, a solid sealing structure is employed, in which a space between the substrate 352 and the substrate 351 is filled with the adhesive layer 142. Alternatively, the space may be filled with an inert gas (e.g., nitrogen or argon), i.e., a hollow sealing structure may be employed. In that case, the adhesive layer 142 may be provided not to overlap with the light-emitting device. Alternatively, the space may be filled with a resin other than the frame-shaped adhesive layer 142.

FIG. 16 illustrates an example in which the connection portion 140 includes a conductive layer 224C obtained by processing the same conductive film as the conductive layers 224R, 224G, and 224B; the conductive layer 151C obtained by processing the same conductive film as the conductive layers 151R, 151G, and 151B; and the conductive layer 152C obtained by processing the same conductive film as the conductive layers 152R, 152G, and 152B. In the example illustrated in FIG. 16, the insulating layer 156C is provided to include a region overlapping with the side surface of the conductive layer 151C.

The display device 100C has a top-emission structure. Light from the light-emitting device is emitted toward the substrate 352. For the substrate 352, a material having a high visible-light-transmitting property is preferably used. The pixel electrode contains a material that reflects visible light, and a counter electrode (a common electrode 155) contains a material that transmits visible light.

An insulating layer 211, an insulating layer 213, an insulating layer 215, and the insulating layer 214 are provided in this order over the substrate 351. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or more.

An inorganic insulating film is preferably used as each of the insulating layers 211, 213, and 215.

An organic insulating layer is suitable as the insulating layer 214 functioning as a planarization layer.

Each of the transistors 201 and 205 includes a conductive layer 221 functioning as a gate, the insulating layer 211 functioning as the gate insulating layer, a conductive layer 222a and the conductive layer 222b functioning as a source and a drain, a semiconductor layer 231, the insulating layer 213 functioning as the gate insulating layer, and a conductive layer 223 functioning as a gate.

A connection portion 204 is provided in a region of the substrate 351 that does not overlap with the substrate 352. In the connection portion 204, the source electrode or the drain electrode of the transistor 201 is electrically connected to the FPC 353 through a conductive layer 166 and a connection layer 242. An example is described in which the conductive layer 166 has a stacked-layer structure of a conductive film obtained by processing the same conductive film as the conductive layers 224R, 224G, and 224B; a conductive film obtained by processing the same conductive film as the conductive layers 151R, 151G, and 151B; and a conductive film obtained by processing the same conductive film as the conductive layers 152R, 152G, and 152B. On the top surface of the connection portion 204, the conductive layer 166 is exposed. Thus, the connection portion 204 and the FPC 353 can be electrically connected to each other through the connection layer 242.

The light-blocking layer 157 is preferably provided on the surface of the substrate 352 on the substrate 351 side. The light-blocking layer 157 can be provided over a region between adjacent light-emitting devices, in the connection portion 140, and in the circuit 356, for example. A variety of optical members can be arranged on the outer surface of the substrate 352.

A material that can be used for the substrate 120 can be used for each of the substrates 351 and 352.

A material that can be used for the resin layer 122 can be used for the adhesive layer 142.

As the connection layer 242, an anisotropic conductive film (ACF), an anisotropic conductive paste (ACP), or the like can be used.

### [Display Device 100D]

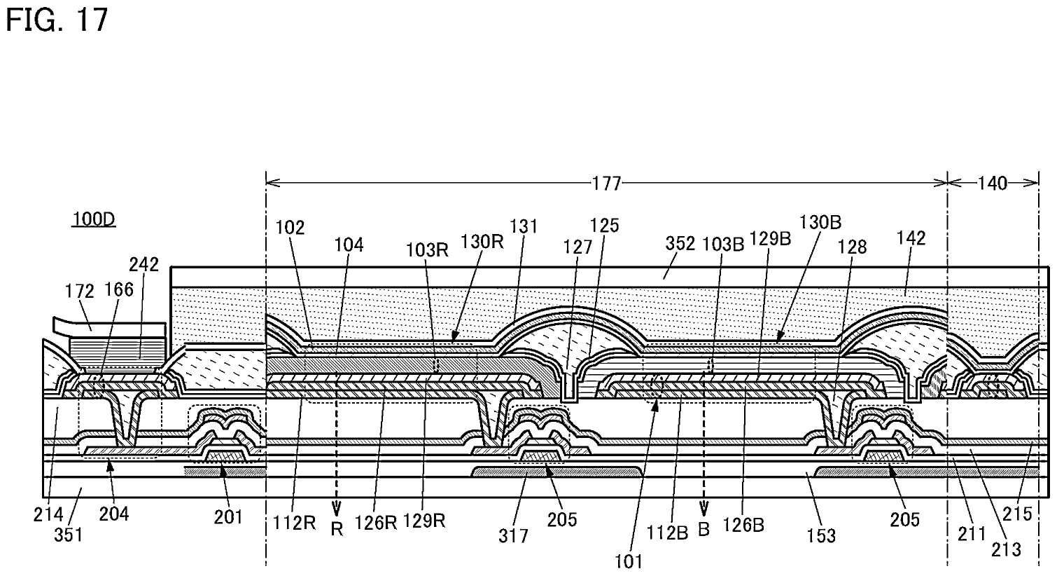

The display device 100D illustrated in FIG. 17 differs from the display device 100C illustrated in FIG. 16 mainly in having a bottom-emission structure.

Light from the light-emitting device is emitted toward the substrate 351. For the substrate 351, a material having a high visible-light-transmitting property is preferably used. By contrast, there is no limitation on the light-transmitting property of a material used for the substrate 352.

A light-blocking layer 317 is preferably formed between the substrate 351 and the transistor 201 and between the substrate 351 and the transistor 205. FIG. 17 illustrates an example in which the light-blocking layer 317 is provided over the substrate 351, an insulating layer 153 is provided over the light-blocking layer 317, and the transistors 201 and 205 and the like are provided over the insulating layer 153.

The light-emitting device 130R includes a conductive layer 112R, a conductive layer 126R over the conductive layer 112R, and a conductive layer 129R over the conductive layer 126R.

The light-emitting device 130B includes a conductive layer 112B, a conductive layer 126B over the conductive layer 112B, and a conductive layer 129B over the conductive layer 126B.

A material having a high visible-light-transmitting property is used for each of the conductive layers 112R, 112B, 126R, 126B, 129R, and 129B. A material that reflects visible light is preferably used for the second electrode 102.

Although not illustrated in FIG. 17, the light-emitting device 130G is also provided.

Although FIG. 17 and the like illustrate an example in which the top surface of the layer 128 includes a flat portion, the shape of the layer 128 is not particularly limited.

### [Display Device 100D2]

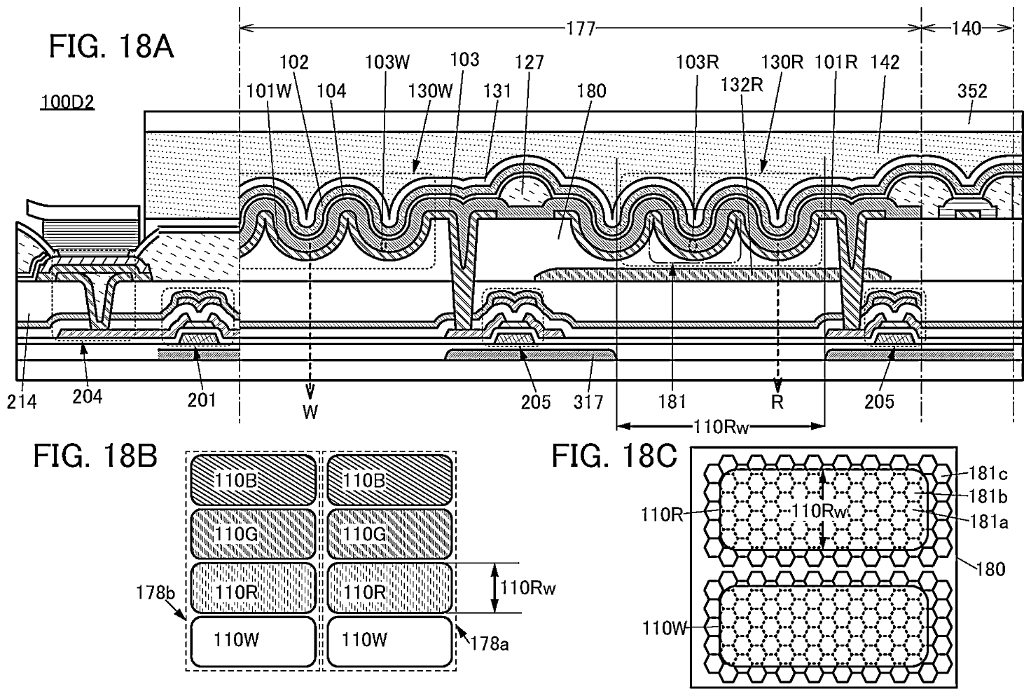

The display device 100D2 illustrated in FIG. 18A is an example of a bottom-emission display device different from the display device 100D illustrated in FIG. 17. The display device 100D2 is different from the display device 100D in that an organic resin layer 180 is included. Note that the reference numerals of the components that are the same as those in FIG. 17 are sometimes omitted and the description for FIG. 17 is preferably referred to for the details of such components.

FIG. 18B shows a top-view layout of the pixels 178 (a pixel 178a and a pixel 178b) each including the subpixels 110 (the subpixels 110R, 110G, 110B, and 110W), and FIG. 18C shows a top view of the organic resin layer 180 in a region where the subpixels 110R and 110W of the pixel 178 are formed. Note that the width between the light-blocking layer 317 and another light-blocking layer 317 corresponds to a width 110Rw in the light-emitting region of the subpixel 110R.

As illustrated in FIG. 18A, the organic resin layer 180 is provided over the insulating layer 214. As illustrated in FIG. 18C and the region surrounded by the dashed-dotted line in FIG. 18A, the organic resin layer 180 includes depressed portions 181 (depressed portions 181a and depressed portions 181b) each having a curved surface, at least in a region where the subpixels are formed. Note that the depressed portion 181 may be provided outside the light-emitting region, like a depressed portion 181c. When the depressed portion 181c is provided, light that has been emitted in a region overlapping with the light-blocking layer 317 or light that has progressed to the region overlapping with the light-blocking layer 317 can be refracted and extracted from the light-emitting region, increasing the emission efficiency.

A plurality of the depressed portions 181 may be formed in a matrix. The depressed portion 181a and the depressed portion 181b may be provided in contact with each other or may have a flat surface therebetween.

Although the top surface shape and the cross-sectional shape of the depressed portion are hexagonal (FIG. 18C) and semicircular (FIG. 18A), respectively, other shapes may be employed as needed. Examples of a top surface shape of the depressed portion include polygons such as a triangle, a tetragon (including a rectangle and a square), and a pentagon; these polygons with rounded corners; an ellipse; and a circle.

As the organic resin layer 180, an insulating layer including an organic material can be used. For the organic resin layer 180, an acrylic resin, a polyimide resin, an epoxy resin, an imide resin, a polyamide resin, a polyimide-amide resin, a silicone resin, a siloxane resin, a benzocyclobutene-based resin, a phenol resin, or a precursor of any of these resins can be used, for example. Alternatively, an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin may be used for the organic resin layer 180.

Further alternatively, a photosensitive resin can be used for the organic resin layer 180. A photoresist may be used as the photosensitive resin. As the photosensitive resin, a positive photosensitive material or a negative photosensitive material can be used.

The organic resin layer 180 may contain a material absorbing visible light. For example, the organic resin layer 180 itself may be made of a material absorbing visible light, or the organic resin layer 180 may contain a pigment absorbing visible light. For the organic resin layer 180, for example, a resin that can be used as a color filter transmitting red, blue, or green light and absorbing light of the other colors or a resin that contains carbon black as a pigment and functions as a black matrix can be used.

The first electrodes 101 (the first electrode 101R and a first electrode 101W) are provided over the organic resin layer 180, and the organic compound layer 103 is provided over the first electrodes 101. End portions of the first electrodes 101 and the organic compound layer 103 may be covered with the insulating layer 127.

Along the depressed portion of the organic resin layer 180, the first electrode 101 formed over the organic resin layer 180 has a depressed portion in a manner similar to that of the organic resin layer 180. Furthermore, along the depressed portion of the first electrode 101, the organic compound layer 103 formed over the first electrode 101 has a depressed portion in a manner similar to that of the first electrode 101. Furthermore, along the depressed portion of the organic compound layer 103, the common layer 104 formed over the organic compound layer 103 has a depressed portion in a manner similar to that of the organic compound layer 103. Furthermore, along the depressed portion of the common layer 104, the second electrode 102 formed over the common layer 104 has a depressed portion in a manner similar to that of the common layer 104. That is, the depressed portions of the organic resin layer 180, the first electrode 101, the organic compound layer 103, the common layer 104, and the second electrode 102 overlap with each other.

The common layer 104 is provided over the organic compound layer 103 and the insulating layer 127, and the second electrode 102 is provided over the common layer 104. The protective layer 131 is provided over the second electrode 102, and the substrate 352 is bonded with the use of the adhesive layer 142.

Although FIG. 18A illustrates a light-emitting device 130W and the light-emitting device 130R and does not illustrate the light-emitting devices 130G and 130B, the light-emitting devices 130G and 130B are also provided.

### [Display Device 100E]

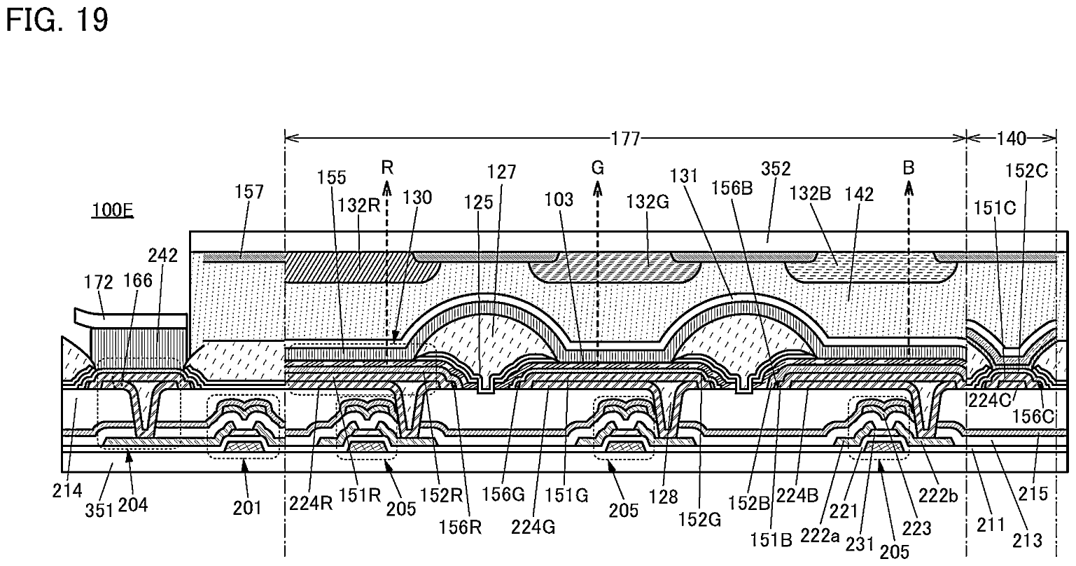

The display device 100E illustrated in FIG. 19 is a variation example of the display device 100C illustrated in FIG. 16 and differs from the display device 100C mainly in including the coloring layers 132R, 132G, and 132B.

In the display device 100E, the light-emitting device 130 includes a region overlapping with one of the coloring layers 132R, 132G, and 132B. The coloring layers 132R, 132G, and 132B can be provided on the surface of the substrate 352 on the substrate 351 side. End portions of the coloring layers 132R, 132G, and 132B can overlap with the light-blocking layer 157.

In the display device 100E, for example, the light-emitting device 130 can emit white light. For example, the coloring layer 132R, the coloring layer 132G, and the coloring layer 132B can transmit red light, green light, and blue light, respectively. Note that in the display device 100E, the coloring layers 132R, 132G, and 132B may be provided between the protective layer 131 and the adhesive layer 142.

### [Display Device 100E2]

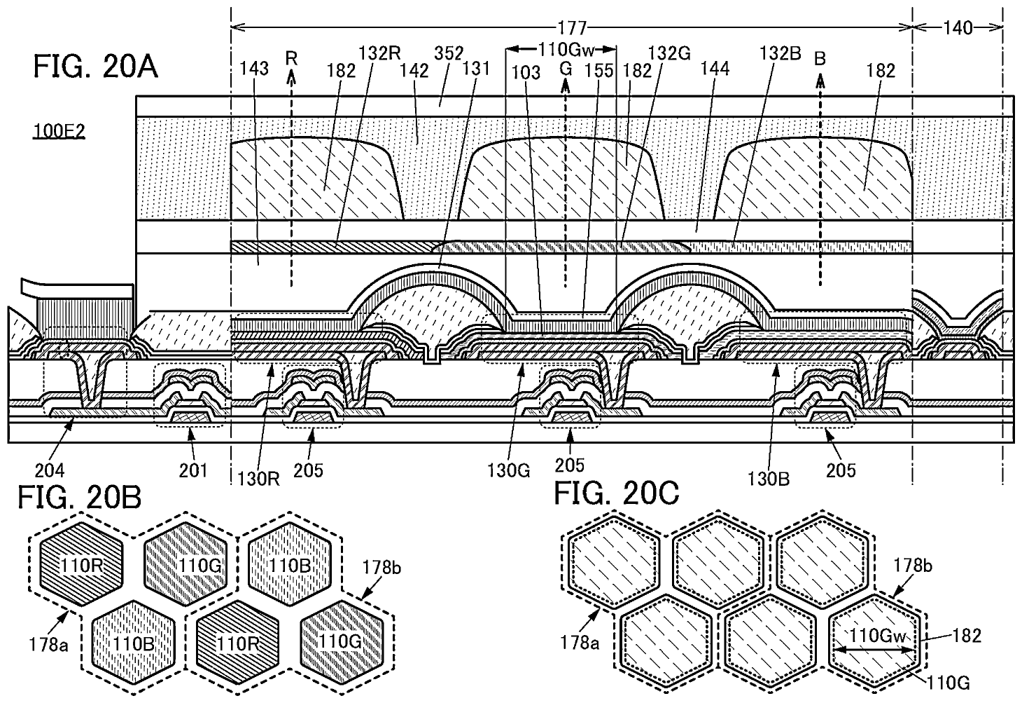

The display device 100E2 illustrated in FIG. 20A is a variation example of the display device 100E illustrated in FIG. 19 and includes microlenses 182 over the coloring layers 132R, 132G, and 132B. Note that the reference numerals of the components that are the same as those in FIG. 19 are sometimes omitted and the description for FIG. 19 is preferably referred to for the details of such components.

FIG. 20B is a top-view layout of the pixels 178 (the pixels 178a and 178b) each including the subpixels 110 (the subpixels 110R, 110G, and 110B), and FIG. 20C is a top view of the microlenses 182 in a region where the subpixels 110R, 110G, and 110B included in the pixel 178 are formed. Note that the width of a region where the common electrode 155 and the organic compound layer 103 are in contact with each other corresponds to a width 110Gw of a light-emitting region of the subpixel 110G.

In the display device 100E2 illustrated in FIG. 20A, a planarization film 143 is provided over the protective layer 131, and the coloring layers 132R, 132G, and 132B are provided over the planarization film 143. A planarization film 144 is provided to cover the coloring layers 132R, 132G, and 132B. The microlenses 182 are provided over the planarization film 144.

Note that as illustrated in FIG. 20C, the microlenses 182 are preferably provided on a subpixel basis in the region where the subpixels are formed.

Although the top surface shape of the microlens 182 is hexagonal in FIG. 20C, a different shape may be employed as needed. Examples of a top surface shape of the microlens 182 include polygons such as a triangle, a tetragon (including a rectangle and a square), and a pentagon; these polygons with rounded corners; an ellipse; and a circle.

The microlenses 182 can be formed using a material similar to that of the organic resin layer 180.

This embodiment can be combined as appropriate with the other embodiments or examples. In this specification, in the case where a plurality of structure examples are described in one embodiment, the structure examples can be combined as appropriate.

### Embodiment 6

In this embodiment, electronic devices of one embodiment of the present invention will be described.

Electronic devices of this embodiment include the display device of one embodiment of the present invention in their display portions. The display device of one embodiment of the present invention has low power consumption and high reliability. Thus, the display device of one embodiment of the present invention can be used for display portions of a variety of electronic devices.

Examples of the electronic devices include a digital camera, a digital video camera, a digital photo frame, a mobile phone, a portable game machine, a portable information terminal, and an audio reproducing device, in addition to electronic devices with a relatively large screen, such as a television device, desktop and laptop personal computers, a monitor of a computer and the like, digital signage, and a large game machine such as a pachinko machine.

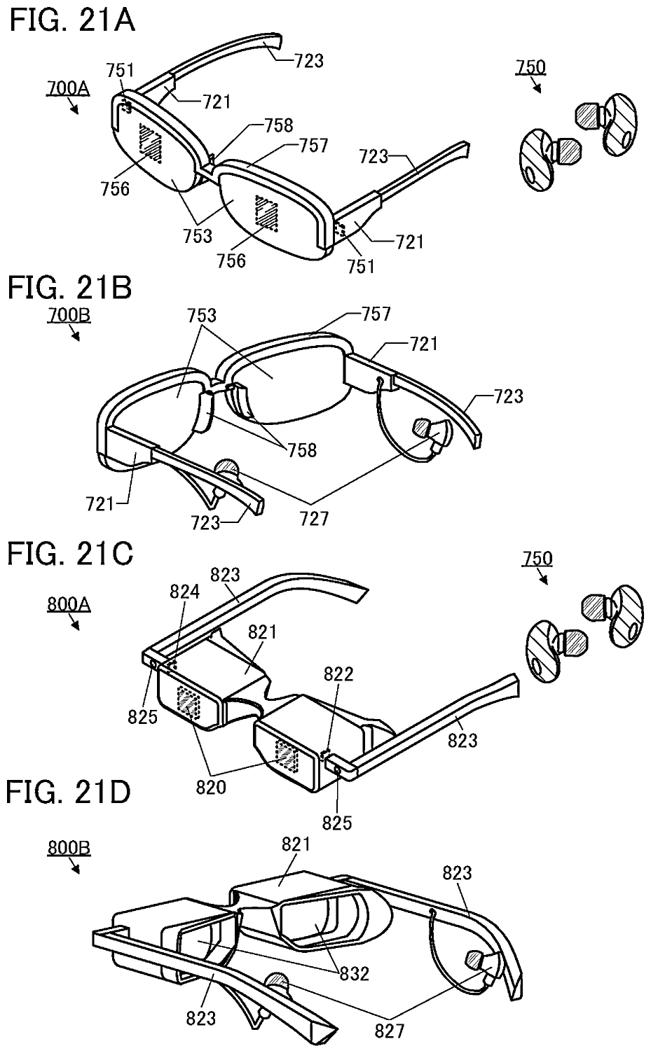

Examples of wearable devices capable of being worn on a head are described with reference to FIGS. 21A to 21D.

An electronic device 700A illustrated in FIG. 21A and an electronic device 700B illustrated in FIG. 21B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, a highly reliable electronic device is obtained.

The electronic devices 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753.

In the electronic devices 700A and 700B, a camera capable of capturing images of the front side may be provided as the image capturing portion. Furthermore, when the electronic devices 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal, for example, can be supplied by the wireless communication device. Instead of or in addition to the wireless communication device, a connector that can be connected to a cable for supplying a video signal and a power supply potential may be provided.

The electronic devices 700A and 700B are provided with a battery, so that they can be charged wirelessly and/or by wire.

A touch sensor module may be provided in the housing 721.

Various touch sensors can be used for the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

An electronic device 800A illustrated in FIG. 21C and an electronic device 800B illustrated in FIG. 21D each include a pair of display portions 820, a housing 821, a communication portion 822, a pair of wearing portions 823, a control portion 824, a pair of image capturing portions 825, and a pair of lenses 832.

The display device of one embodiment of the present invention can be used in the display portions 820. Thus, a highly reliable electronic device is obtained.

The display portions 820 are positioned inside the housing 821 so as to be seen through the lenses 832. When the pair of display portions 820 display different images, three-dimensional display using parallax can be performed.

The electronic devices 800A and 800B preferably include a mechanism for adjusting the lateral positions of the lenses 832 and the display portions 820 so that the lenses 832 and the display portions 820 are positioned optimally in accordance with the positions of the user's eyes.

The electronic device 800A or 800B can be mounted on the user's head with the wearing portions 823.

The image capturing portion 825 has a function of obtaining information on the external environment. Data obtained by the image capturing portion 825 can be output to the display portions 820. An image sensor can be used for the image capturing portion 825. Moreover, a plurality of cameras may be provided so as to cover a plurality of fields of view, such as a telescope field of view and a wide field of view.

The electronic device 800A may include a vibration mechanism that functions as bone-conduction earphones.

The electronic devices 800A and 800B may each include an input terminal. To the input terminal, a cable for supplying a video signal from a video output device or the like, power for charging a battery provided in the electronic device, and the like can be connected.

The electronic device of one embodiment of the present invention may have a function of performing wireless communication with earphones 750.

The electronic device may include earphone portions. The electronic device 700B in FIG. 21B includes earphone portions 727. Part of a wiring that connects the earphone portion 727 and the control portion may be positioned inside the housing 721 or the wearing portion 723.

Similarly, the electronic device 800B in FIG. 21D includes earphone portions 827. For example, the earphone portions 827 can be connected to the control portion 824 by wire.

As described above, both the glasses-type device (e.g., the electronic devices 700A and 700B) and the goggles-type device (e.g., the electronic devices 800A and 800B) are preferable as the electronic device of one embodiment of the present invention.

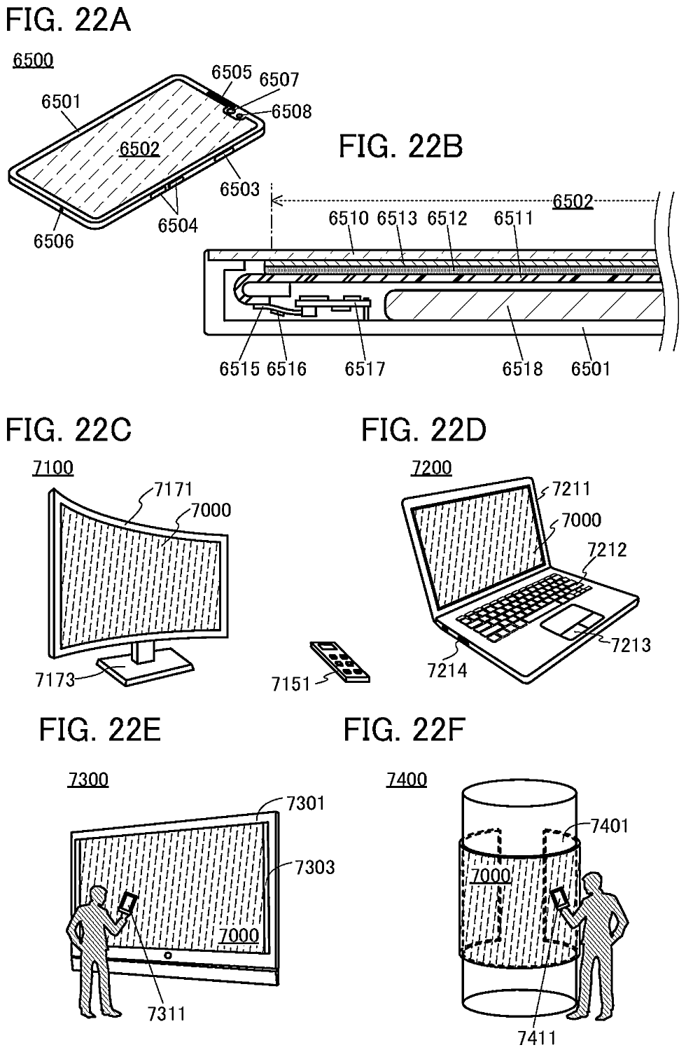

An electronic device 6500 illustrated in FIG. 22A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502. Thus, a highly reliable electronic device is obtained.

FIG. 22B is a schematic cross-sectional view including an edge portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display device of one embodiment of the present invention can be used in the display panel 6511. Thus, an extremely lightweight electronic device can be obtained. Since the display panel 6511 is extremely thin, the battery 6518 with high capacity can be mounted without an increase in the thickness of the electronic device. An electronic device with a narrow bezel can be obtained when part of the display panel 6511 is folded back so that the portion connected to the FPC 6515 is provided on the back side of a pixel portion.

FIG. 22C illustrates an example of a television device. In a television device 7100, a display portion 7000 is incorporated in a housing 7171. Here, the housing 7171 is supported by a stand 7173.

The display device of one embodiment of the present invention can be used in the display portion 7000. Thus, a highly reliable electronic device is obtained.

The television device 7100 illustrated in FIG. 22C can be operated with an operation switch provided in the housing 7171 and a separate remote control 7151.

FIG. 22D illustrates an example of a laptop personal computer. A laptop personal computer 7200 includes a housing 7211, a keyboard 7212, a pointing device 7213, an external connection port 7214, and the like. The display portion 7000 is incorporated in the housing 7211.

The display device of one embodiment of the present invention can be used in the display portion 7000. Thus, a highly reliable electronic device is obtained.

FIGS. 22E and 22F illustrate examples of digital signage.

Digital signage 7300 illustrated in FIG. 22E includes a housing 7301, the display portion 7000, a speaker 7303, and the like. The digital signage 7300 can also include an LED lamp, operation keys (including a power switch or an operation switch), a connection terminal, a variety of sensors, a microphone, and the like.

FIG. 22F illustrates digital signage 7400 attached to a cylindrical pillar 7401. The digital signage 7400 includes the display portion 7000 provided along a curved surface of the pillar 7401.

In FIGS. 22E and 22F, the display device of one embodiment of the present invention can be used in the display portion 7000. Thus, a highly reliable electronic device is obtained.

A larger area of the display portion 7000 can increase the amount of information that can be provided at a time. The display portion 7000 having a larger area attracts more attention, so that the effectiveness of the advertisement can be increased, for example.

As illustrated in FIGS. 22E and 22F, it is preferable that the digital signage 7300 or the digital signage 7400 be capable of working with an information terminal 7311 or an information terminal 7411, such as a smartphone that a user has, through wireless communication.

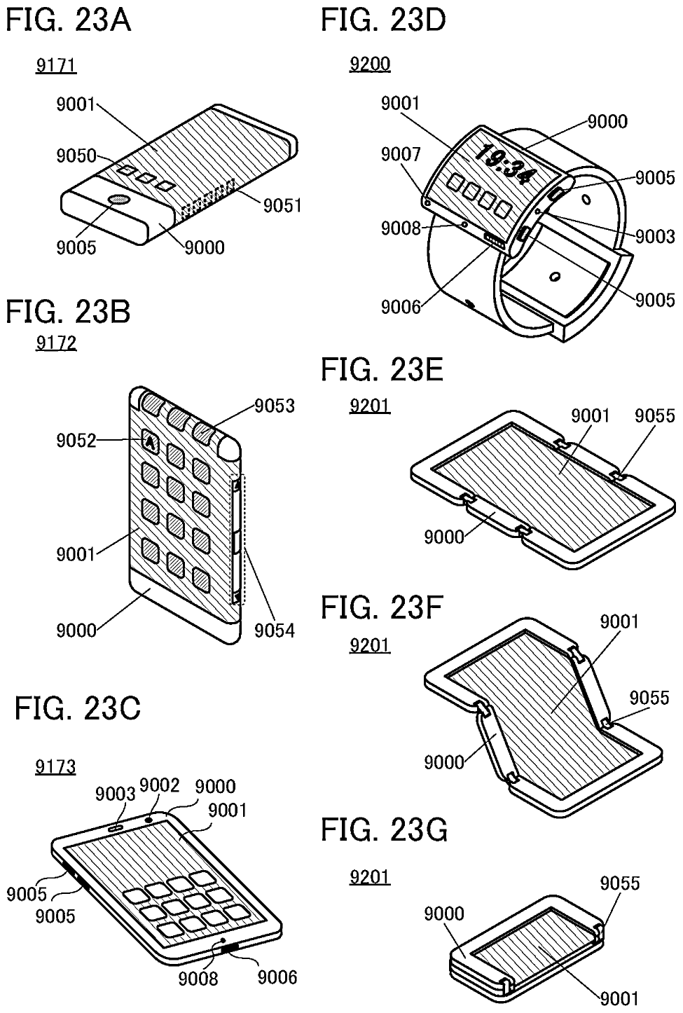

Electronic devices illustrated in FIGS. 23A to 23G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone 9008, and the like.

The electronic devices illustrated in FIGS. 23A to 23G have a variety of functions. For example, the electronic devices can have a function of displaying a variety of information (e.g., a still image, a moving image, and a text image) on the display portion, a touch panel function, a function of displaying a calendar, date, time, and the like, a function of controlling processing with the use of a variety of software (programs), a wireless communication function, and a function of reading out and processing a program or data stored in a recording medium.

The electronic devices in FIGS. 23A to 23G are described in detail below.

FIG. 23A is a perspective view of a portable information terminal 9171. The portable information terminal 9171 can be used as a smartphone, for example. The portable information terminal 9171 may include the speaker 9003, the connection terminal 9006, the sensor 9007, or the like. The portable information terminal 9171 can display text and image information on its plurality of surfaces. FIG. 23A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050 or the like may be displayed at the position where the information 9051 is displayed.

FIG. 23B is a perspective view of a portable information terminal 9172. The portable information terminal 9172 has a function of displaying information on three or more surfaces of the display portion 9001. Here, an example in which information 9052, information 9053, and information 9054 are displayed on different surfaces is described. For example, the user of the portable information terminal 9172 can check the information 9053 displayed such that it can be seen from above the portable information terminal 9172, with the portable information terminal 9172 put in a breast pocket of his/her clothes.

FIG. 23C is a perspective view of a tablet terminal 9173. The tablet terminal 9173 is capable of executing a variety of applications such as mobile phone calls, e-mailing, viewing and editing texts, music reproduction, Internet communication, and a computer game, for example. The tablet terminal 9173 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 23D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 23E to 23G are perspective views of a foldable portable information terminal 9201. FIG. 23E is a perspective view illustrating the portable information terminal 9201 that is opened. FIG. 23G is a perspective view illustrating the portable information terminal 9201 that is folded. FIG. 23F is a perspective view illustrating the portable information terminal 9201 that is shifted from one of the states in FIGS. 23E and 23G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined as appropriate with the other embodiments or examples. In this specification, in the case where a plurality of structure examples are described in one embodiment, the structure examples can be combined as appropriate.

### Example 11

In this example, the orientation characteristics of a platinum complex A, a platinum complex B, and a platinum complex C used as dopants in light-emitting devices were examined. The results will be described below. The structural formulae and compound names of the platinum complexes A to C are shown below.

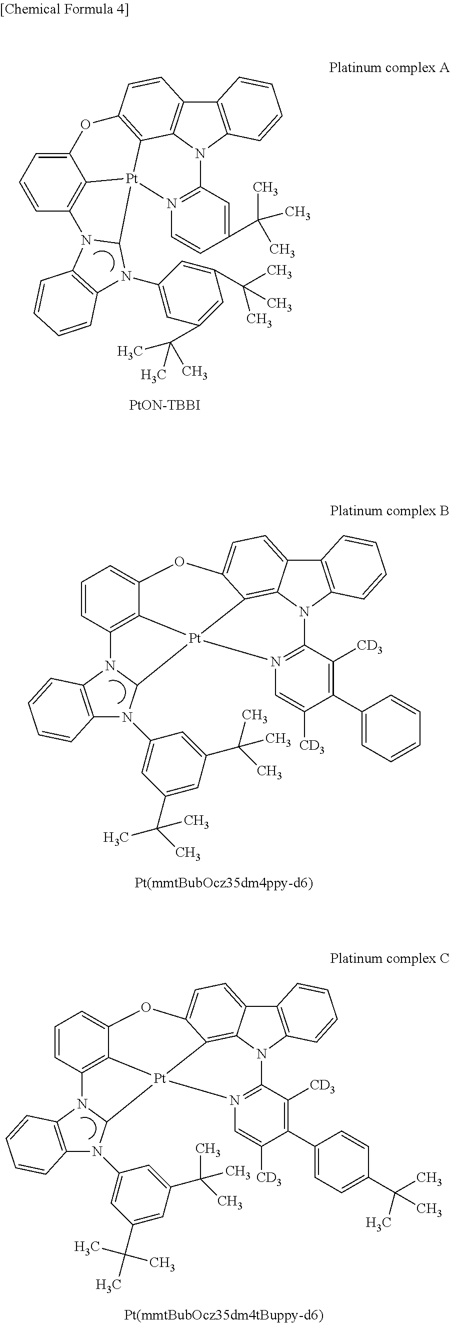

Platinum complex A: (2-{3-[3-(3,5-di-tert-butylphenyl)benzimidazol-1-yl-2-ylidene-κC²]phenoxy-κC²}-9-(4-tert-butyl-2-pyridinyl-κN)carbazole-2,1-diyl-κC)platinum(II) (abbreviation: PtON-TBBI); Platinum complex B: (2-{3-[3-(3,5-di-tert-butylphenyl)benzimidazol-1-yl-2-ylidene-κC]phenoxy-κC²}-9-[3,5-di(methyl-d3)-4-phenyl-2-pyridinyl-κN]carbazole-2,1-diyl-κC)platinum(II) (abbreviation: Pt(mmtBubOcz35dm4ppy-d6)); and Platinum complex C: (2-{3-[3-(3,5-di-tert-butylphenyl)benzimidazol-1-yl-2-ylidene-κC²]phenoxy-κC²}-9-[3,5-di(methyl-d3)-4-tert-butylphenyl-2-pyridinyl-κN]carbazole-2,1-diyl-KC)platinum(II) (abbreviation: Pt(mmtBubOcz35dm4tBuppy-d6)).

First, the inner product of the vector A connecting two most distant atoms in the molecular arrangement in the lowest triplet excited state and the vector B of a transition dipole moment relating to light emission was calculated.

Here, the inner product of the vector A and the vector B of each of the platinum complex A, the platinum complex B, and the platinum complex C was calculated.

First, the most stable structures in the singlet ground state and the lowest triplet excited state were obtained by calculation.

The structure subjected to quantum chemical calculation was sampled by conformational analysis in MacroModel with Maestro GUI produced by Schrödinger, Inc. The quantum chemical calculation software, Jaguar, was used to calculate the most stable structure in the singlet ground state by the density functional theory (DFT), whereby the most stable conformational structure was determined. This structure was subjected to calculation under the following conditions to obtain the most stable structure: as basis functions, DYALL-2ZCVP_ZORA-J-PT-GEN++ was used for a Pt atom and LACVP** was used for the other atoms; ωB97X-D (ω=0.1) was used as a functional; time-dependent density functional theory (TD-DFT) using spin-free ZORA relativistic Hamiltonian was employed; and the excited state was the lowest triplet excited state.

The most stable structure in the lowest triplet excited state obtained above was then subjected to single point energy calculation of the excited state using spin-orbital ZORA relativistic Hamiltonian, whereby the vector B of the transition dipole moment relating to light emission was visualized.

In the above structure, the vector A connecting two most distant atoms was set such that an angle formed by the vector A and the vector B was less than or equal to 90°, and the angle was calculated. For example, FIG. 2 illustrates the vectors and the angle formed by the vectors in the platinum complex B. The results are shown in Table 3.

TABLE 3

| | Vector A | Vector B | Angle | Inner |
|---|---|---|---|---|
| | (nm) | (debye) | (°) | product |
| Platinum complex A | 1.56 | 2.17 | 85 | 0.3 |
| Platinum complex B | 1.54 | 2.99 | 10 | 4.5 |
| Platinum complex C | 1.68 | 2.81 | 25 | 4.3 |

The inner product of the vector A and the vector B was greater than or equal to 4.0 in each of the platinum complex B and the platinum complex C, probably leading to large contribution of the transition dipole moment to an improvement in emission efficiency.

Next, in order to calculate the orientation parameters a of the platinum complexes A to C used as the emission center substances in the light-emitting devices, light-emitting devices for orientation measurement in which the front luminance was greatly reduced by optical path length adjustment were fabricated and subject to the measurement. In this example, besides the light-emitting devices for orientation measurement, normal light-emitting devices in which the front luminance was not reduced by optical path length adjustment were also fabricated, and data of the normal light-emitting devices are also shown.

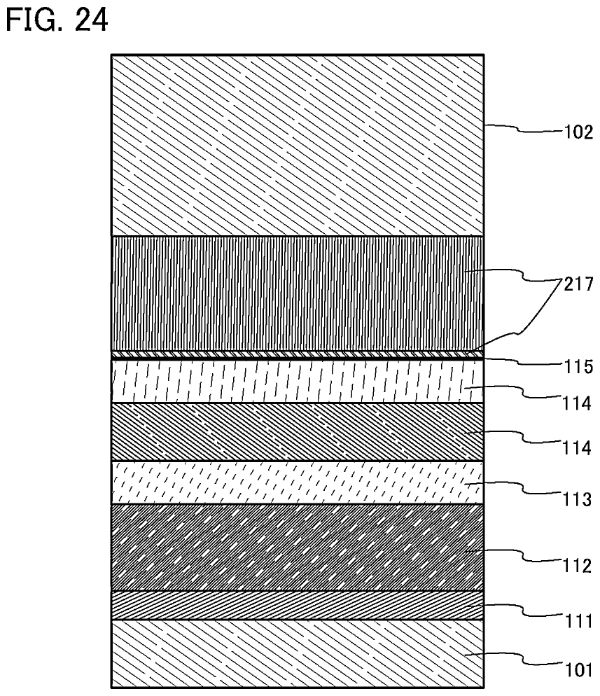

Structural formulae of organic compounds used in this example are shown below. FIG. 24 is a schematic view illustrating a device structure of the light-emitting devices for orientation measurement.

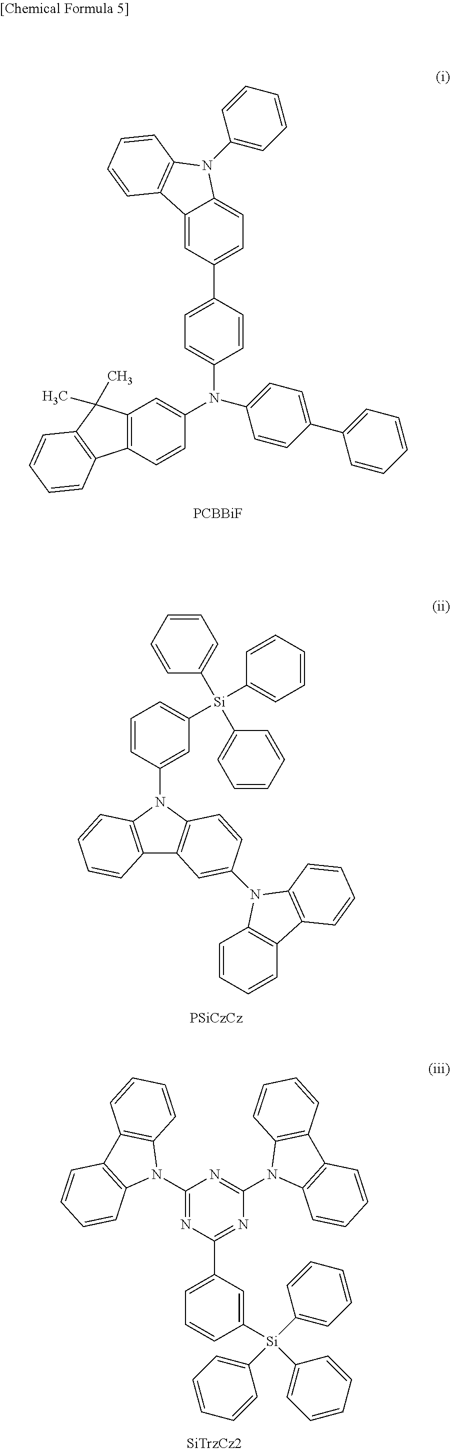

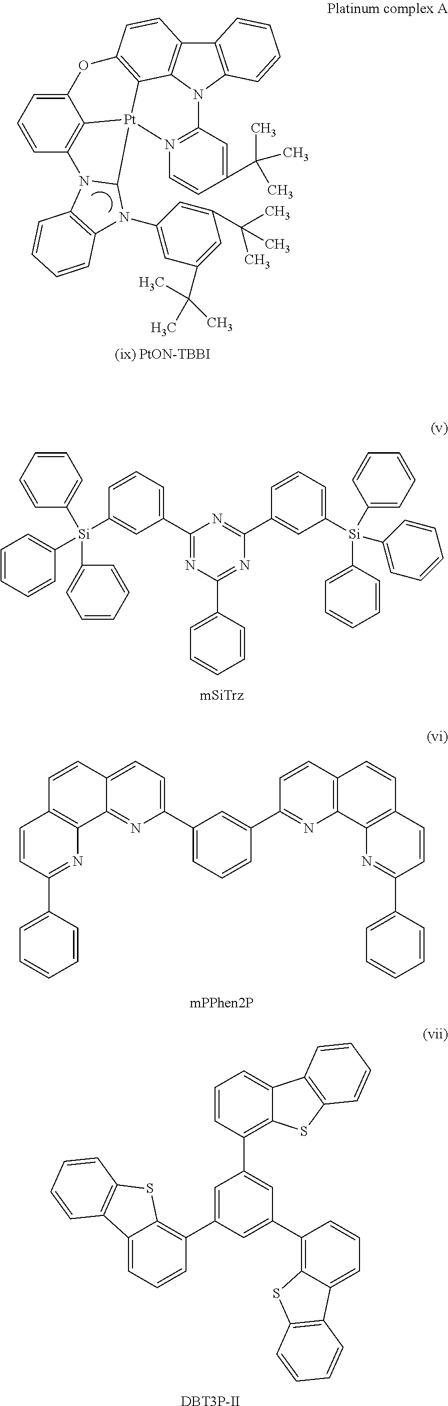

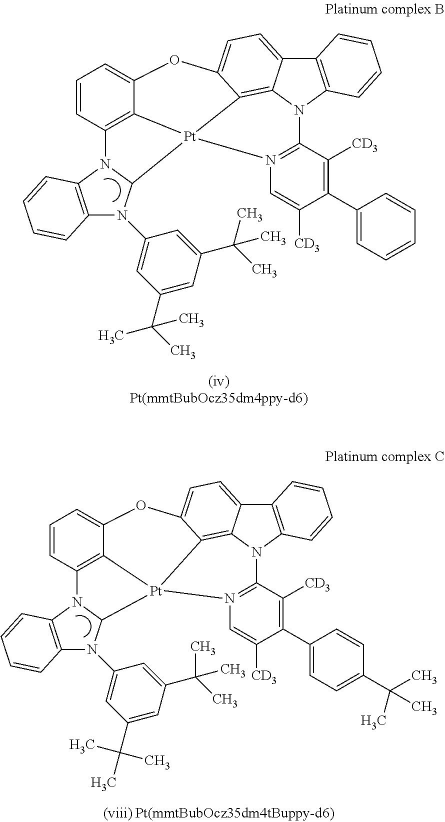

### (Method for Fabricating Light-Emitting Device 1Aa)

A light-emitting device 1Aa was fabricated as the light-emitting device for orientation measurement, in which the platinum complex A was used as an emission center substance and a thickness adjustment layer was formed to facilitate obtaining the value of a indicating an orientation state.

First, indium tin oxide containing silicon oxide (ITSO) was stacked over a glass substrate to a thickness of 70 nm by a sputtering method, so that the first electrode 101 having a size of 2 mm×2 mm was formed. Note that the first electrode 101 functions as an anode.

Then, pretreatment for formation of the light-emitting device over the substrate was performed by washing the substrate surface with water.

After that, the substrate was transferred into a vacuum evaporation apparatus where the pressure was reduced to approximately 1×10⁻⁴ Pa, and was subjected to vacuum baking at 170° C. for 30 minutes in a heating chamber of the vacuum evaporation apparatus, and then the substrate was cooled down for approximately 30 minutes.

Then, the substrate was fixed to a holder provided in the vacuum evaporation apparatus such that the surface on which the first electrode 101 was formed faced downward. Over the inorganic insulating film and the first electrode 101, N-(biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (i) above and a fluorine-containing electron acceptor material with a molecular weight of 672 (OCHD-003) were deposited by co-evaporation to a thickness of 10 nm such that the weight ratio of PCBBiF to OCHD-003 was 1:0.03, whereby the hole-injection layer 111 was formed.

Over the hole-injection layer 111, PCBBiF was deposited by evaporation to a thickness of 30 nm to form a first hole-transport layer and 9-[3-(triphenylsilyl)phenyl]-3,9′-bi-9H-carbazole (abbreviation: PSiCzCz) represented by Structural Formula (ii) above was subsequently deposited by evaporation to a thickness of 5 nm to form a second hole-transport layer, whereby the hole-transport layer 112 was formed. Note that the second hole-transport layer also functions as an electron-blocking layer.

Then, over the hole-transport layer 112, 9,9′-{6-[3-(triphenylsilyl)phenyl]-1,3,5-triazine-2,4-diyl}bis(9H-carbazole) (abbreviation: SiTrzCz2) represented by Structural Formula (iii) above, PSiCzCz, and the platinum complex A (PtON-TBBI) were deposited by co-evaporation to a thickness of 35 nm such that the weight ratio between SiTrzCz2, PSiCzCz, and PtON-TBBI was 0.45:0.45:0.10, whereby the light-emitting layer 113 was formed.

After that, 2-phenyl-4,6-bis[3-(triphenylsilyl)phenyl]-1,3,5-triazine (abbreviation: mSiTrz) represented by Structural Formula (v) above was deposited by evaporation to a thickness of 5 nm to form a first electron-transport layer, and then 2,2′-(1,3-phenylene)bis(9-phenyl-1,10-phenanthroline) (abbreviation: mPPhen2P) represented by Structural Formula (vi) above was deposited by evaporation to a thickness of 20 nm to form a second electron-transport layer, whereby the electron-transport layer 114 was formed.

Next, lithium oxide (Li₂O) was deposited by evaporation to a thickness of 0.1 nm, whereby the electron-injection layer 115 was formed.

After that, copper phthalocyanine was deposited by evaporation to a thickness of 2 nm, and 4,4′,4″-(benzene-1,3,5-triyl)tri(dibenzothiophene) (abbreviation: DBT3P-II) represented by Structural Formula (vii) above and molybdenum oxide (MoOₓ) were deposited by co-evaporation to a thickness of 55 nm such that the weight ratio of DBT3P-II to MoOₓ was 1:0.5, whereby a thickness adjustment layer 217 was formed.

Then, aluminum (Al) was deposited by evaporation to a thickness of 200 nm, whereby the second electrode 102 was formed.

Then, the light-emitting device was sealed using a glass substrate in a glove box containing a nitrogen atmosphere so as not to be exposed to the air. Specifically, a UV curable sealing material was applied to surround the device, only the sealing material was irradiated with UV while the light-emitting device was not irradiated with the UV, and heat treatment was performed at 80° C. under an atmospheric pressure for one hour. In this manner, the light-emitting device 1Aa was fabricated.

### (Method for Fabricating Light-Emitting Device 1Ab)

A light-emitting device 1Ab contains the platinum complex A as an emission center substance. Since the structures and fabrication methods of the light-emitting device 1Ab and the light-emitting device 1Aa are the same except for the presence of the thickness adjustment layer, the orientation states of the emission center substances in the light-emitting layers are the same.

The light-emitting device 1Ab was fabricated in the same manner as the light-emitting device 1Aa except that the thickness adjustment layer 217 was not formed and the second electrode 102 was formed immediately after the formation of the electron-injection layer 115.

### (Method for Fabricating Light-Emitting Device 1Ba)

A light-emitting device 1Ba was fabricated as the light-emitting device for orientation measurement, in which the platinum complex B was used as an emission center substance and a thickness adjustment layer was formed to facilitate obtaining the value of a indicating an orientation state.

The light-emitting device 1Ba was fabricated in the same manner as the light-emitting device 1Aa except that the platinum complex A in the light-emitting device 1Aa was replaced with the platinum complex B (Pt(mmtBubOcz35dm4ppy-d6)).

### (Method for Fabricating Light-Emitting Device 1Bb)

A light-emitting device 1Bb contains the platinum complex B as an emission center substance. Since the structures and fabrication methods of the light-emitting device 1Bb and the light-emitting device 1Ba are the same except for the presence of the thickness adjustment layer, the orientation states of the emission center substances in the light-emitting layers are the same.

The light-emitting device 1Bb was fabricated in the same manner as the light-emitting device 1Ba except that the thickness adjustment layer 217 was not formed and the second electrode 102 was formed immediately after the formation of the electron-injection layer 115.

### (Method for Fabricating Light-Emitting Device 1Ca)

A light-emitting device 1Ca was fabricated as the light-emitting device for orientation measurement, in which the platinum complex C was used as an emission center substance and a thickness adjustment layer was formed to facilitate obtaining the value of a indicating an orientation state.

The light-emitting device 1Ca was fabricated in the same manner as the light-emitting device 1Aa except that the platinum complex A in the light-emitting device 1Aa was replaced with the platinum complex C (Pt(mmtBubOcz35dm4tBuppy-d6)).

(Method for Fabricating Light-Emitting Device 1Cb) A light-emitting device 1Cb contains the platinum complex C as an emission center substance. Since the structures and fabrication methods of the light-emitting device 1Cb and the light-emitting device 1Ca are the same except for the presence of the thickness adjustment layer, the orientation states of the emission center substances in the light-emitting layers are the same.

The light-emitting device 1Cb was fabricated in the same manner as the light-emitting device 1Ca except that the thickness adjustment layer 217 was not formed and the second electrode 102 was formed immediately after the formation of the electron-injection layer 115.

The device structures of the light-emitting device 1Aa, the light-emitting device 1Ab, the light-emitting device 1Ba, the light-emitting device 1Bb, the light-emitting device 1Ca, and the light-emitting device 1Cb are shown below.

TABLE 4

| | Thickness | Light-emitting | Light-emitting |
|---|---|---|---|
| | (nm) | device 1Xa | device 1Xb |
| Second electrode | 200 | Al | |
| Thickness | 55 | DBT3P-II:MoOx | — |
| adjustment layer | | (1:0.5) | |
| | 2 | CuPC | — |

| | | |
|---|---|---|
| Electron-injection | 0.1 | Li₂O |
| layer | | |
| Electron-transport | 20 | mPPhen2P |
| layer | 5 | mSiTrz |
| Light-emitting layer | 35 | SiTrzCz2:PSiCzCz:*1 |
| | | (0.45:0.45:0.10) |
| Hole-transport layer | 5 | PSiCzCz |
| | 30 | PCBBiF |
| Hole-injection layer | 10 | PCBBiF:OCHD-003 (1:0.03) |
| First electrode | 70 | ITSO |

*1 X = A: Platinum complex A
X = B: Platinum complex B
X = C: Platinum complex C

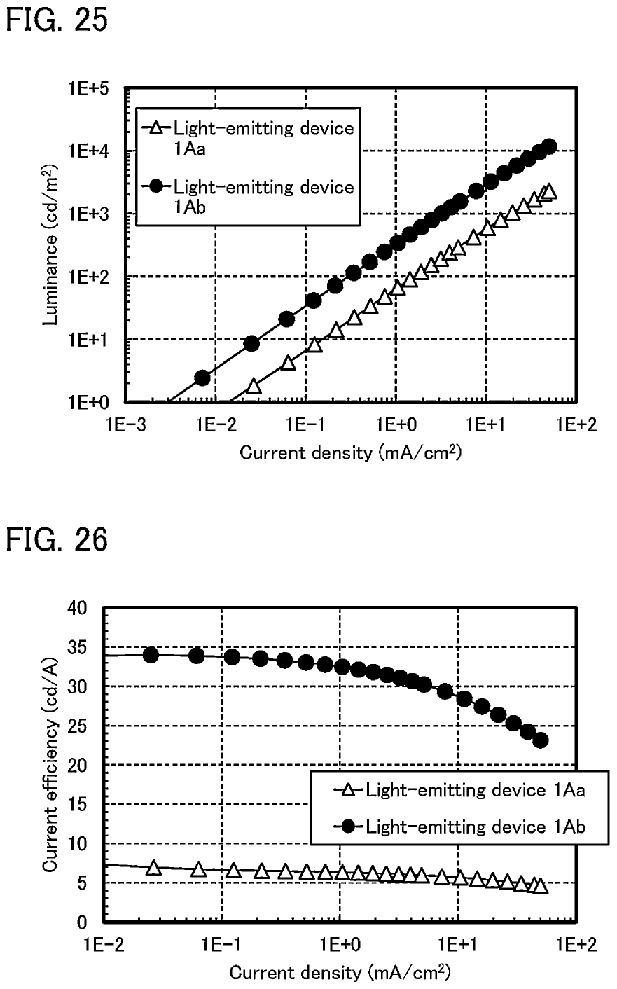

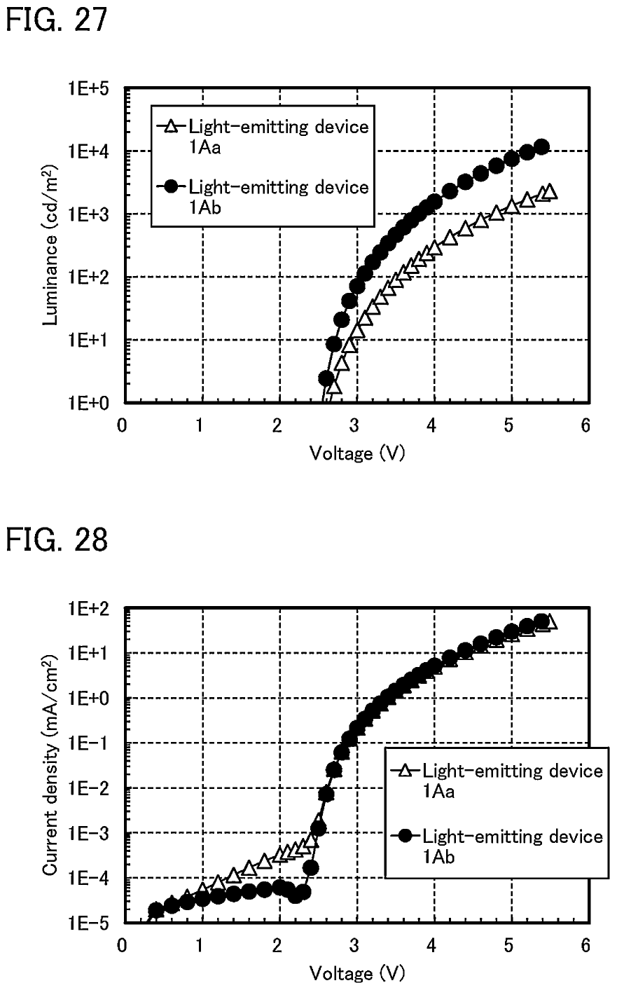

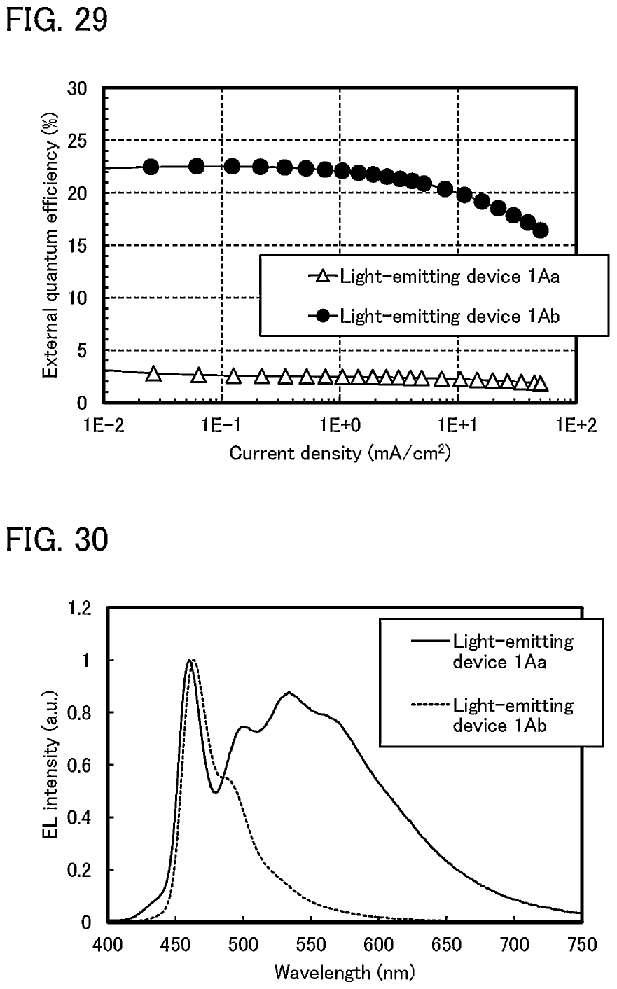

FIG. 25 shows the luminance-current density characteristics of the light-emitting devices 1Aa and 1Ab. FIG. 26 shows the current efficiency-current density characteristics thereof. FIG. 27 shows the luminance-voltage characteristics thereof. FIG. 28 shows the current density-voltage characteristics thereof. FIG. 29 shows the external quantum efficiency-current density characteristics thereof. FIG. 30 shows electroluminescence spectra thereof.

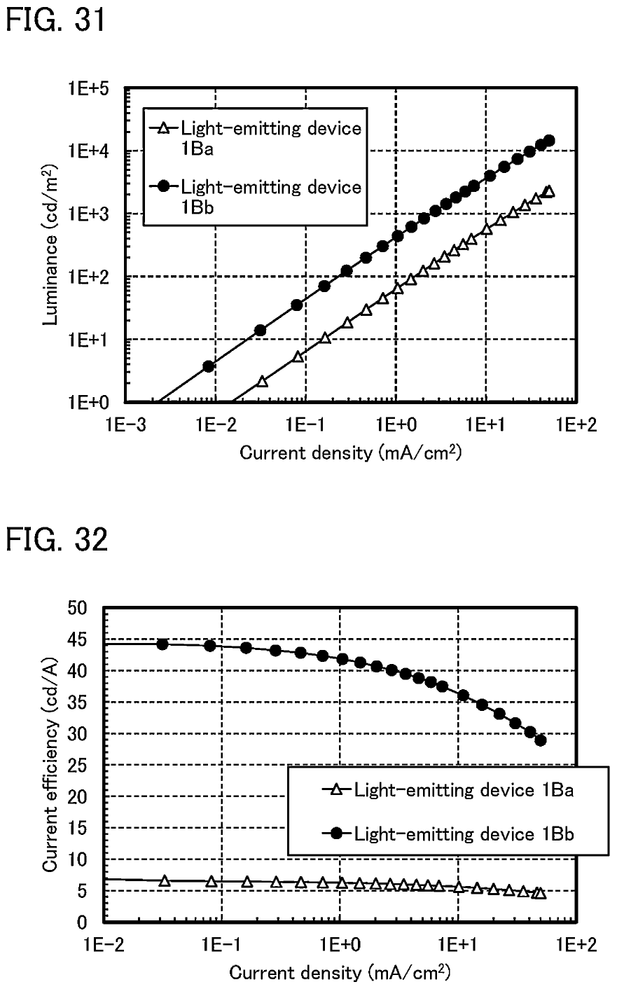

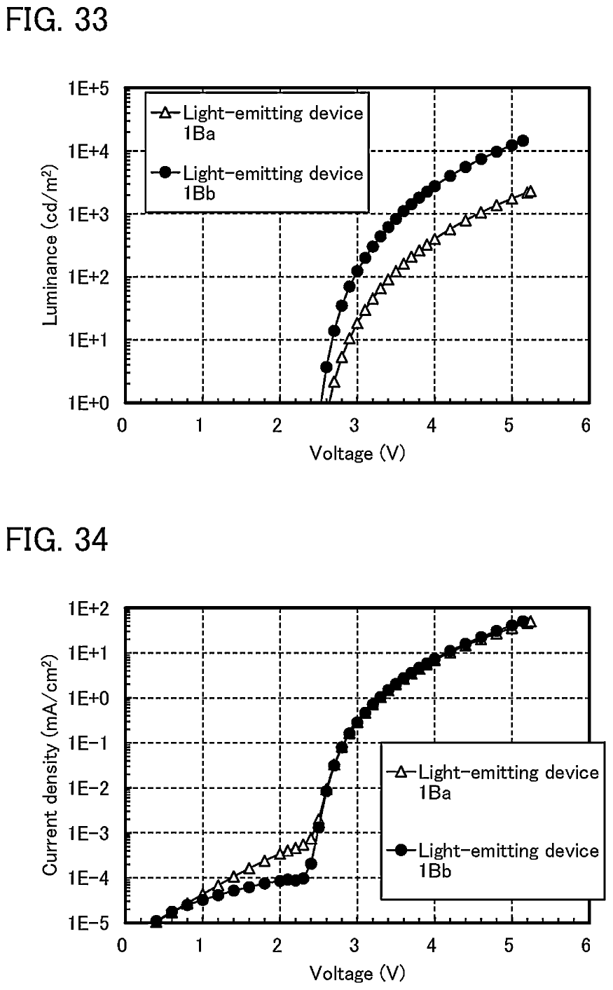

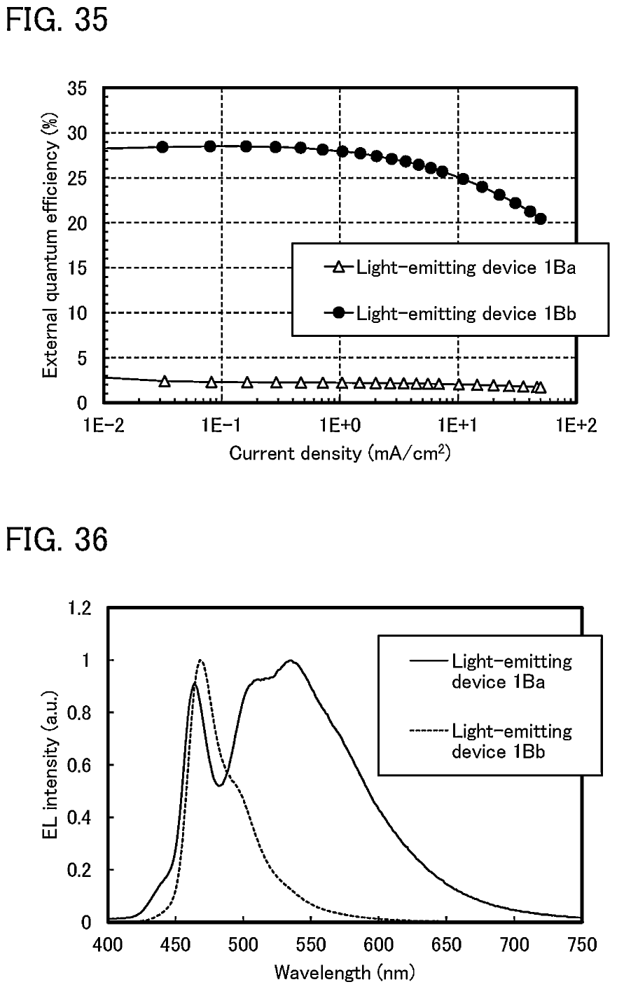

FIG. 31 shows the luminance-current density characteristics of the light-emitting devices 1Ba and 1Bb. FIG. 32 shows the current efficiency-current density characteristics thereof. FIG. 33 shows the luminance-voltage characteristics thereof. FIG. 34 shows the current density-voltage characteristics thereof. FIG. 35 shows the external quantum efficiency-current density characteristics thereof. FIG. 36 shows electroluminescence spectra thereof.

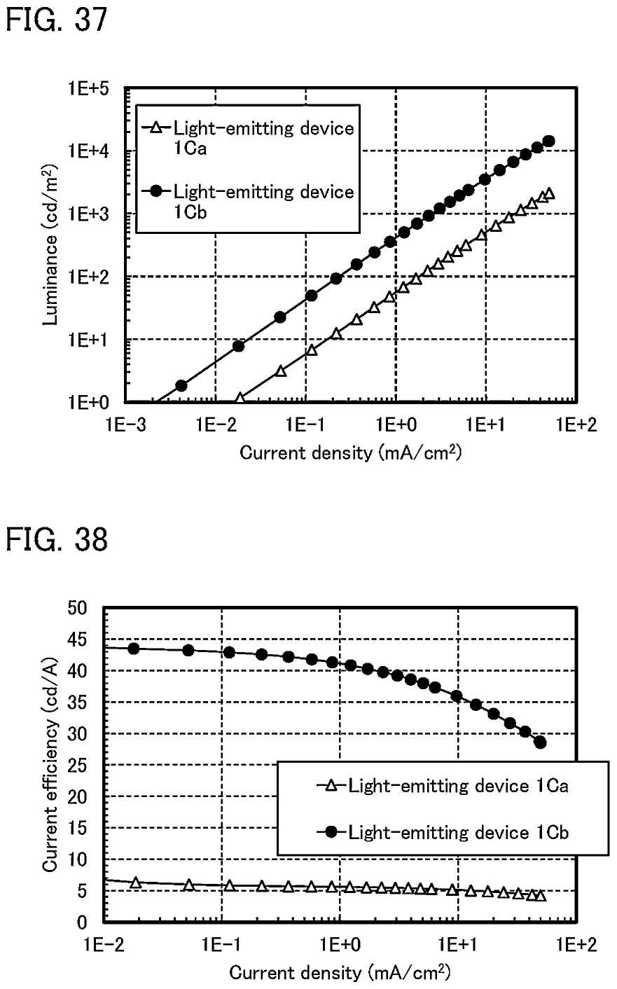

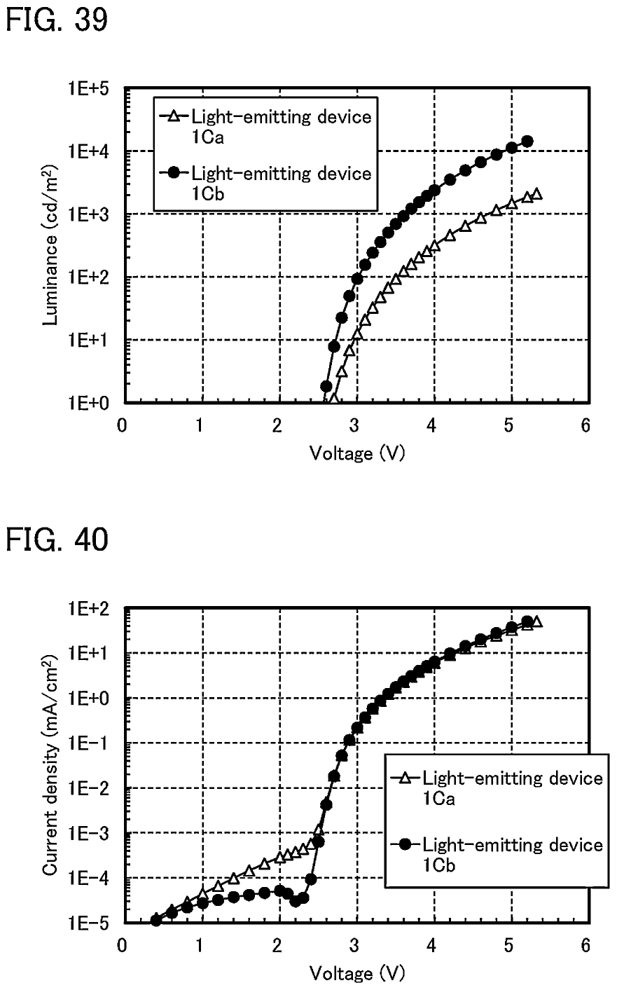

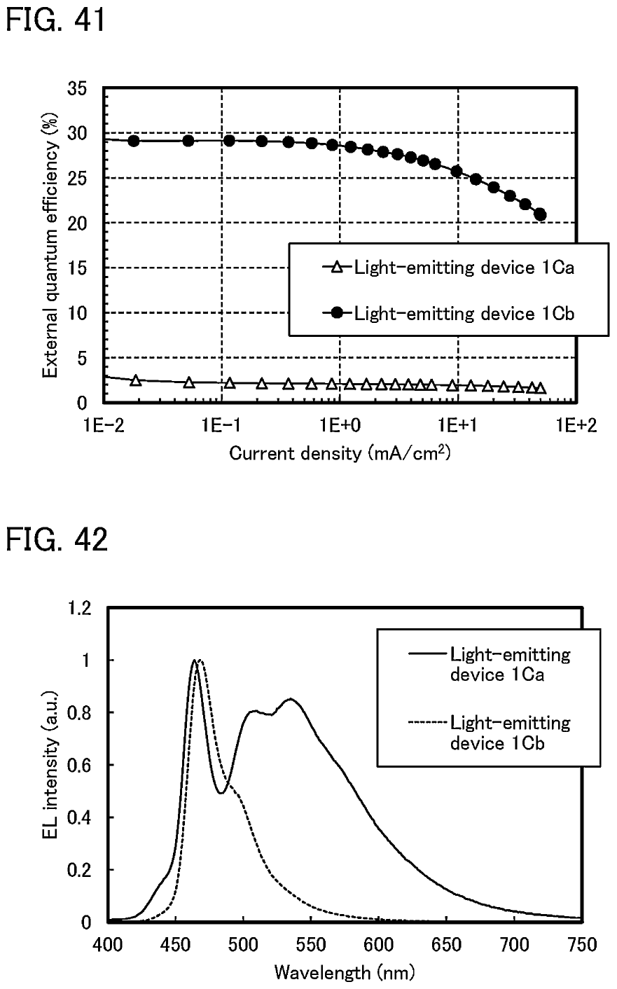

FIG. 37 shows the luminance-current density characteristics of the light-emitting devices 1Ca and 1Cb. FIG. 38 shows the current efficiency-current density characteristics thereof. FIG. 39 shows the luminance-voltage characteristics thereof. FIG. 40 shows the current density-voltage characteristics thereof. FIG. 41 shows the external quantum efficiency-current density characteristics thereof. FIG. 42 shows electroluminescence spectra thereof.

The values of the voltage, current, current density, CIE chromaticity, current efficiency, external quantum efficiency, and blue index (BI) at around 1000 cd/cm² of the light-emitting device 1Aa, the light-emitting device 1Ab, the light-emitting device 1Ba, the light-emitting device 1Bb, the light-emitting device 1Ca, and the light-emitting device 1Cb are shown below. The luminance, CIE chromaticity, and electroluminescence spectra were measured at normal temperature with a spectroradiometer (SR-UL1R, produced by TOPCON TECHNOHOUSE CORPORATION).

TABLE 5

| | | | Current | | | Current | External | |
|---|---|---|---|---|---|---|---|---|
| | Voltage | Current | density | Chromaticity | Chromaticity | efficiency | quantum | BI |
| | (V) | (mA) | (mA/cm²) | x | y | (cd/A) | efficiency (%) | (cd/A/y) |
| Light-emitting | 4.8 | 0.788 | 19.69 | 0.32 | 0.41 | 5 | 2 | 13 |
| device 1Aa | | | | | | | | |
| Light-emitting | 3.8 | 0.130 | 3.24 | 0.14 | 0.20 | 31 | 21 | 155 |
| device 1Ab | | | | | | | | |

TABLE 6

| | | | Current | | | Current | External | |
|---|---|---|---|---|---|---|---|---|
| | Voltage | Current | density | Chromaticity | Chromaticity | efficiency | quantum | BI |
| | (V) | (mA) | (mA/cm²) | x | y | (cd/A) | efficiency (%) | (cd/A/y) |
| Light-emitting | 4.6 | 0.801 | 20.02 | 0.30 | 0.44 | 5 | 2 | 12 |
| device 1Ba | | | | | | | | |
| Light-emitting | 3.6 | 0.110 | 2.74 | 0.13 | 0.22 | 40 | 27 | 185 |
| device 1Bb | | | | | | | | |

TABLE 7

| | | | Current | | | Current | External | |
|---|---|---|---|---|---|---|---|---|
| | Voltage | Current | density | Chromaticity | Chromaticity | efficiency | quantum | BI |
| | (V) | (mA) | (mA/cm²) | x | y | (cd/A) | efficiency (%) | (cd/A/y) |
| Light-emitting | 4.6 | 0.715 | 17.88 | 0.28 | 0.42 | 5 | 2 | 12 |
| device 1Ca | | | | | | | | |
| Light-emitting | 3.6 | 0.093 | 2.32 | 0.13 | 0.21 | 40 | 28 | 193 |
| device 1Cb | | | | | | | | |

According to FIGS. 25 to 42 and Tables 5 to 7, it is found that the emission efficiency of each of the light-emitting device 1Aa, the light-emitting device 1Ba, and the light-emitting device 1Ca is decreased as a result of the front luminance reduction by the thickness adjustment layer. The light-emitting device 1Ab, the light-emitting device 1Bb, and the light-emitting device 1Cb have higher emission efficiency than the light-emitting device 1Aa, the light-emitting device 1Ba, and the light-emitting device 1Ca. In particular, the light-emitting device 1Bb and the light-emitting device 1Cb have extremely high efficiency and BI.

Next, the orientation characteristics of the light-emitting device 1Aa, the light-emitting device 1Ba, and the light-emitting device 1Ca were measured and calculated.

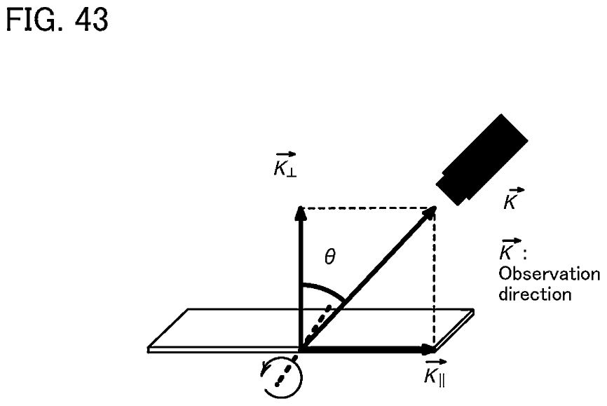

First, as shown in FIG. 43, the angle dependence of the shape of the EL emission spectrum was measured by measuring the EL emission spectrum in steps of 1° in the following manner: the substrate provided with the light-emitting device for orientation measurement (any of the light-emitting devices 1Aa, 1Ba, and 1Ca) was inclined to a detector (a multi-channel spectrometer PMA-12, produced by Hamamatsu Photonics K.K.) from θ=0° to 80°. In this measurement, a linear polarizer (Glan-Taylor prism) was interposed between the light-emitting device for orientation measurement and the detector to be perpendicular to the substrate surface in order to remove an S polarization from light emitted from the light-emitting device for orientation measurement, so that the spectrum of only a P polarization was measured.

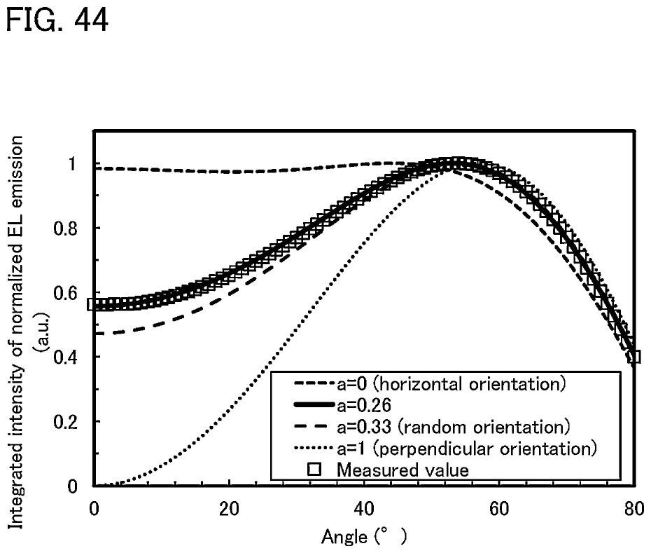

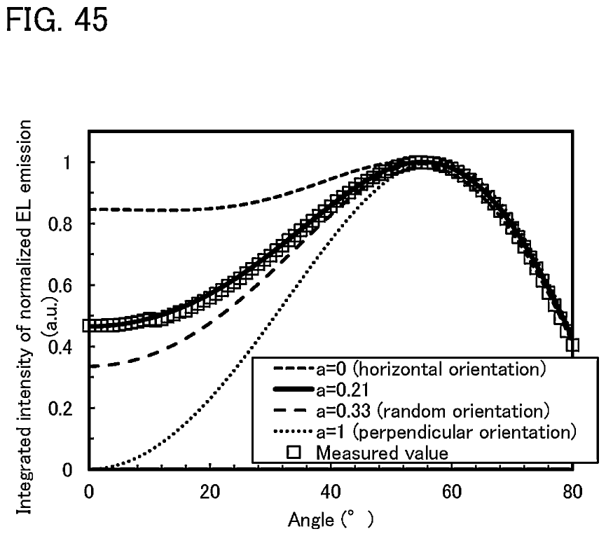

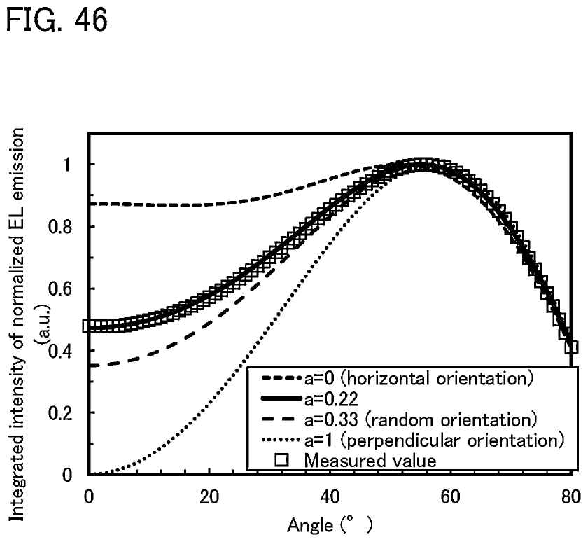

FIG. 44, FIG. 45, and FIG. 46 are graphs in each of which the vertical axis represents the integrated intensity of the EL emission spectrum from 420 nm to 750 nm depending on the angle (θ) and the horizontal axis represents the angle (θ) of the detector to the substrate. FIG. 44 shows the results of the light-emitting device 1Aa, FIG. 45 shows the results of the light-emitting device 1Ba, and FIG. 46 shows the results of the light-emitting device 1Ca.

In each graph, a curve plotted by open squares represents the measured values, and a solid curve and a dashed curve represent the calculation results obtained by setfos which is an organic device simulator. The calculation was performed by inputting the thickness of each layer in the device, the measured values of the refractive index and the extinction coefficient, the measured value of the emission spectrum of the dopant, the position and the width of a light-emitting region, and the orientation parameter a.

Among them, the thickness of each layer, the refractive index, and the extinction coefficient were measured with a spectroscopic ellipsometer (M-2000U, produced by J. A. Woollam Japan). A film used for the measurement was formed of the material over a quartz substrate by a vacuum evaporation method to a thickness of 50 nm.

The emission spectrum of the dopant was measured with a detector (a multi-channel spectrometer PMA-12, produced by Hamamatsu Photonics K.K.). A film used for the measurement was formed over a quartz substrate by co-evaporation using a vacuum evaporation method to have a thickness of 50 nm and the same composition as the light-emitting layer of the light-emitting device for orientation measurement.

Furthermore, the light-emitting region was set in the calculation by setfos. In the light-emitting device 1Aa, the state of the light-emitting region was assumed in which the recombination probability shows a Gaussian attenuation curve with respect to the cathode direction with the interface between the hole-transport layer and the light-emitting layer as a top, and the light-emitting region was set to spread such that the standard deviation σ of the Gaussian function was 15 nm. In the light-emitting device 1Ba, the state of the light-emitting region was assumed in which the recombination probability shows a Gaussian attenuation curve with respect to the cathode direction and the anode direction with a point 3.5 nm away from the interface between the hole-transport layer and the light-emitting layer in the cathode direction as a top, and the light-emitting region was set to spread such that the standard deviation a of the Gaussian function was 8.5 nm. In the light-emitting device 1Ca, the state of the light-emitting region was assumed in which the recombination probability shows a Gaussian attenuation curve with respect to the cathode direction with the interface between the hole-transport layer and the light-emitting layer as a top, and the light-emitting region was set to spread such that the standard deviation a of the Gaussian function was 11 nm. Note that the reason why the light-emitting regions of the light-emitting devices are set in different manners is that the carrier recombination region changes depending on the carrier-trapping property, which differs between the platinum complexes in the light-emitting layers.

In this manner, the angle dependence of the integrated intensity of the emission spectrum corresponding to each orientation parameter a can be calculated. The results of the light-emitting device 1Aa agree well with the graph with a of 0.26, the results of the light-emitting device 1Ba agree well with the graph with a of 0.21, and the results of the light-emitting device 1Ca agree well with the graph with a of 0.22.

The above results show that the orientation of the platinum complex used as the emission center substance in the light-emitting layer in each of the light-emitting device 1Bb and the light-emitting device 1Cb is closer to horizontal orientation than the orientation of the platinum complex used as the emission center substance in the light-emitting layer in the light-emitting device 1Ab.

According to Tables 5 to 7 and FIGS. 25 to 42, the light-emitting device 1Bb and the light-emitting device 1Cb have higher efficiency than the light-emitting device 1Ab, which agrees well with the calculation results of the inner products of the vector A and the vector B and the orientation parameters a.

According to the orientation parameters a, the platinum complex B and the platinum complex C have better orientation characteristics than the platinum complex A. This result probably correlates to the difference in the inner product of the vector A and the vector B as shown in Table 3. In each of the platinum complex B and the platinum complex C, the transition dipole moment contributes greatly to an improvement in emission efficiency; thus, a light-emitting apparatus or a light-emitting device formed using a light-emitting apparatus material or a light-emitting device material that contains the platinum complex B or the platinum complex C can have high emission efficiency.

Note that an efficiency improvement effect derived from the difference in the molecular orientation parameter a between the light-emitting device 1Ab and the light-emitting device 1Bb or the light-emitting device 1Cb is from 5% to 7%. The main factor of the efficiency improvement effect in each of the light-emitting device 1Bb and the light-emitting device 1Cb is probably a large inner product of the vector A and the vector B.

### Example 2

In this example, fabrication methods and characteristics of a light-emitting device 2a and a light-emitting device 2b of one embodiment of the present invention and a comparative light-emitting device 2 as a comparative example will be described in detail. Structural formulae of main compounds used for the light-emitting devices 2a and 2b and the comparative light-emitting device 2 are shown below.

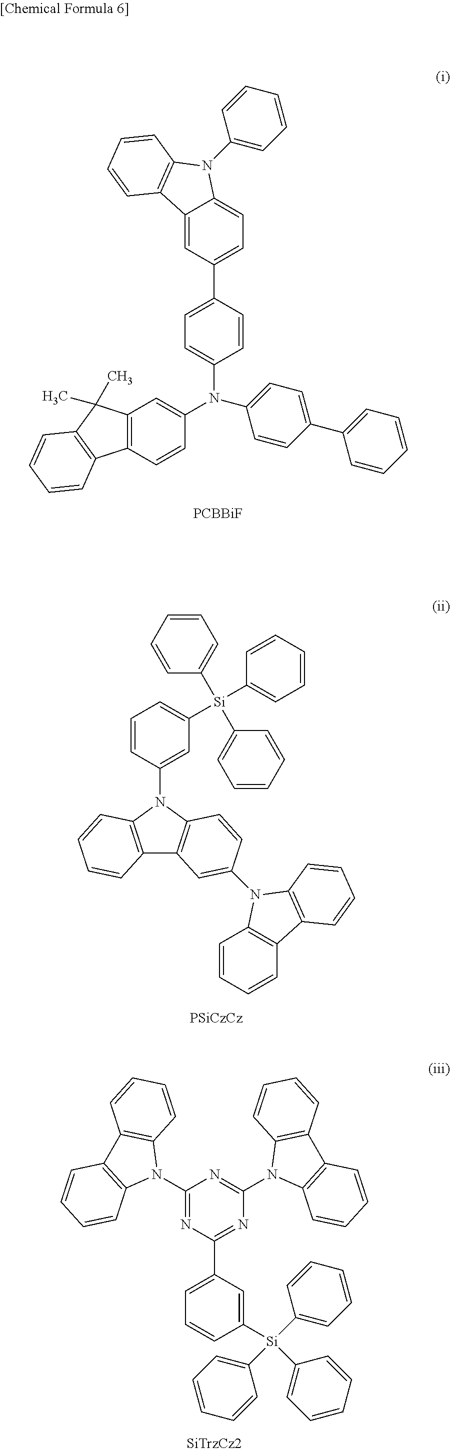

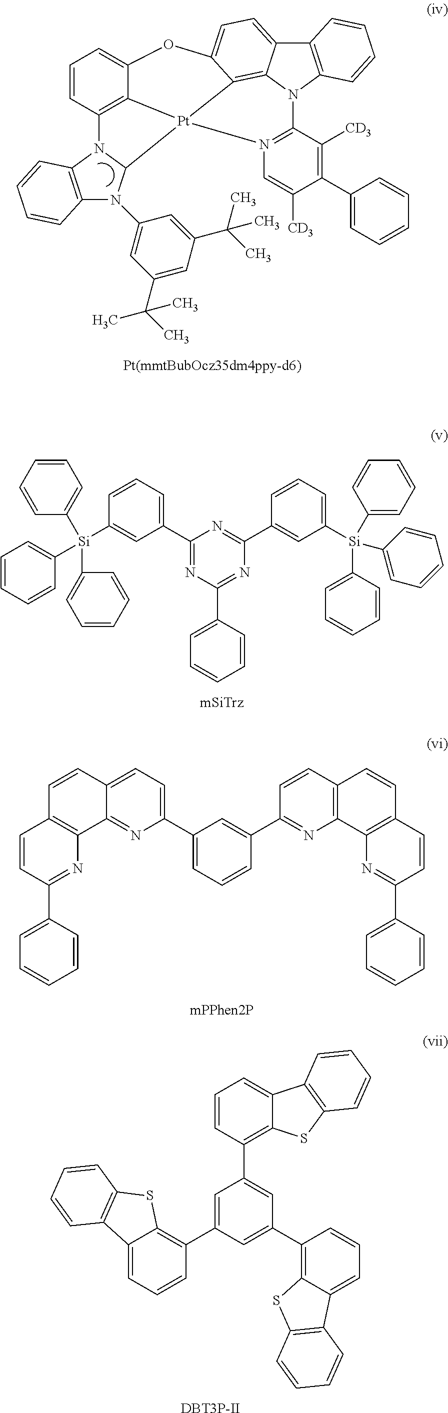

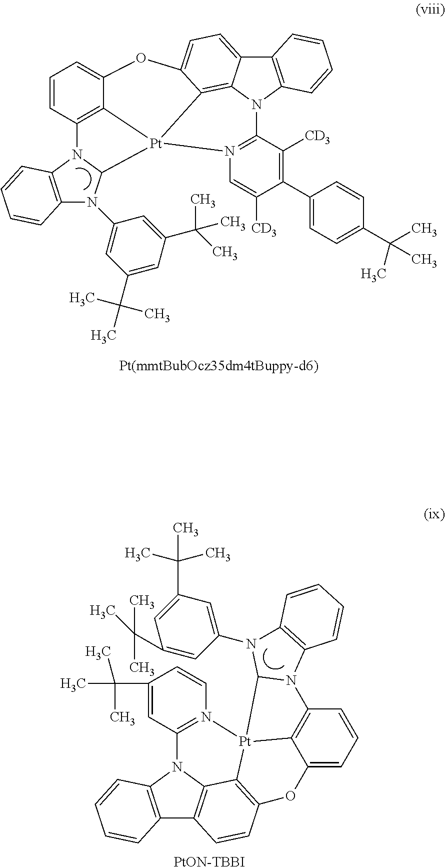

### (Method for Fabricating Light-Emitting Device 2a)

First, 100-nm-thick silver (Ag) and 10-nm-thick indium tin oxide containing silicon oxide (ITSO) were sequentially stacked over a glass substrate by a sputtering method, whereby the first electrode 101 with a size of 2 mm×2 mm was formed. Note that the first electrode 101 functions as an anode.

Then, pretreatment for formation of the light-emitting device over the substrate was performed by washing the substrate surface with water.

After that, the substrate was transferred into a vacuum evaporation apparatus where the pressure was reduced to approximately 1×10⁻⁴ Pa, and was subjected to vacuum baking at 170° C. for 30 minutes in a heating chamber of the vacuum evaporation apparatus, and then the substrate was cooled down for approximately 30 minutes.

Then, the substrate was fixed to a holder provided in the vacuum evaporation apparatus such that the surface on which the first electrode 101 was formed faced downward. Over the inorganic insulating film and the first electrode 101, N-(biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (i) above and a fluorine-containing electron acceptor material with a molecular weight of 672 (OCHD-003) were deposited by co-evaporation to a thickness of 10 nm such that the weight ratio of PCBBiF to OCHD-003 was 1:0.03, whereby the hole-injection layer 111 was formed.

Over the hole-injection layer 111, PCBBiF was deposited by evaporation to a thickness of 120 nm to form a first hole-transport layer and 9-[3-(triphenylsilyl)phenyl]-3,9′-bi-9H-carbazole (abbreviation: PSiCzCz) represented by Structural Formula (ii) above was subsequently deposited by evaporation to a thickness of 5 nm to form a second hole-transport layer, whereby the hole-transport layer 112 was formed. Note that the second hole-transport layer also functions as an electron-blocking layer.

Then, over the hole-transport layer 112, 9,9′-{6-[3-(triphenylsilyl)phenyl]-1,3,5-triazine-2,4-diyl}bis(9H-carbazole) (abbreviation: SiTrzCz2) represented by Structural Formula (iii) above, PSiCzCz, and (2-{3-[3-(3,5-di-tert-butylphenyl)benzimidazol-1-yl-2-ylidene-κC²]phenoxy-κC²}-9-[3,5-di(methyl-d3)-4-phenyl-2-pyridinyl-κN]carbazole-2,1-diyl-κC)platinum(II) (abbreviation: Pt(mmtBubOcz35dm4ppy-d6)) (the platinum complex B in Example 1) represented by Structural Formula (iv) above were deposited by co-evaporation to a thickness of 35 nm such that the weight ratio between SiTrzCz2, PSiCzCz, and Pt(mmtBubOcz35dm4ppy-d6) was 0.45:0.45:0.10, whereby the light-emitting layer 113 was formed.

After that, 2-phenyl-4,6-bis[3-(triphenylsilyl)phenyl]-1,3,5-triazine (abbreviation: mSiTrz) represented by Structural Formula (v) above was deposited by evaporation to a thickness of 5 nm to form a first electron-transport layer, and then 2,2′-(1,3-phenylene)bis(9-phenyl-1,10-phenanthroline) (abbreviation: mPPhen2P) represented by Structural Formula (vi) above was deposited by evaporation to a thickness of 20 nm to form a second electron-transport layer, whereby the electron-transport layer 114 was formed.

After that, lithium fluoride (LiF) was deposited by evaporation to a thickness of 1 nm to form the electron-injection layer 115, and then silver (Ag) and magnesium (Mg) were deposited by co-evaporation to a thickness of 15 nm such that the volume ratio of Ag to Mg was 1:0.1, whereby the second electrode 102 was formed. Over the second electrode, 4,4′,4″-(benzene-1,3,5-triyl)tri(dibenzothiophene) (abbreviation: DBT3P-II) represented by Structural Formula (vii) above was deposited by evaporation to a thickness of 70 nm to form a cap layer.

Then, the light-emitting device was sealed using a glass substrate in a glove box containing a nitrogen atmosphere so as not to be exposed to the air. Specifically, a UV curable sealing material was applied to surround the device, only the sealing material was irradiated with UV while the light-emitting device was not irradiated with the UV, and heat treatment was performed at 80° C. under an atmospheric pressure for one hour. In this manner, the light-emitting device 2a was fabricated.

### (Method for Fabricating Light-Emitting Device 2b)

The light-emitting device 2b was fabricated in the same manner as the light-emitting device 2a except that Pt(mmtBubOcz35dm4ppy-d6) in the light-emitting device 2a was replaced with (2-{3-[3-(3,5-di-tert-butylphenyl)benzimidazol-1-yl-2-ylidene-κC²]phenoxy-κC²}-9-[3,5-di(methyl-d3)-4-tert-butylphenyl-2-pyridinyl-κN]carbazole-2,1-diyl-κC)platinum(II) (abbreviation: Pt(mmtBubOcz35dm4tBuppy-d6)) (the platinum complex C in Example 1) represented by Structural Formula (viii) above.

### (Method for Fabricating Comparative Light-Emitting Device 2)

The comparative light-emitting device 2 was fabricated in the same manner as the light-emitting device 2a except that Pt(mmtBubOcz35dm4ppy-d6) in the light-emitting device 2a was replaced with (2-{3-[3-(3,5-di-tert-butylphenyl)benzimidazol-1-yl-2-ylidene-κC²]phenoxy-κC²}-9-(4-tert-butyl-2-pyridinyl-κN)carbazole-2,1-diyl-κC¹)platinum(II) (abbreviation: PtON-TBBI) (the platinum complex A in Example 1) represented by Structural Formula (ix) above.

Device structures of the light-emitting devices 2a and 2b and the comparative light-emitting device 2 are shown below.

TABLE 8

| | | | |
|---|---|---|---|
| | | | Comparative |
| | Light- | Light- | light- |
| Thickness | emitting | emitting | emitting |
| (nm) | device 2a | device 2b | device 2 |

| | | |
|---|---|---|
| Cap layer | 70 | DBT3P-II |
| Second electrode | 15 | Ag:Mg (1:0.1) |
| Electron-injection | 1 | LiF |
| layer | | |
| Electron-transport | 20 | mPPhen2P |
| layer | 5 | mSiTrz |
| Light-emitting | 35 | SiTrzCz2:PSiCzCz:*1 |
| layer | | (0.45:0.45:0.10) |
| Hole-transport | 5 | PSiCzCz |
| layer | 120 | PCBBiF |
| Hole-injection | 10 | PCBBiF:OCHD-003 (1:0.03) |
| layer | | |
| First electrode | 10 | ITSO |
| | 100 | Ag |

*1 Light-emitting device 2a: Pt(mmtBubOcz35dm4ppy-d6)
Light-emitting device 2b: Pt(mmtBubOcz35dm4tBuppy-d6)
Comparative light-emitting device 2: PtON-TBBI

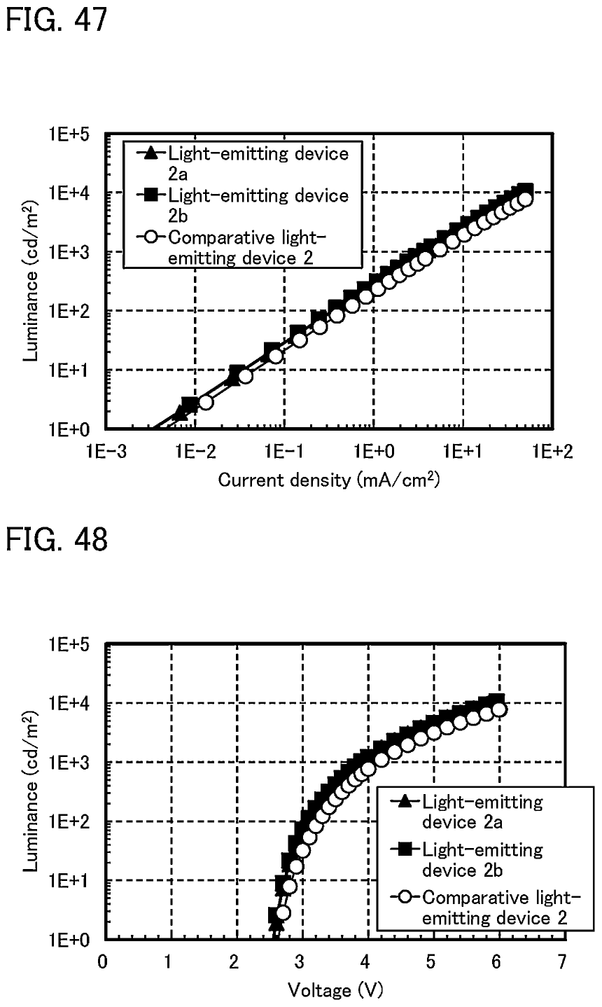

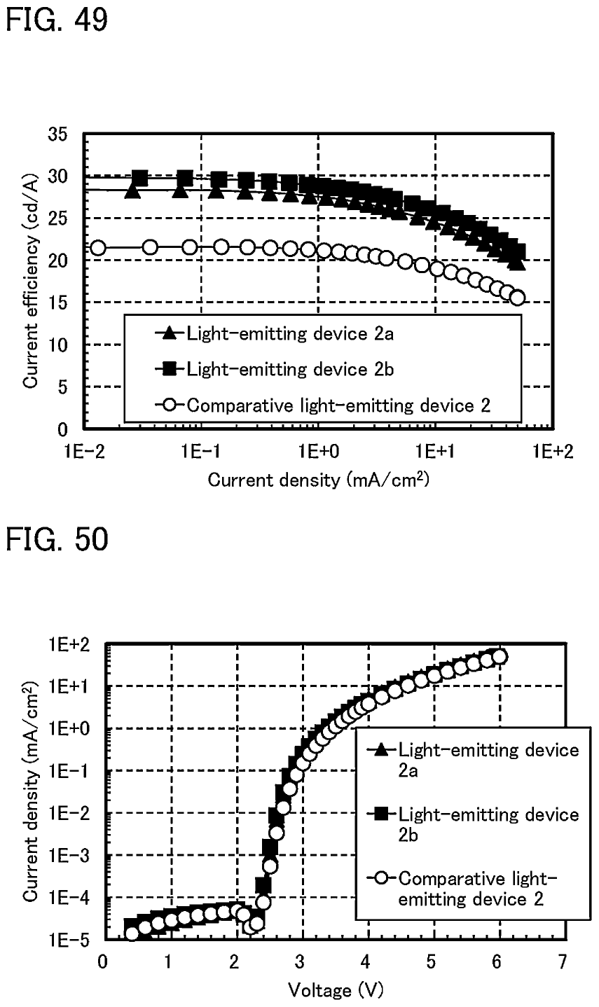

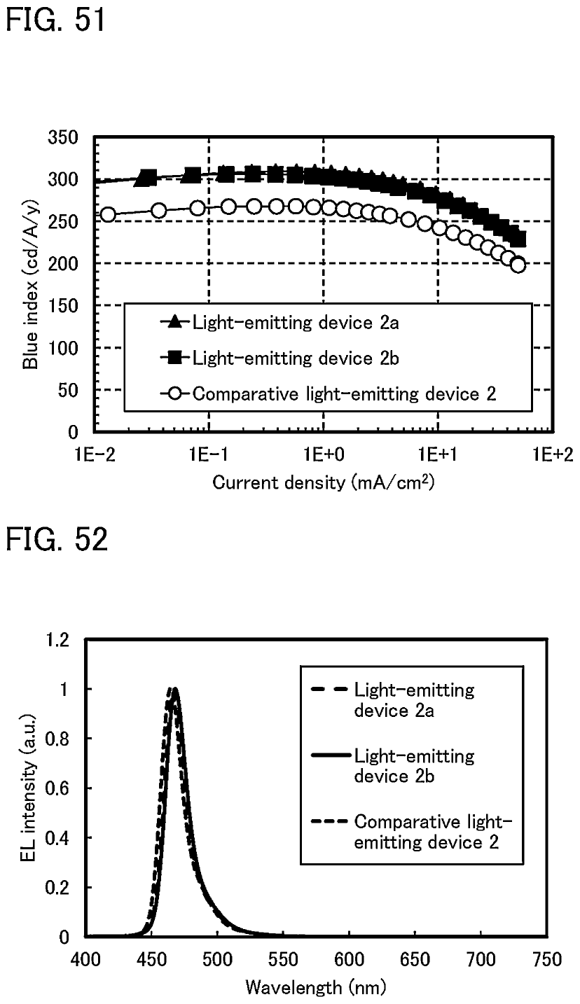

FIG. 47 shows the luminance-current density characteristics of the light-emitting devices 2a and 2b and the comparative light-emitting device 2. FIG. 48 shows the luminance-voltage characteristics thereof. FIG. 49 shows the current efficiency-current density characteristics thereof. FIG. 50 shows the current density-voltage characteristics thereof. FIG. 51 shows the blue index (BI)-current density characteristics thereof. FIG. 52 shows electroluminescence spectra thereof.

The values of the voltage, current, current density, CIE chromaticity, current efficiency, and blue index (BI) at around 1000 cd/cm² are shown below. The luminance, CIE chromaticity, and electroluminescence spectra were measured at normal temperature with a spectroradiometer (SR-UL1R, produced by TOPCON TECHNOHOUSE CORPORATION).

TABLE 9

| | | | Current | | | Current | |
|---|---|---|---|---|---|---|---|
| | Voltage | Current | density | Chromaticity | Chromaticity | efficiency | BI |
| | (V) | (mA) | (mA/cm²) | x | y | (cd/A) | (cd/A/y) |
| Light-emitting | 3.9 | 0.162 | 4.06 | 0.12 | 0.09 | 26 | 297 |
| device 2a | | | | | | | |
| Light-emitting | 3.9 | 0.147 | 3.69 | 0.12 | 0.09 | 28 | 293 |
| device 2b | | | | | | | |
| Comparative | 4.2 | 0.221 | 5.52 | 0.13 | 0.08 | 20 | 252 |
| light-emitting | | | | | | | |
| device 2 | | | | | | | |

According to FIGS. 47 to 52 and Table 9, the light-emitting device 2a and the light-emitting device 2b each have high current efficiency and high blue index.

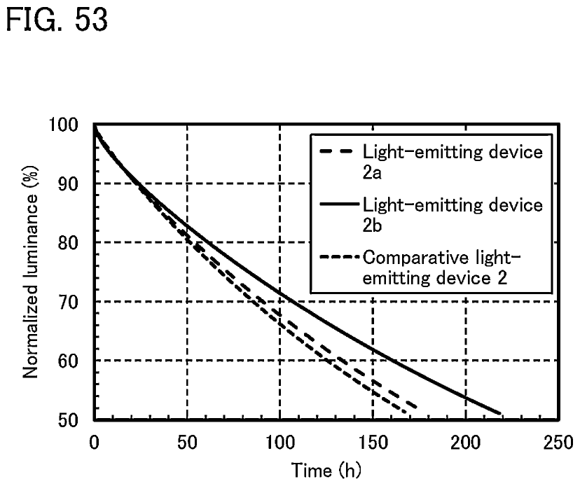

FIG. 53 shows time dependence of normalized luminance of the light-emitting device 2a, the light-emitting device 2b, and the comparative light-emitting device 2. In the measurement, on the assumption of a full-color display device including the light-emitting devices, the initial luminance was set to luminance at which a luminance of 5000 cd/m² was obtained when the display device performed white (D65) display. As for the aperture ratio of the display device, red was 13.4%, green was 13.4%, and blue was 26.7%. The initial luminance, the current density, the time taken for the luminance to decrease to 90% of the initial luminance (LT90), and the time taken for the luminance to decrease to 50% of the initial luminance (LT50) of the light-emitting devices are listed in the following table.

TABLE 10

| | Luminance | Current density | LT90 | LT50 |
|---|---|---|---|---|
| | (cd/m²) | (mA/cm²) | (h) | (h) |
| Light-emitting | 2350 | 9.57 | 22.6 | 185 |
| device 2a | | | | |
| Light-emitting | 2260 | 8.65 | 23.6 | 226 |
| device 2b | | | | |
| Comparative | 1960 | 10.30 | 22.3 | 174 |
| light-emitting | | | | |
| device 2 | | | | |

FIG. 53 reveals that the light-emitting device 2a and the light-emitting device 2b of one embodiment of the present invention each have a smaller time-dependent change in normalized luminance and thus have higher reliability than the comparative light-emitting device 2.

### Reference Example 1

### Synthesis Example 1

In this reference example, the synthesis example of (2-{3-[3-(3,5-di-tert-butylphenyl)benzimidazol-1-yl-2-ylidene-κC²]phenoxy-κC²}-9-[3,5-di(methyl-d3)-4-phenyl-2-pyridinyl-κN]carbazole-2,1-diyl-κC)platinum(II) (abbreviation: Pt(mmtBubOcz35dm4ppy-d6)), which is the organometallic complex used as the platinum complex B in Examples 1 and 2, is specifically described.

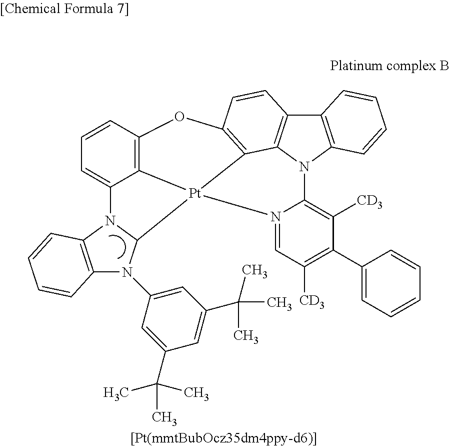

### Step 1: Synthesis of 2-fluoro-3,5-dimethyl-4-phenylpyridine

First, 4.9 g of 2-fluoro-4-iodo-3,5-dimethylpyridine, 2.7 g of phenylboronic acid, 8.3 g of potassium carbonate, 80 mL of 1,4-dioxane, and 20 mL of water were put into a three-neck flask equipped with a reflux pipe, and the air in the flask was replaced with nitrogen. The mixture in the flask was degassed by being stirred under reduced pressure, and then 1.4 g of tetrakis(triphenylphosphine)palladium(0) (abbreviation: Pd(PPh₃)₄) was added thereto. The mixture was stirred at 85° C. for 23 hours to cause a reaction.

After a predetermined time elapsed, extraction was performed with toluene. The resulting residue was purified by silica gel column chromatography using toluene as a developing solvent, so that 3.6 g of a target pale yellow solid was obtained in a yield of 90%. The synthesis scheme of Step 1 is shown below.

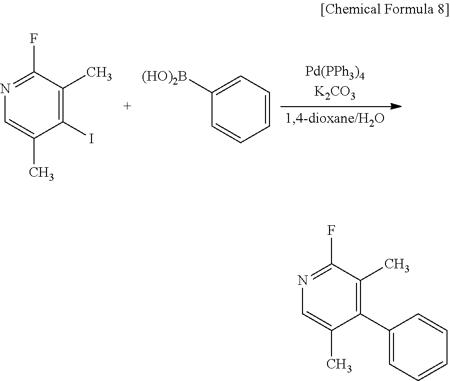

### Step 2: Synthesis of 2-bromo-9-(3,5-dimethyl-4-phenylpyridin-2-yl)carbazole

Next, 3.6 g of 2-fluoro-3,5-dimethyl-4-phenylpyridine obtained in Step 1 above, 4.6 g of 2-bromocarbazole, 12 g of cesium carbonate, and 40 mL of N-methyl-2-pyrrolidone (abbreviation: NMP) were put into a three-neck flask equipped with a reflux pipe, and the air in the flask was replaced with nitrogen. After that, the mixture was stirred at 120° C. for 18.5 hours to cause a reaction.

After a predetermined time elapsed, extraction was performed with toluene. The resulting residue was purified by silica gel column chromatography using hexane and toluene in a ratio of 1:5 as a developing solvent, so that 6.9 g of a target colorless oil was obtained in a yield of 90%. The synthesis scheme of Step 2 is shown below.

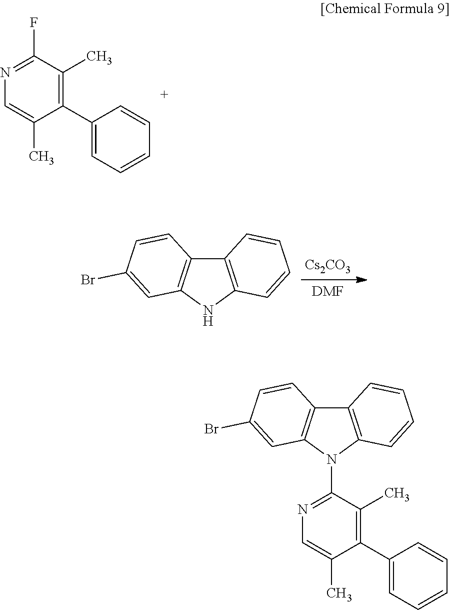

### Step 3: Synthesis of 2-bromo-9-[3,5-di(methyl-d3)-4-phenylpyridin-2-yl]carbazole

Then, 6.9 g of 2-bromo-9-(3,5-dimethyl-4-phenylpyridin-2-yl)carbazole obtained in Step 2 above, 23 mL of dimethyl sulfoxide-d6 (abbreviation: DMSO-d₆), and 0.93 g of sodium tert-butoxide were put into a recovery flask, and the air in the flask was replaced with nitrogen. After that, the mixture was stirred at room temperature for 16 hours to cause a reaction.

After a predetermined time elapsed, extraction was performed with toluene. The resulting residue was purified by silica gel column chromatography using hexane and toluene in a ratio of 1:5 as a developing solvent, so that 5.8 g of a target white solid was obtained in a yield of 83%. The synthesis scheme of Step 3 is shown below.

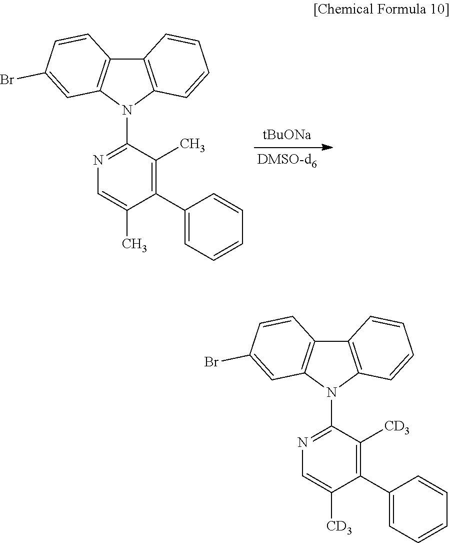 [SMILES: "tBuONa" ; Cc1cnc(-n2c3ccccc3c3ccc(Br)cc32)c(C)c1-c1ccccc1 ; [2H]C([2H])([2H])c1cnc(-n2c3ccccc3c3ccc(Br)cc32)c(C([2H])([2H])[2H])c1-c1ccccc1]

### Step 4: Synthesis of 2-hydroxy-9-[3,5-di(methyl-d3)-4-phenylpyridin-2-yl]carbazole

Subsequently, 5.8 g of 2-bromo-9-[3,5-di(methyl-d3)-4-phenylpyridin-2-yl]carbazole obtained in Step 3 above, 2.7 g of sodium tert-butoxide, 54 mL of dimethyl sulfoxide, and 13 mL of water were put into a three-neck flask equipped with a reflux pipe, and the air in the flask was replaced with nitrogen. The mixture in the flask was degassed by being stirred under reduced pressure; then, 0.066 g of copper(I) chloride (abbreviation: CuCl) and 0.22 g of N¹,N²-bis(4-hydroxy-2,6-dimethylphenyl)oxalamide were added and stirring was performed at 110° C. for 2 hours to cause a reaction.

After a predetermined time elapsed, extraction was performed with ethyl acetate. The resulting residue was purified by being recrystallized with toluene, so that 4.0 g of a target pale orange solid was obtained in a yield of 80%. The synthesis scheme of Step 4 is shown below.

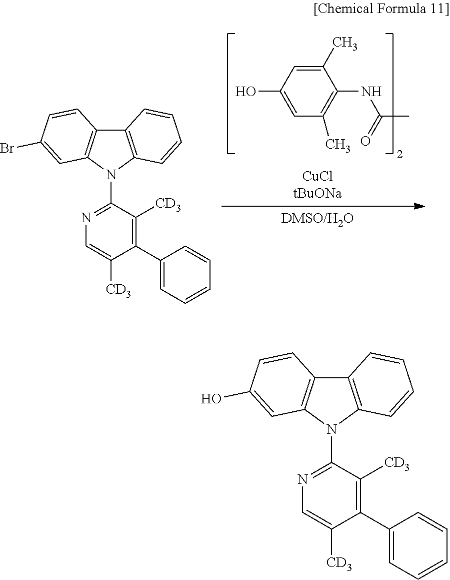

### Step 5: Synthesis of 2-[3-(benzimidazol-1-yl)phenoxy]-9-[3,5-di(methyl-d₃)-4-phenylpyridin-2-yl]carbazole

Next, 1.9 g of 2-hydroxy-9-[3,5-di(methyl-d₃)-4-phenylpyridin-2-yl]carbazole obtained in Step 4 above, 1.5 g of 1-(3-bromophenyl)benzimidazole, 2.2 g of tripotassium phosphate, and 51 mL of dimethyl sulfoxide were put into a three-neck flask equipped with a reflux pipe, and the air in the flask was replaced with nitrogen. The mixture in the flask was degassed by being stirred under reduced pressure, and then 0.098 g of copper(I) iodide (abbreviation: CuI) and 0.063 g of picolinic acid were added thereto. The mixture was stirred at 160° C. for 6.5 hours to cause a reaction.

After a predetermined time elapsed, extraction was performed with ethyl acetate. The resulting residue was purified by silica gel column chromatography using toluene and ethyl acetate in a ratio of 10:1 as a developing solvent, so that 2.7 g of a target brown solid was obtained in a yield of 94%. The synthesis scheme of Step 5 is shown below.

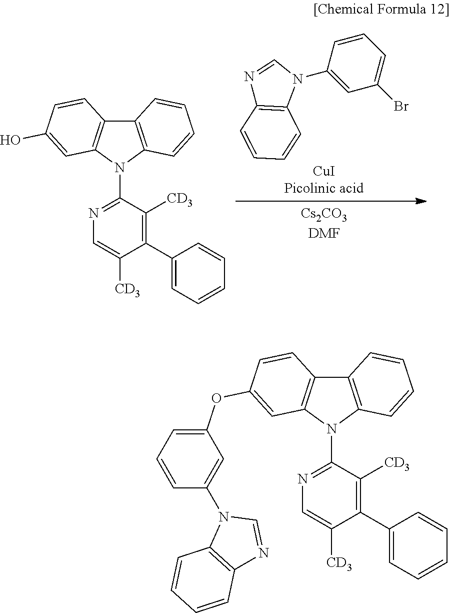 [SMILES: [2H]C([2H])([2H])c1cnc(-n2c3ccccc3c3ccc(O)cc32)c(C([2H])([2H])[2H])c1-c1ccccc1 ; Brc1cccc(-n2cnc3ccccc32)c1 ; [2H]C([2H])([2H])c1cnc(-n2c3ccccc3c3ccc(Oc4cccc(-n5cnc6ccccc65)c4)cc32)c(C([2H])([2H])[2H])c1-c1ccccc1]

### Step 6: Synthesis of 1-(3,5-di-tert-butylphenyl)-3-[3-({9-[3,5-di(methyl-d₃)-4-phenylpyridin-2-yl]carbazol-2-yl}oxy)phenyl]benzimidazolium-1,1,1-trifluoromethanesulfonate

Then, 2.7 g of 2-[3-(benzimidazol-1-yl)phenoxy]-9-[3,5-di(methyl-d₃)-4-phenylpyridin-2-yl]carbazole obtained in Step 5 above, 5.7 g of (3,5-di-tert-butylphenylxmesityl)iodonium trifluoromethanesulfonate, and 25 mL of N,N-dimethylformamide (abbreviation: DMF) were put into a three-neck flask equipped with a reflux pipe, and the air in the flask was replaced with nitrogen. The mixture in the flask was degassed by being stirred under reduced pressure, and then 0.13 g of copper(II) acetate (abbreviation: Cu(OAc)₂) was added thereto. The mixture was stirred at 100° C. for 6 hours to cause a reaction.

After a predetermined time elapsed, the solvent was distilled off and the obtained residue was purified by silica gel column chromatography using dichloromethane and acetone in a ratio of 9:1 as a developing solvent, so that 0.84 g of a target reddish brown solid was obtained in a yield of 19%. The synthesis scheme of Step 6 is shown below.

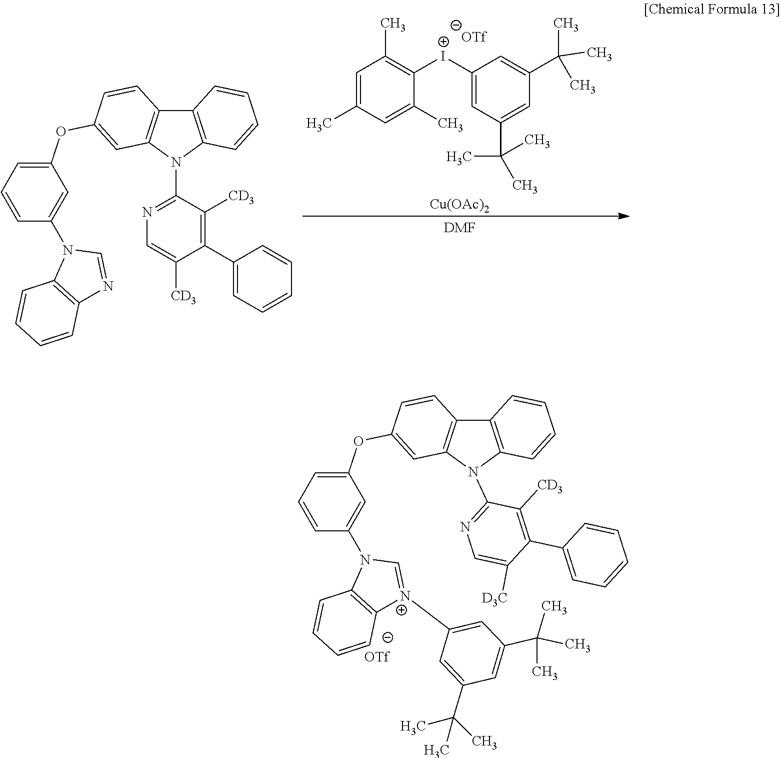

### Step 7: Synthesis of (2-{3-[3-(3,5-di-tert-butylphenyl)benzimidazol-1-yl-2-ylidene-κC²]phenoxy-κC²}-9-[3,5-di(methyl-d₃)-4-phenyl-2-pyridinyl-κN]carbazole-2,1-diyl-κC)platinum(II) (abbreviation: Pt(mmtBubOcz35dm4ppy-d6))

Subsequently, 0.84 g of 1-(3,5-di-tert-butylphenyl)-3-[3-({9-[3,5-di(methyl-d₃)-4-phenylpyridin-2-yl]carbazol-2-yl}oxy)phenyl]benzimidazolium-1,1,1-trifluoromethanesulfonate obtained in Step 6 above, 0.42 g of dichloro(1,5-cyclooctadiene)platinum(II), 0.23 g of sodium acetate, and 42 mL of N,N-dimethylformamide were put into a three-neck flask equipped with a reflux pipe, and the air in the flask was replaced with nitrogen. After that, the mixture was stirred at 160° C. for 3 hours to cause a reaction.

After a predetermined time elapsed, the solvent was distilled off, and extraction was performed with dichloromethane. The resulting residue was purified by silica gel column chromatography using toluene as a developing solvent, and then purification by recrystallization was performed using toluene, so that 0.19 g of a target yellow solid was obtained in a yield of 22

By a train sublimation method, 0.12 g of the obtained yellow solid was purified by sublimation. In the purification by sublimation, the solid was heated at 305° C. under a pressure of 2.5 Pa. After the purification by sublimation, 0.060 g of a target yellow solid was obtained in a yield of 50%. The synthesis scheme of Step 7 is shown below.

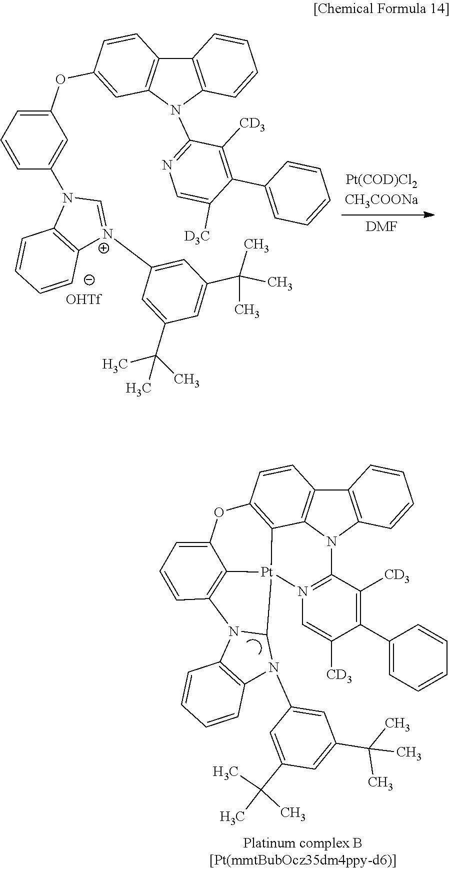

### <Characteristics of Organometallic Complex>

Results of nuclear magnetic resonance (¹H-NMR) spectroscopy analysis of the yellow solid obtained in Step 7 above are shown below. The results show that Pt(mmtBubOcz35dm4ppy-d6) was obtained in this synthesis example.

¹H-NMR. δ (CDCl₃): 1.08 (brs, 9H), 1.42 (brs, 9H), 6.93-6.94 (m, 1H), 7.10 (d, 2H), 7.19 (d, 1H), 7.29-7.42 (m, 7H), 7.48-7.53 (m, 3H), 7.58 (d, 1H), 7.71 (d, 1H), 7.77 (brs, 1H), 7.87 (d, 2H), 8.03 (d, 1H), 8.27 (d, 1H), 8.79 (s, 1H).

### Reference Example 2

### Synthesis Example 2

In this reference example, a method for synthesizing (2-{3-[3-(3,5-di-tert-butylphenyl)benzimidazol-1-yl-2-ylidene-κC²]phenoxy-κC²}-9-[3,5-di(methyl-d3)-4-tert-butylphenyl-2-pyridinyl-κN]carbazole-2,l-diyl-κC)platinum(II) (abbreviation: Pt(mmtBubOcz35dm4tBuppy-d6)), which is the organometallic complex used as the platinum complex C in Examples 1 and 2, is specifically described.

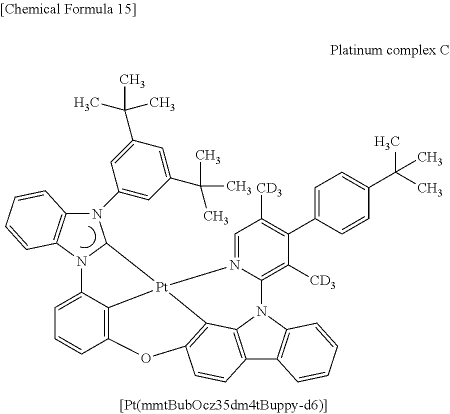

### Step 1: Synthesis of 4-tert-butylphenyl-2-fluoro-3,5-dimethylpyridine

First, 6.0 g of 2-fluoro-4-iodo-3,5-dimethylpyridine, 13 g of 4-tert-butylphenylboronic acid, 15 g of potassium carbonate, 96 mL of 1,4-dioxane, and 24 mL of water were put into a three-neck flask equipped with a reflux pipe, and the air in the flask was replaced with nitrogen. The mixture in the flask was degassed by being stirred under reduced pressure, and then 1.8 g of tetrakis(triphenylphosphine)palladium(0) (abbreviation: Pd(PPh₃)₄) was added thereto. The mixture was stirred at 85° C. for 7.5 hours to cause a reaction.

After a predetermined time elapsed, extraction was performed with toluene. The resulting residue was purified by silica gel column chromatography using toluene as a developing solvent, so that 6.1 g of a target brown solid was obtained in a yield of 100%. The synthesis scheme of Step 1 is shown below.

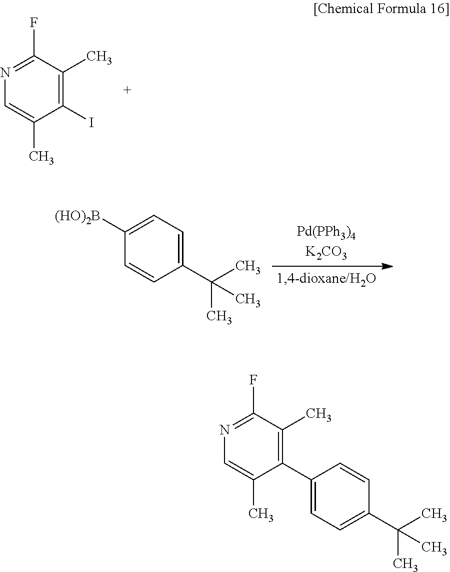

### Step 2: Synthesis of 2-bromo-9-(4-tert-butylphenyl-3,5-dimethylpyridin-2-yl)carbazole

First, 6.1 g of 4-tert-butylphenyl-2-fluoro-3,5-dimethylpyridine, 6.1 g of 2-bromocarbazole, 15 g of cesium carbonate, and 54 mL of N-methyl-2-pyrrolidone (abbreviation: NMP) were put into a three-neck flask equipped with a reflux pipe, and the air in the flask was replaced with nitrogen. After that, the mixture was stirred at 140° C. for 8 hours to cause a reaction.

After a predetermined time elapsed, extraction was performed with toluene. The resulting residue was purified by silica gel column chromatography using hexane and toluene in a ratio of 1:5 as a developing solvent, so that 8.5 g of a target white solid was obtained in a yield of 74%. The synthesis scheme of Step 2 is shown below.

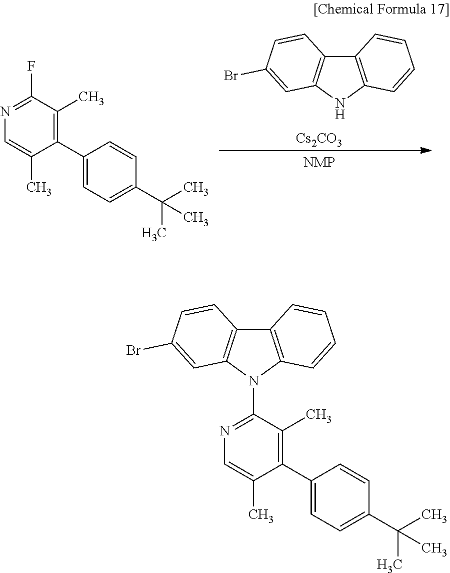

### Step 3: Synthesis of 2-bromo-9-[4-tert-butylphenyl-3,5-di(methyl-d₃)pyridin-2-yl]carbazole

Then, 8.5 g of 2-bromo-9-(4-tert-butylphenyl-3,5-dimethylpyridin-2-yl)carbazole obtained in Step 2 above, 25 mL of dimethyl sulfoxide-d₆ (abbreviation: DMSO-d₆), and 1.0 g of sodium tert-butoxide were put into a recovery flask, and the air in the flask was replaced with nitrogen. After that, the mixture was stirred at 140° C. for 2.5 hours to cause a reaction.

After a predetermined time elapsed, extraction was performed with toluene. The resulting residue was purified by silica gel column chromatography using hexane and toluene in a ratio of 1:5 as a developing solvent, so that 6.2 g of a target yellowish white solid was obtained in a yield of 72%. The synthesis scheme of Step 3 is shown below.

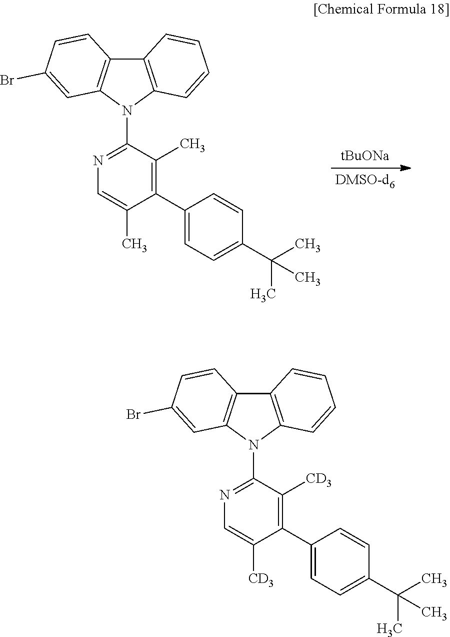 [SMILES: "tBuONa" ; Cc1cnc(-n2c3ccccc3c3ccc(Br)cc32)c(C)c1-c1ccc(C(C)(C)C)cc1 ; [2H]C([2H])([2H])c1cnc(-n2c3ccccc3c3ccc(Br)cc32)c(C([2H])([2H])[2H])c1-c1ccc(C(C)(C)C)cc1]

### Step 4: Synthesis of 2-hydroxy-9-[4-tert-butylphenyl-3,5-di(methyl-d₃)pyridin-2-yl]carbazole

Subsequently, 6.2 g of 2-bromo-9-[4-tert-butylphenyl-3,5-di(methyl-d₃)pyridin-2-yl]carbazole obtained in Step 3 above, 2.6 g of sodium tert-butoxide, 51 mL of dimethyl sulfoxide, and 13 mL of water were put into a three-neck flask equipped with a reflux pipe, and the air in the flask was replaced with nitrogen. The mixture in the flask was degassed by being stirred under reduced pressure; then, 0.13 g of copper(I) chloride (abbreviation: CuCl) and 0.42 g of N¹,N²-bis(4-hydroxy-2,6-dimethylphenyl)oxalamide were added and stirring was performed at 110° C. for 10.5 hours to cause a reaction.

After a predetermined time elapsed, 300 mL of water was added, and the resulting mixture was suction-filtered. The resulting residue was purified by being recrystallized with toluene, so that 3.8 g of a target gray solid was obtained in a yield of 70%. The synthesis scheme of Step 4 is shown below.

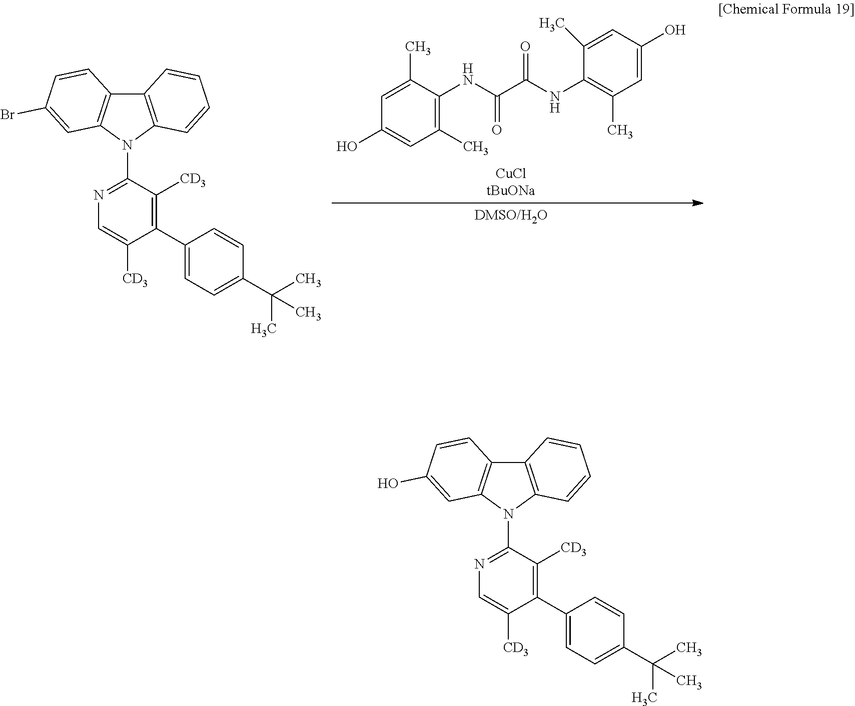 [SMILES: [2H]C([2H])([2H])c1cnc(-n2c3ccccc3c3ccc(Br)cc32)c(C([2H])([2H])[2H])c1-c1ccc(C(C)(C)C)cc1 ; Cc1cc(O)cc(C)c1NC(=O)C(=O)Nc1c(C)cc(O)cc1C ; [2H]C([2H])([2H])c1cnc(-n2c3ccccc3c3ccc(O)cc32)c(C([2H])([2H])[2H])c1-c1ccc(C(C)(C)C)cc1]

### Step 5: Synthesis of 2-[3-(benzimidazol-1-yl)phenoxy]-9-[4-tert-butylphenyl-3,5-di(methyl-d₃)pyridin-2-yl]carbazole

Next, 3.8 g of 2-hydroxy-9-[4-tert-butylphenyl-3,5-di(methyl-d₃)pyridin-2-yl]carbazole obtained in Step 4 above, 2.6 g of 1-(3-bromophenyl)benzimidazole, 3.7 g of tripotassium phosphate, and 88 mL of dimethyl sulfoxide were put into a three-neck flask equipped with a reflux pipe, and the air in the flask was replaced with nitrogen. The mixture in the flask was degassed by being stirred under reduced pressure, and then 0.17 g of copper(I) iodide (abbreviation: CuI) and 0.11 g of picolinic acid were added thereto. The mixture was stirred at 160° C. for 3 hours to cause a reaction.

After a predetermined time elapsed, extraction was performed with ethyl acetate. The resulting residue was purified by silica gel column chromatography using toluene and ethyl acetate in a ratio of 10:1 as a developing solvent, so that 5.6 g of a target brown solid was obtained in a yield of 100%. The synthesis scheme of Step 5 is shown below.

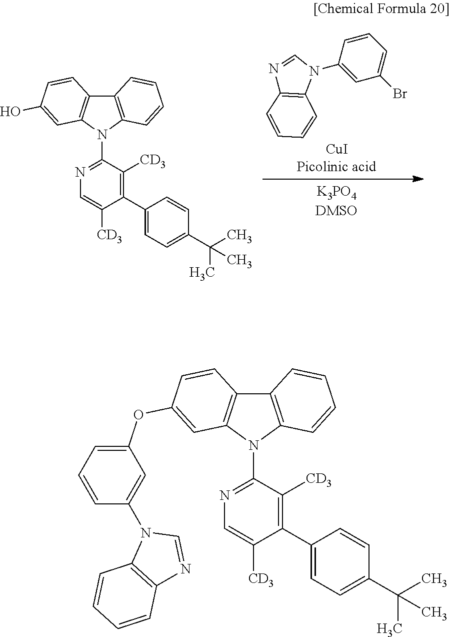 [SMILES: [2H]C([2H])([2H])c1cnc(-n2c3ccccc3c3ccc(O)cc32)c(C([2H])([2H])[2H])c1-c1ccc(C(C)(C)C)cc1 ; Brc1cccc(-n2cnc3ccccc32)c1 ; [2H]C([2H])([2H])c1cnc(-n2c3ccccc3c3ccc(Oc4cccc(-n5cnc6ccccc65)c4)cc32)c(C([2H])([2H])[2H])c1-c1ccc(C(C)(C)C)cc1]

### Step 6: Synthesis of 1-(3,5-di-tert-butylphenyl)-3-[3-({9-[4-tert-butylphenyl-3,5-di(methyl-d₃)pyridin-2-yl]carbazol-2-yl}oxy)phenyl]benzimidazolium-1,1,1-trifluoromethanesulfonate

Then, 5.6 g of 2-[3-(benzimidazol-1-yl)phenoxy]-9-[4-tert-butylphenyl-3,5-di(methyl-d₃)pyridin-2-yl]carbazole obtained in Step 5 and 25 mL of N,N-dimethylformamide (abbreviation: DMF) were put into a three-neck flask equipped with a reflux pipe, and the air in the flask was replaced with nitrogen. The mixture in the flask was degassed by being stirred under reduced pressure, 0.25 g of copper(II) acetate (abbreviation: Cu(OAc)₂) was added thereto, and heating was performed at 100° C. A solution in which 10 g of (3,5-di-tert-butylphenyl) (mesityl)iodonium trifluoromethanesulfonate was dissolved in 100 mL of DMF was dripped into the resulting mixture, and stirring was performed at 100° C. for 3 hours to cause a reaction.

After a predetermined time elapsed, the solvent was distilled off and the obtained residue was purified by silica gel column chromatography using dichloromethane and acetone in a ratio of 9:1 as a developing solvent, so that 8.0 g of a target brown solid was obtained in a yield of 92%. The synthesis scheme of Step 6 is shown below.

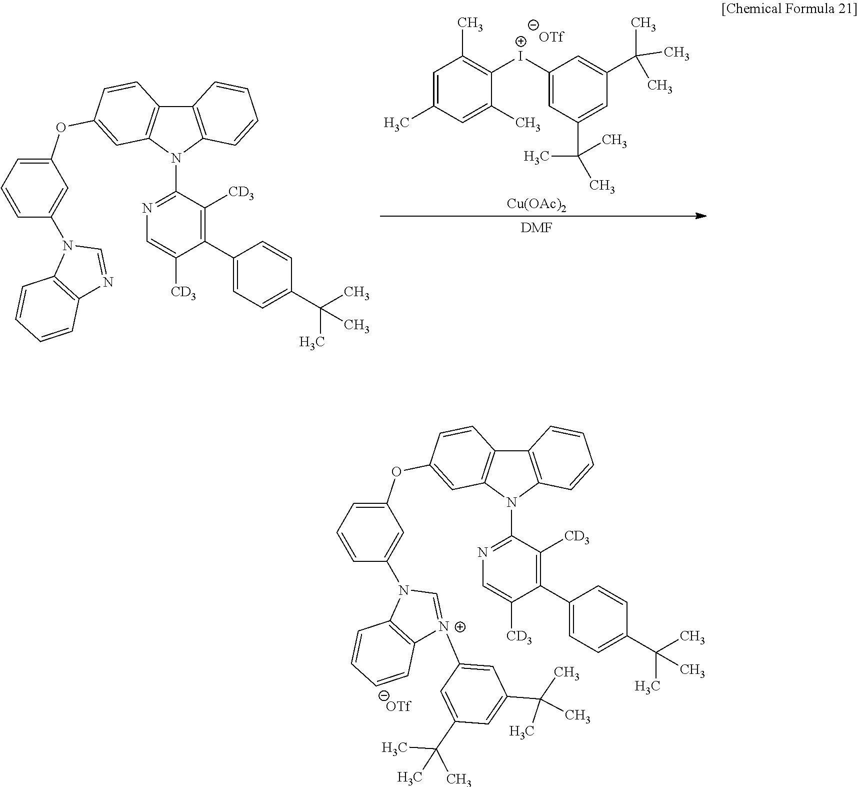

### Step 7: Synthesis of Pt(mmtBubOcz35dm4tBuppy-d₆)

Subsequently, 8.0 g of 1-(3,5-di-tert-butylphenyl)-3-[3-({9-[4-tert-butylphenyl-3,5-di(methyl-d₃)pyridin-2-yl]carbazol-2-yl}oxy)phenyl]benzimidazolium-1,1,1-trifluoromethanesulfonate obtained in Step 6 above, 3.7 g of dichloro(1,5-cyclooctadiene)platinum(II), 2.1 g of sodium acetate, and 380 mL of DMF were put into a three-neck flask equipped with a reflux pipe, and the air in the flask was replaced with nitrogen. After that, the mixture was stirred at 160° C. for 2 hours to cause a reaction.

After a predetermined time elapsed, the solvent was distilled off, and extraction was performed with dichloromethane. The resulting residue was purified by silica gel column chromatography using toluene as a developing solvent, and then purification by recrystallization was performed using a mixed solvent of toluene and ethanol, so that 3.0 g of a target yellow solid was obtained in a yield of 36%.

By a train sublimation method, 1.9 g of the obtained yellow solid was purified by sublimation. In the purification by sublimation, the solid was heated at 325° C. under a pressure of 3.1 Pa. After the purification by sublimation, 1.4 g of a target yellow solid was obtained in a yield of 74%. The synthesis scheme of Step 7 is shown below.

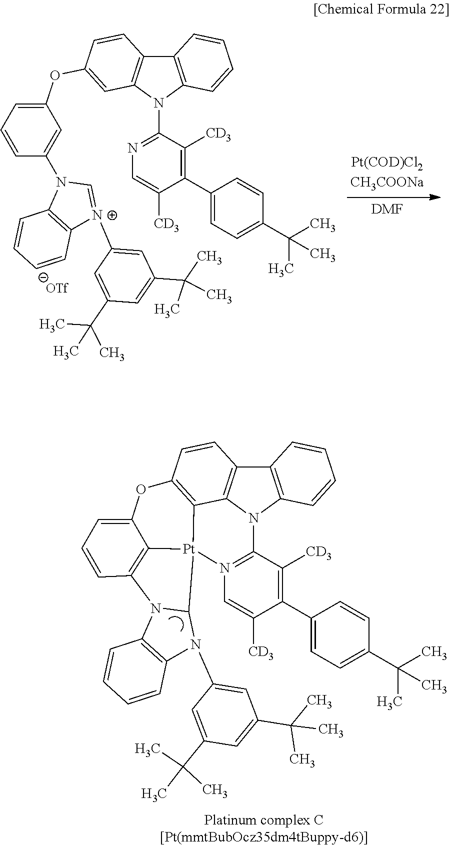

### <Characteristics of Organometallic Complex>

Results of nuclear magnetic resonance (¹H-NMR) spectroscopy analysis of the yellow solid obtained in Step 7 above are shown below. The results show that Pt(mmtBubOcz35dm4tBuppy-d6) was obtained in this synthesis example.

¹H-NMR. δ (CD₂Cl₂): 1.08 (brs, 9H), 1.33 (s, 9H), 1.42 (brs, 9H), 6.86 (d, 1H), 7.03 (d, 1H), 7.10 (d, 1H), 7.20 (d, 1H), 7.29-7.42 (m, 6H), 7.48 (s, 1H), 7.51 (t, 2H), 7.58 (d, 1H), 7.70 (d, 1H), 7.78 (brs, 1H), 7.84 (d, 2H), 8.03 (d, 1H), 8.27 (d, 1H), 8.77 (s, 1H).

This application is based on Japanese Patent Application Serial No. 2023-203379 filed with Japan Patent Office on Nov. 30, 2023, the entire contents of which are hereby incorporated by reference.

What is claimed is:

1. A light-emitting apparatus material comprising:
an organic compound,
wherein an inner product of a vector A connecting two most distant atoms in a lowest excited state of the organic compound and a vector B that is a transition dipole moment relating to light emission from the organic compound is greater than or equal to 2.5,
wherein a length of the vector A is represented in nm,
wherein a magnitude of the vector B is represented in debye, and
wherein a direction of the vector A is set such that an angle formed by the vector A and the vector B is less than or equal to 90°.

2. A light-emitting apparatus material comprising:
an organometallic complex,
wherein an inner product of a vector A connecting two most distant atoms in a lowest triplet excited state of the organometallic complex and a vector B that is a transition dipole moment relating to light emission from the organometallic complex is greater than or equal to 2.5,
wherein a length of the vector A is represented in nm,
wherein a magnitude of the vector B is represented in debye, and
wherein a direction of the vector A is set such that an angle formed by the vector A and the vector B is less than or equal to 90°.

3. The light-emitting apparatus material according to claim 2, wherein the organometallic complex comprises a quadridentate ligand.

4. The light-emitting apparatus material according to claim 2, wherein the organometallic complex is a cyclometalated complex.

5. The light-emitting apparatus material according to claim 2, wherein a metal in the organometallic complex and some atoms in a ligand in the organometallic complex form a six-membered ring.

6. The light-emitting apparatus material according to claim 2, wherein a metal in the organometallic complex and some atoms in a ligand in the organometallic complex form a five-membered ring.

7. The light-emitting apparatus material according to claim 6, further comprising a plurality of the five-membered rings.

8. The light-emitting apparatus material according to claim 2, wherein the organometallic complex comprises a ligand comprising carbazole.

9. The light-emitting apparatus material according to claim 2, wherein a metal in the organometallic complex is platinum.

10. The light-emitting apparatus material according to claim 2, wherein an emission quantum yield of the organometallic complex is higher than or equal to 0.60.

11. The light-emitting apparatus material according to claim 1, wherein a molecular orientation parameter a of light emitted from a light-emitting device comprising the organic compound as an emission center substance in a light-emitting layer is less than or equal to 0.23.

12. The light-emitting apparatus material according to claim 2, wherein a molecular orientation parameter a of light emitted from a light-emitting device comprising the organometallic complex as an emission center substance in a light-emitting layer is less than or equal to 0.23.

13. A light-emitting device comprising:
the light-emitting apparatus material according to claim 1.

14. A light-emitting device comprising:
a first electrode;
a second electrode; and
a light-emitting layer between the first electrode and the second electrode,
wherein the light-emitting layer comprises an organometallic complex,
wherein an inner product of a vector A connecting two most distant atoms in a lowest triplet excited state of the organometallic complex and a vector B that is a transition dipole moment relating to light emission from the organometallic complex is greater than or equal to 2.5,
wherein a length of the vector A is represented in nm,
wherein a magnitude of the vector B is represented in debye, and
wherein a direction of the vector A is set such that an angle formed by the vector A and the vector B is less than or equal to 90°.

15. The light-emitting device according to claim 14, wherein the organometallic complex comprises a quadridentate ligand.

16. The light-emitting device according to claim 14, wherein the organometallic complex comprises a ligand comprising carbazole.

17. The light-emitting device according to claim 14, wherein a metal in the organometallic complex is platinum.

18. The light-emitting device according to claim 14, wherein an emission quantum yield of the organometallic complex is higher than or equal to 0.60.

19. The light-emitting device according to claim 14, wherein a molecular orientation parameter a of light emitted from the light-emitting device comprising the organometallic complex as an emission center substance in the light-emitting layer is less than or equal to 0.23.
